(19) United States
(12) Patent Application Publication
(10) Pub. No.: US 2023/0145851 A1
(43) Pub. Date: May 11, 2023

(54) INTERFACE LAYER DESIGN FOR EFFICIENT AND STABLE WHITE OLEDS

(71) Applicant: ARIZONA BOARD OF REGENTS ON BEHALF OF ARIZONA STATE UNIVERSITY, Scottsdale, AZ (US)

(72) Inventor: Jian Li, Tempe, AZ (US)

(21) Appl. No.: 18/054,209

(22) Filed: Nov. 10, 2022

Related U.S. Application Data
(60) Provisional application No. 63/277,755, filed on Nov. 10, 2021.

(51) Int. Cl. H01L 51/00; H01L 51/50; H01L 51/42

(52) U.S. Cl. CPC H01L 51/0072; H01L 51/0094; H01L 51/0052; H01L 51/0054; H01L 51/0067; H01L 51/0073; H01L 51/0074; H01L 51/0059; H01L 51/0061; H01L 51/006; H01L 51/0087; H01L 51/0084; H01L 51/5016; H01L 51/42

(57) ABSTRACT

A white organic light emitting device comprises a first emissive layer comprising a phosphorescent emitter; a second emissive layer comprising a fluorescent emitter; and an interface layer, disposed between the first emissive layer and the second emissive layer; wherein the interface layer comprises a high energy gap material represented by Formula I, Formula II, or Formula III.

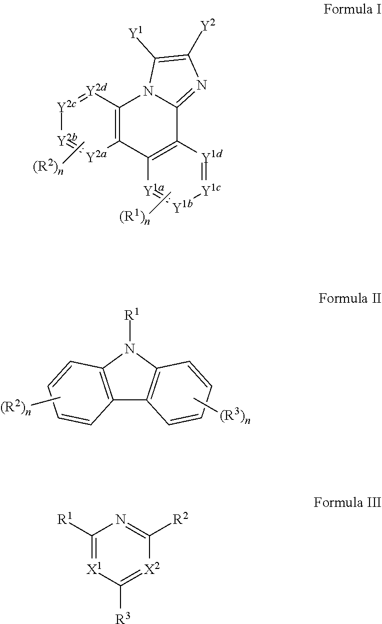

### CROSS-REFERENCE TO RELATED APPLICATIONS

The present application claims priority to U.S. Provisional Application No. 63/277,755, filed Nov. 10, 2021, which is incorporated by reference herein in its entirety.

### STATEMENT REGARDING FEDERALLY SPONSORED RESEARCH OR DEVELOPMENT

This invention was made with government support under EE0008721 awarded by the U.S. Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

In recent years, organic light emitting diodes (OLEDs) have attracted great attention from both academic and industrial areas due to their outstanding merits, like high color quality, wide-viewing angle, low cost fabrication, low power consumption, fast respond speed and high electron to photon conversion efficiency. Most of the organic light emitting diodes (OLEDs) are phosphorescent OLEDs using Iridium(Ir), palladium (Pd) and platinum (Pt) complexes, as these metal complexes have strong Spin-Orbital Coupling, they can efficiently emit light from their triplet exited state and reach nearly 100% internal efficiency.

The development of efficient white OLED can have significant applications for general lighting purpose. However, the current short operational lifetime of blue phosphorescent emitters will limit the overall performance of white OLED consisting of all phosphorescent emitters.

There remains a need in the art for efficient and stable white organic light-emitting diodes. This invention addresses this unmet need.

### SUMMARY OF THE INVENTION

In one aspect, the present invention relates to a white organic light emitting device comprising:

a first emissive layer comprising a phosphorescent emitter;

a second emissive layer comprising a fluorescent emitter; and

an interface layer, disposed between the first emissive layer and the second emissive layer;

wherein the interface layer comprises a high energy gap material represented by Formula I, Formula II, or Formula III:

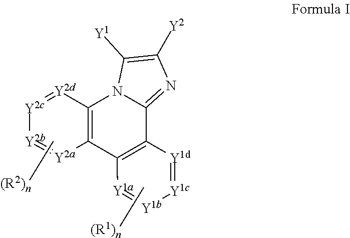

wherein in Formula I:

Y^{1a}, Y^{1b}, Y^{1c}, Y^{1d}, Y^{2a}, Y^{2b}, Y^{2c}, Y^{2d}, each independently represents C or N; wherein at least two of Y^{1a}, Y^{1b}, Y^{1c}, Y^{1d}, Y^{2a}, Y^{2b}, Y^{2c}, and Y^{2d} represent N;

Y¹ and Y² independently represent hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; Y¹ and Y² may together form a ring which is optionally further studied;

R¹ and R² are independently absent or present, valency permitting, and each R¹ and R² independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; any two adjacent R¹ and R² may together form a ring; and
each n is an integer, valency permitting;

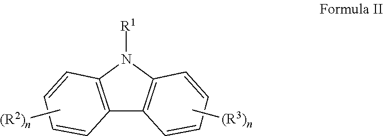

wherein in Formula II:

Each of R¹, R², and R³ is independently absent or present as a single substituent or multiple substituents, valency permitting, and each R¹, R², and R³ present independently represents hydrogen, deuterium, halogen, hydroxyl, thiol, nitro, cyanide, isocyanide, sulfinyl, mercapto, sulfo, carboxyl, hydrazino; substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; and

each n is an integer, valency permitting;

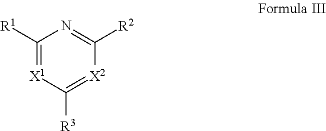

wherein in Formula III:

each of X¹ and X² is independently N or C—R⁴. each of R¹, R², R³, and R⁴ independently represents hydrogen, deuterium, halogen, hydroxyl, thiol, nitro, cyanide, isocyanide, sulfinyl, mercapto, sulfo, carboxyl, hydrazino; substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

### BRIEF DESCRIPTION OF THE DRAWINGS

The following detailed description of preferred embodiments of the disclosure will be better understood when read in conjunction with the appended drawings. For the purpose of illustrating the invention, there are shown in the drawings embodiments which are presently preferred. It should be understood, however, that the invention is not limited to the precise arrangements and instrumentalities of the embodiments shown in the drawings.

FIG. 1 is a schematic diagram of an organic light emitting device.

FIG. 2 is a plot of EL spectra for Devices 1-3.

FIG. 3 is a plot of EQE vs Luminance for Devices 1-3.

FIG. 4 is a plot of normalized EL intensity vs device operational time at the constant current of 20 mA cm⁻² for Devices 1-3.

FIG. 5 is a plot of EL spectra at driving currents of 1-10 mA cm⁻² for Device 1.

FIG. 6 is a plot of EL spectra at driving currents of 1-10 mA cm⁻² for Device 2.

FIG. 7 is a plot of EL spectra at driving currents of 1-10 mA cm⁻² for Device 3.

FIG. 8 is a schematic of device operation in devices of amber excimer/blue fluorescent layer (i.e., devices lacking an interface layer).

FIG. 9 is a schematic of device operation in devices of amber excimer/interface layer/blue fluorescent layer where an interface layer consists a thin layer of mixed BH (transporting holes and electrons) and high energy gap materials (spacing and preventing the quenching of excimers from low triplet energy BH materials).

FIG. 10 is a plot of EQE vs Luminance for devices having various exemplary interface layer configurations.

FIG. 11 is a plot of EL spectra for devices having various exemplary interface layer configurations.

FIG. 12 is a J-V curve for devices having various exemplary interface layer configurations.

FIG. 13 is a plot of power efficiency vs luminance for devices having various exemplary interface layer configurations.

FIG. 14 is a plot of current density—voltage characteristics for devices 1-4 with the structure of ITO (100 nm)/HATCN (10 nm)/NPD (70 nm)/TrisPCz (10 nm)/EML/BPyTP (40 nm)/Liq (2 nm)/Al, where EML is Pd3O8-Py5 (5 nm)/2 wt. % t-DABNA:BH (30 nm) for device 1, 2 wt. % t-DABNA:BH (30 nm)/Pd3O8-Py5 (5 nm) for device 2, 10 wt. % PQIr:CBP (5 nm)/2 wt. % t-DABNA:BH (30 nm) for device 3, and PQIr (5 nm)/2 wt. % t-DABNA:BH (30 nm) for device 4.

FIG. 15 is plot of EL spectra at current densities of 1, 5 and 10 mA cm⁻² for Device 1.

FIG. 16 is plot of EL spectra at current densities of 1, 5 and 10 mA cm⁻² for Device 2.

FIG. 17 is plot of EL spectra at current densities of 1, 5 and 10 mA cm⁻² for Device 3.

FIG. 18 is plot of EL spectra at current densities of 1, 5 and 10 mA cm⁻² for Device 4.

FIG. 19 is a plot of EQE versus luminance for devices 1-4.

FIG. 20 is a plot of relative luminance versus operational time at a constant current density of 20 mA cm⁻² for devices 1-4.

FIG. 21 is a plot of EQE versus luminance and EL spectra at the current density of 1 mA cm⁻² (inset) for devices 5-8 with the structure of ITO (100 nm)/HATCN (10 nm)/NPD (70 nm)/TrisPCz (10 nm)/Pd3O8-Py5 (5 nm)/X/2 wt. % t-DABNA:BH (30 nm)/BPyTP (40 nm)/Liq (2 nm)/Al, where X is 20 wt. % 2py22-dp:BH (5 nm) for device 5, 50 wt. % 2py22-dp:BH (5 nm) for device 6, 80 wt. % 2py22-dp:BH (5 nm) for device 7 and 2py22-dp (2 nm) for device 8.

FIG. 22 is a plot of relative luminance versus operational time at a constant current density of 20 mA cm ⁻² for devices 5-8.

FIG. 23 is plot of EL spectra at current densities of 1, 5 and 10 mA cm⁻² for device 6.

FIG. 24 is plot of EL spectra at current densities of 1, 5 and 10 mA cm⁻² for device 9.

FIG. 25 is plot of EL spectra at current densities of 1, 5 and 10 mA cm⁻² for device 10.

FIG. 26 is plot of EL spectra at current densities of 1, 5 and 10 mA cm⁻² for device 11.

FIG. 27 is a plot of EQE versus luminance device 6, 9-11 with the structure of ITO (100 nm)/HATCN (10 nm)/NPD (70 nm)/TrisPCz (10 nm)/Pd3O8-Py5 (x nm)/50 wt. % 2py22-dp:BH (5 nm)/2 wt. % t-DABNA:BH (30 nm)/BPyTP (40 nm)/Liq (2 nm)/Al, where x is 5 nm for device 6, 4 nm for device 9, 3 nm for device 10, 2 nm for device 11.

FIG. 28 is a plot of relative luminance versus operational lifetime at a constant current density of 20 mA cm² for device 6, 9-12; Device 12 has the structure of ITO (100 nm) /HATCN (10 nm)/NPD (70 nm)/TrisPCz (10 nm)/Pd3O8-Py5 (5 nm)/50 wt. % 2py22-dp:BH (5 nm)/2 wt. % t-DABNA:BH (30 nm)/BAlq (10 nm)/BPyTP (40 nm)/Liq (2 nm)/Al.

FIG. 29 is a plot of EQE versus luminance (left, solid lines), PE versus luminance (right, dashed lines) and EL spectra (inset) of device 12.

FIG. 30 is a plot of EQE vs Luminance for devices employing SiTrzCz2 and SiBCz as high energy gap materials.

FIG. 31 is a plot of electroluminescence spectra for devices employing SiTrzCz2 and SiBCz as high energy gap materials.

FIG. 32 is a plot of electroluminescent intensity @ 20 mA/cm² vs operation time for devices employing SiTrzCz2 and SiBCz as high energy gap materials.

### DETAILED DESCRIPTION

The present disclosure relates in part to the unexpected discovery that an interface layer between fluorescent and phosphorescent emitting layers can improve efficiency in a white OLED.

### Definitions

It is to be understood that the figures and descriptions in the present disclosure have been simplified to illustrate elements that are relevant for a clear understanding of the present invention, while eliminating, for the purpose of clarity, many other elements found in the art related to phosphorescent organic light emitting devices and the like. Those of ordinary skill in the art may recognize that other elements and/or steps are desirable and/or required in implementing the disclosed embodiments. However, because such elements and steps are well known in the art, and because they do not facilitate a better understanding of the present disclosure, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this disclosure belongs. Although any methods, materials and components similar or equivalent to those described herein can be used in the practice or testing of the disclosed embodiments, the preferred methods, and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, or ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

Disclosed are the components to be used to prepare the compositions of the disclosure as well as the compositions themselves to be used within the methods disclosed herein. These and other materials are disclosed herein, and it is understood that when combinations, subsets, interactions, groups, etc. of these materials are disclosed that while specific reference of each various individual and collective combinations and permutation of these compounds cannot be explicitly disclosed, each is specifically contemplated and described herein. For example, if a particular compound is disclosed and discussed and a number of modifications that can be made to a number of molecules including the compounds are discussed, specifically contemplated is each and every combination and permutation of the compound and the modifications that are possible unless specifically indicated to the contrary. Thus, if a class of molecules A, B, and C are disclosed as well as a class of molecules D, E, and F and an example of a combination molecule, A-D is disclosed, then even if each is not individually recited each is individually and collectively contemplated meaning combinations, A-E, A-F, B-D, B-E, B-F, C-D, C-E, and C-F are considered disclosed. Likewise, any subset or combination of these is also disclosed. Thus, for example, the sub-group of A-E, B-F, and C-E would be considered disclosed. This concept applies to all aspects of this application including, but not limited to, steps in methods of making and using the compositions of the invention. Thus, if there are a variety of additional steps that can be performed it is understood that each of these additional steps can be performed with any specific embodiment or combination of embodiments of the methods of the invention.

As referred to herein, a linking atom or a linking group can connect two groups such as, for example, an N and C group. The linking atom can optionally, if valency permits, have other chemical moieties attached. For example, in one aspect, an oxygen would not have any other chemical groups attached as the valency is satisfied once it is bonded to two groups (e.g., N and/or C groups). In another aspect, when carbon is the linking atom, two additional chemical moieties can be attached to the carbon. Suitable chemical moieties include, but are not limited to, hydrogen, hydroxyl, alkyl, alkoxy, ═O, halogen, nitro, amine, amide, thiol, aryl, heteroaryl, cycloalkyl, and heterocyclyl.

The term “cyclic structure” or the like terms used herein refer to any cyclic chemical structure which includes, but is not limited to, aryl, heteroaryl, cycloalkyl, cycloalkenyl, and heterocyclyl.

As used herein, the term “substituted” is contemplated to include all permissible substituents of organic compounds. In a broad aspect, the permissible substituents include acyclic and cyclic, branched and unbranched, carbocyclic and heterocyclic, and aromatic and nonaromatic substituents of organic compounds. Illustrative substituents include, for example, those described below. The permissible substituents can be one or more and the same or different for appropriate organic compounds. For purposes of this disclosure, the heteroatoms, such as nitrogen, can have hydrogen substituents and/or any permissible substituents of organic compounds described herein which satisfy the valences of the heteroatoms. This disclosure is not intended to be limited in any manner by the permissible substituents of organic compounds. Also, the terms “substitution” or “substituted with” include the implicit proviso that such substitution is in accordance with permitted valence of the substituted atom and the substituent, and that the substitution results in a stable compound, e.g., a compound that does not spontaneously undergo transformation such as by rearrangement, cyclization, elimination, etc. It is also contemplated that, in certain aspects, unless expressly indicated to the contrary, individual substituents can be further optionally substituted (i.e., further substituted or unsubstituted).

The term “alkyl” as used herein is a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can be cyclic or acyclic. The alkyl group can be branched or unbranched. The alkyl group can also be substituted or unsubstituted. For example, the alkyl group can be substituted with one or more groups including, but not limited to, alkyl, cycloalkyl, alkoxy, amino, ether, halide, hydroxy, nitro, silyl, sulfo-oxo, or thiol, as described herein. A “lower alkyl” group is an alkyl group containing from one to six (e.g., from one to four) carbon atoms.

Throughout the specification “alkyl” is generally used to refer to both unsubstituted alkyl groups and substituted alkyl groups; however, substituted alkyl groups are also specifically referred to herein by identifying the specific substituent(s) on the alkyl group. For example, the term “halogenated alkyl” or “haloalkyl” specifically refers to an alkyl group that is substituted with one or more halide, e.g., fluorine, chlorine, bromine, or iodine. The term “alkoxyalkyl” specifically refers to an alkyl group that is substituted with one or more alkoxy groups, as described below. The term “alkylamino” specifically refers to an alkyl group that is substituted with one or more amino groups, as described below, and the like. When “alkyl” is used in one instance and a specific term such as “alkylalcohol” is used in another, it is not meant to imply that the term “alkyl” does not also refer to specific terms such as “alkylalcohol” and the like.

This practice is also used for other groups described herein. That is, while a term such as “cycloalkyl” refers to both unsubstituted and substituted cycloalkyl moieties, the substituted moieties can, in addition, be specifically identified herein; for example, a particular substituted cycloalkyl can be referred to as, e.g., an “alkylcycloalkyl.” Similarly, a substituted alkoxy can be specifically referred to as, e.g., a “halogenated alkoxy,” a particular substituted alkenyl can be, e.g., an “alkenylalcohol,” and the like. Again, the practice of using a general term, such as “cycloalkyl,” and a specific term, such as “alkylcycloalkyl,” is not meant to imply that the general term does not also include the specific term.

The term “cycloalkyl” as used herein is a non-aromatic carbon-based ring composed of at least three carbon atoms. Examples of cycloalkyl groups include, but are not limited to, cyclopropyl, cyclobutyl, cyclopentyl, cyclohexyl, norbornyl, and the like. The term “heterocycloalkyl” is a type of cycloalkyl group as defined above, and is included within the meaning of the term “cycloalkyl,” where at least one of the carbon atoms of the ring is replaced with a heteroatom such as, but not limited to, nitrogen, oxygen, sulfur, or phosphorus. The cycloalkyl group and heterocycloalkyl group can be substituted or unsubstituted. The cycloalkyl group and heterocycloalkyl group can be substituted with one or more groups including, but not limited to, alkyl, cycloalkyl, alkoxy, amino, ether, halide, hydroxy, nitro, silyl, sulfo-oxo, or thiol as described herein.

The term “polyalkylene group” as used herein is a group having two or more CH₂ groups linked to one another. The polyalkylene group can be represented by the formula —(CH₂)ₐ—, where “a” is an integer of from 2 to 500.

The terms “alkoxy” and “alkoxyl” as used herein to refer to an alkyl or cycloalkyl group bonded through an ether linkage; that is, an “alkoxy” group can be defined as —OA' where A¹ is alkyl or cycloalkyl as defined above. “Alkoxy” also includes polymers of alkoxy groups as just described; that is, an alkoxy can be a polyether such as —OA¹—OA² or —OA¹—(OA²)ₐ—OA³, where “a” is an integer of from 1 to 200 and A¹, A², and A³ are alkyl and/or cycloalkyl groups.

The term “alkenyl” as used herein is a hydrocarbon group of from 2 to 24 carbon atoms with a structural formula containing at least one carbon-carbon double bond. Asymmetric structures such as (A¹A²)C═C(A³A⁴) are intended to include both the E and Z isomers. This can be presumed in structural formulae herein wherein an asymmetric alkene is present, or it can be explicitly indicated by the bond symbol C=C. The alkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkenyl” as used herein is a non-aromatic carbon-based ring composed of at least three carbon atoms and containing at least one carbon-carbon double bond, i.e., C═C. Examples of cycloalkenyl groups include, but are not limited to, cyclopropenyl, cyclobutenyl, cyclopentenyl, cyclopentadienyl, cyclohexenyl, cyclohexadienyl, norbornenyl, and the like. The term “heterocycloalkenyl” is a type of cycloalkenyl group as defined above, and is included within the meaning of the term “cycloalkenyl,” where at least one of the carbon atoms of the ring is replaced with a heteroatom such as, but not limited to, nitrogen, oxygen, sulfur, or phosphorus. The cycloalkenyl group and heterocycloalkenyl group can be substituted or unsubstituted. The cycloalkenyl group and heterocycloalkenyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “alkynyl” as used herein is a hydrocarbon group of 2 to 24 carbon atoms with a structural formula containing at least one carbon-carbon triple bond. The alkynyl group can be unsubstituted or substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol, as described herein.

The term “cycloalkynyl” as used herein is a non-aromatic carbon-based ring composed of at least seven carbon atoms and containing at least one carbon-carbon triple bound. Examples of cycloalkynyl groups include, but are not limited to, cycloheptynyl, cyclooctynyl, cyclononynyl, and the like. The term “heterocycloalkynyl” is a type of cycloalkenyl group as defined above, and is included within the meaning of the term “cycloalkynyl,” where at least one of the carbon atoms of the ring is replaced with a heteroatom such as, but not limited to, nitrogen, oxygen, sulfur, or phosphorus. The cycloalkynyl group and heterocycloalkynyl group can be substituted or unsubstituted. The cycloalkynyl group and heterocycloalkynyl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein.

The term “aryl” as used herein is a group that contains any carbon-based aromatic group including, but not limited to, benzene, naphthalene, phenyl, biphenyl, phenoxybenzene, and the like. The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group is optionally substituted.

The term “aryl” also includes “heteroaryl,” which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term “non-heteroaryl,” which is also included in the term “aryl,” defines a group that contains an aromatic group that does not contain a heteroatom. The aryl group can be substituted or unsubstituted. The aryl group can be substituted with one or more groups including, but not limited to, alkyl, cycloalkyl, alkoxy, alkenyl, cycloalkenyl, alkynyl, cycloalkynyl, aryl, heteroaryl, aldehyde, amino, carboxylic acid, ester, ether, halide, hydroxy, ketone, azide, nitro, silyl, sulfo-oxo, or thiol as described herein. The term “biaryl” is a specific type of aryl group and is included in the definition of “aryl.” Biaryl refers to two aryl groups that are bound together via a fused ring structure, as in naphthalene, or are attached via one or more carbon-carbon bonds, as in biphenyl.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group is optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f, h]quinoxaline and dibenzo[f,h]quinoline. One of ordinary skill in the art can readily envision other nitrogen analogs of the aza-derivatives described above, and all such analogs are intended to be encompassed by the terms as set forth herein.

The term “aldehyde” as used herein is represented by the formula —C(O)H. Throughout this specification “C(O)” is a short hand notation for a carbonyl group, i.e., C═O.

The terms “amine” or “amino” as used herein are represented by the formula —NA¹A², where A¹ and A² can be, independently, hydrogen or alkyl, cycloalkyl, alkenyl, cycloalkenyl, alkynyl, cycloalkynyl, aryl, or heteroaryl group as described herein.

The term “alkylamino” as used herein is represented by the formula —NH(-alkyl) where alkyl is a described herein. Representative examples include, but are not limited to, methylamino group, ethylamino group, propylamino group, isopropylamino group, butylamino group, isobutylamino group, (sec-butyl)amino group, (tert-butypamino group, pentylamino group, isopentylamino group, (tert-pentypamino group, hexylamino group, and the like.

The term “dialkylamino” as used herein is represented by the formula —N(-alkyl)₂ where alkyl is a described herein. Representative examples include, but are not limited to, dimethylamino group, diethylamino group, dipropylamino group, diisopropylamino group, dibutylamino group, diisobutylamino group, di(sec-butyl)amino group, di(tert-butyl)amino group, dipentylamino group, diisopentylamino group, di(tert-pentyl)amino group, dihexylamino group, N-ethyl-N-methylamino group, N-methyl-N-propylamino group, N-ethyl-N-propylamino group and the like.

The term “carboxylic acid” as used herein is represented by the formula —C(O)OH.

The term “ester” as used herein is represented by the formula —OC(O)A¹ or —C(O)OA¹, where A¹ can be alkyl, cycloalkyl, alkenyl, cycloalkenyl, alkynyl, cycloalkynyl, aryl, or heteroaryl group as described herein. The term “polyester” as used herein is represented by the formula —(A¹O(O)C-A²—C(O)O), or —(A¹O(O)C-A²—OC(O))₁—, where A¹and A² can be, independently, an alkyl, cycloalkyl, alkenyl, cycloalkenyl, alkynyl, cycloalkynyl, aryl, or heteroaryl group described herein and “a” is an integer from 1 to 500. “Polyester” is as the term used to describe a group that is produced by the reaction between a compound having at least two carboxylic acid groups with a compound having at least two hydroxyl groups.

The term “ether” as used herein is represented by the formula A¹OA², where A¹ and A² can be, independently, an alkyl, cycloalkyl, alkenyl, cycloalkenyl, alkynyl, cycloalkynyl, aryl, or heteroaryl group described herein. The term “polyether” as used herein is represented by the formula -(A¹O-A²O)ₐ—, where A¹ and A² can be, independently, an alkyl, cycloalkyl, alkenyl, cycloalkenyl, alkynyl, cycloalkynyl, aryl, or heteroaryl group described herein and “a” is an integer of from 1 to 500. Examples of polyether groups include polyethylene oxide, polypropylene oxide, and polybutylene oxide.

The term “halide” as used herein refers to the halogens fluorine, chlorine, bromine, and iodine.

The term “heterocyclyl,” as used herein refers to single and multi-cyclic non-aromatic ring systems and “heteroaryl” as used herein refers to single and multi-cyclic aromatic ring systems: in which at least one of the ring members is other than carbon. The term “heterocyclyl” includes azetidine, dioxane, furan, imidazole, isothiazole, isoxazole, morpholine, oxazole, oxazole, including, 1,2,3-oxadiazole, 1,2,5-oxadiazole and 1,3,4-oxadiazole, piperazine, piperidine, pyrazine, pyrazole, pyridazine, pyridine, pyrimidine, pyrrole, pyrrolidine, tetrahydrofuran, tetrahydropyran, tetrazine, including 1,2,4,5-tetrazine, tetrazole, including 1,2,3,4-tetrazole and 1,2,4,5-tetrazole, thiadiazole, including, 1,2,3-thiadiazole, 1,2,5-thiadiazole, and 1,3,4-thiadiazole, thiazole, thiophene, triazine, including 1,3,5-triazine and 1,2,4-triazine, triazole, including, 1,2,3-triazole, 1,3,4-triazole, and the like.

The term “hydroxyl” as used herein is represented by the formula —OH.

The term “ketone” as used herein is represented by the formula A¹C(O)A², where A¹ and A² can be, independently, an alkyl, cycloalkyl, alkenyl, cycloalkenyl, alkynyl, cycloalkynyl, aryl, or heteroaryl group as described herein.

The term “azide” as used herein is represented by the formula —N₃.

The term “nitro” as used herein is represented by the formula —NO₂.

The term “nitrile” as used herein is represented by the formula —CN.

The term “ureido” as used herein refers to a urea group of the formula —NHC(O)NH₂ or —NHC(O)NH—.

The term “phosphoramide” as used herein refers to a group of the formula —P(O)(NA¹A²)₂, where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “carbamoyl” as used herein refers to an amide group of the formula —CONA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “sulfamoyl” as used herein refers to a group of the formula —S(O)₂NA¹A², where A¹ and A² can be, independently, hydrogen or an alkyl, cycloalkyl, alkoxy, alkenyl, cycloalkenyl, alkynyl, cycloalkynyl, aryl, or heteroaryl group as described herein.

The term “silyl” as used herein is represented by the formula —SiA 1A²A³, where A¹, A², and A³ can be, independently, hydrogen or an alkyl, cycloalkyl, alkoxy, alkenyl, cycloalkenyl, alkynyl, cycloalkynyl, aryl, or heteroaryl group as described herein.

The term “sulfo-oxo” as used herein is represented by the formulas —S(O)A¹, —S(O)₂A¹, —OS(O)₂A¹, or —OS(O)₂OA¹, where A¹ is hydrogen or an alkyl, cycloalkyl, alkenyl, cycloalkenyl, alkynyl, cycloalkynyl, aryl, or heteroaryl group as described herein. Throughout this specification “S(O)” is a short hand notation for S═O. The term “sulfonyl” is used herein to refer to the sulfo-oxo group represented by the formula —S(O)₂A¹, where A¹ is hydrogen or an alkyl, cycloalkyl, alkenyl, cycloalkenyl, alkynyl, cycloalkynyl, aryl, or heteroaryl group as described herein. The term “sulfone” as used herein is represented by the formula A¹S(O)2A², where A¹ and A² can be, independently, an alkyl, cycloalkyl, alkenyl, cycloalkenyl, alkynyl, cycloalkynyl, aryl, or heteroaryl group as described herein. The term “sulfoxide” as used herein is represented by the formula A′S(O)A², where A¹and A² can be, independently, an alkyl, cycloalkyl, alkenyl, cycloalkenyl, alkynyl, cycloalkynyl, aryl, or heteroaryl group as described herein.

The term “thiol” as used herein is represented by the formula —SH.

The term “polymeric” includes polyalkylene, polyether, polyester, and other groups with repeating units, such as, but not limited to —(CH₂O)ₙ—CH₃, —(CH₂CH₂O)ₙ—CH₃, —[CH₂CH(CH₃)]ₙ—CH₃, —[CH₂CH(COOCH₃)]ₙ—CH₃, —[CH₂CH(COOCH₂CH₃)]ₙ—CH₃, and —[CH₂CH(COO^{t}Bu)]ₙ—CH₃, where n is an integer (e.g., n>1 or n>2).

“R,” “R¹,” “R²,” “R³,” “Rⁿ,” where n is an integer, as used herein can, independently, include hydrogen or one or more of the groups listed above. For example, if R¹ is a straight chain alkyl group, one of the hydrogen atoms of the alkyl group can optionally be substituted with a hydroxyl group, an alkoxy group, an alkyl group, a halide, and the like. Depending upon the groups that are selected, a first group can be incorporated within a second group or, alternatively, the first group can be pendant (i.e., attached) to the second group. For example, with the phrase “an alkyl group comprising an amino group,” the amino group can be incorporated within the backbone of the alkyl group. Alternatively, the amino group can be attached to the backbone of the alkyl group. The nature of the group(s) that is (are) selected will determine if the first group is embedded or attached to the second group.

As described herein, compounds of the disclosure may contain “optionally substituted” moieties. In general, the term “substituted,” whether preceded by the term “optionally” or not, means that one or more hydrogens of the designated moiety are replaced with a suitable substituent. Unless otherwise indicated, an “optionally substituted” group may have a suitable substituent at each substitutable position of the group, and when more than one position in any given structure may be substituted with more than one substituent selected from a specified group, the substituent may be either the same or different at every position. Combinations of substituents envisioned by this disclosure are preferably those that result in the formation of stable or chemically feasible compounds. It is also contemplated that, in certain aspects, unless expressly indicated to the contrary, individual substituents can be further optionally substituted (i.e., further substituted or unsubstituted).

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

In some aspects, a structure of a compound can be represented by a formula:

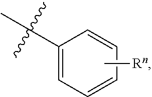

which is understood to be equivalent to a formula:

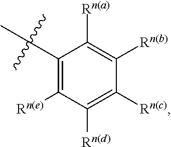

wherein n is typically an integer. That is, Rₙ is understood to represent five independent substituents, R^{n(a)}, R^{n(b)}, R^{n(c)}, R^{n(d)}, Rₙ₍ₑ₎. By “independent substituents,” it is meant that each R substituent can be independently defined. For example, if in one instance R^{n(a)} is halogen, then R^{n(b)} is not necessarily halogen in that instance.

Several references to R, R¹, R², R³, R⁴, R⁵, R⁶, etc. are made in chemical structures and moieties disclosed and described herein. Any description of R, R′, _{R}2_{, R}3_{, R}4_{,} R⁵, R⁶, etc. in the specification is applicable to any structure or moiety reciting R, R¹, R², R³, R⁴, R⁵, R⁶, etc. respectively.

Compounds disclosed herein are suited for use in a wide variety of optical and electro-optical devices, including, but not limited to, photo-absorbing devices such as solar- and photo-sensitive devices, organic light emitting devices (OLEDs), photo-emitting devices, or devices capable of both photo-absorption and emission and as markers for bio-applications.

The compounds disclosed herein are useful in a variety of applications. As light emitting materials, the compounds can be useful in organic light emitting devices (OLEDs), luminescent devices and displays, and other light emitting devices.

In another aspect, the compounds can provide improved efficiency, improved operational lifetimes, or both in lighting devices, such as, for example, organic light emitting devices, as compared to conventional materials.

The compounds of the disclosure can be made using a variety of methods, including, but not limited to any recited in the examples provided herein.

A formulation that comprises any compound disclosed herein is described. The formulation can include one or more components selected from the group consisting of a solvent, a phosphorescent and/or fluorescent emitter, a host, a hole injection material, hole transport material, and/or an electron transport layer material, disclosed herein.

### Compositions and Devices

Disclosed herein are organic emitting diodes or light emitting devices comprising one or more compound and/or compositions disclosed herein.

In one aspect, the present invention relates to a white organic light emitting device comprising:

a first emissive layer comprising a phosphorescent emitter;

a second emissive layer comprising a fluorescent emitter; and

an interface layer, disposed between the first emissive layer and the second emissive layer;

wherein the interface layer comprises a high energy gap material represented by Formula I, Formula II, or Formula III:

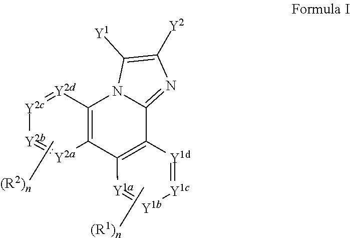

wherein in Formula I:

Y^{1a}, Y^{1b}, Y^{1c}, Y^{1d}, Y^{2a}, Y^{2b}, Y^{2c}, Y^{2d}, each independently represents C or N; wherein at least two of Y^{1a}, Y^{1b}, Y^{1c}, Y^{1d}, Y^{2a}, Y^{2b}, Y^{2c}, and Y^{2d} represented N;

Y¹ and Y² independently represent hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; Y¹ and Y² may together form a ring which is optionally further studied;

R¹ and R² are independently absent or present, valency permitting, and each R¹ and R² independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; any two adjacent R¹ and R² may together form a ring; and

each n is an integer, valency permitting;

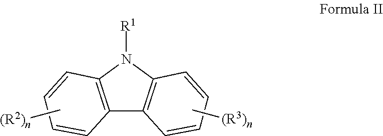

wherein in Formula II:

Each of R¹, R², and R³ is independently absent or present as a single substituent or multiple substituents, valency permitting, and each R¹, R², and R³ present independently represents hydrogen, deuterium, halogen, hydroxyl, thiol, nitro, cyanide, isocyanide, sulfinyl, mercapto, sulfo, carboxyl, hydrazino; substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; and

each n is an integer, valency permitting;

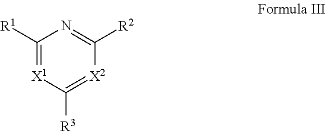

wherein in Formula III:

each of X¹ and X² is independently N or C—R⁴.

each of R¹, R², R³, and R⁴ independently represents hydrogen, deuterium, halogen, hydroxyl, thiol, nitro, cyanide, isocyanide, sulfinyl, mercapto, sulfo, carboxyl, hydrazino; substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof

In one embodiment, the high energy gap material is represented by Formula I. In one embodiment, the high energy gap material is represented by Formula II. In one embodiment, the high energy gap material is represented by Formula III.

In one embodiment, in Formula I, at least one of Y^{1a}, Y^{1b}, Y^{1c}, and Y^{1d} is N, and at least one of Y^{2a}, Y^{2b}, Y^{2c}, and Y^{2d} is N.

In one embodiment, in Formula I, Y¹ and Y² are each selected from the group consisting of alkyl, aryl, heteroaryl, and combinations thereof.

In one embodiment, the high energy gap material is selected from the group consisting of:

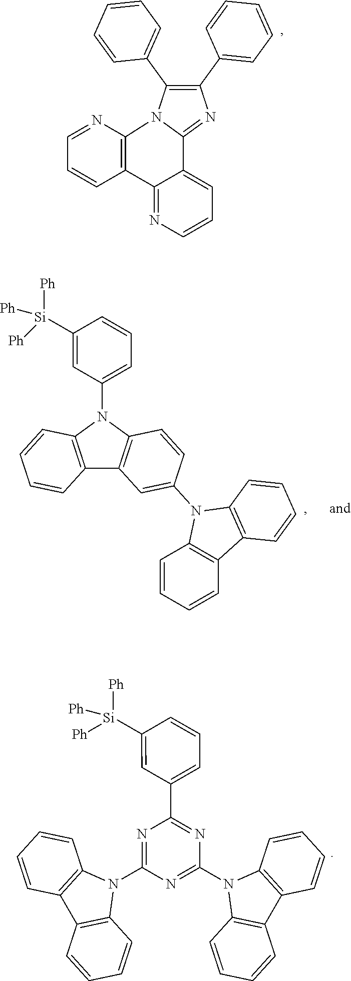 [SMILES: c1ccc(-c2nc3c4cccnc4c4cccnc4n3c2-c2ccccc2)cc1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

In one embodiment, the fluorescent emitter harvests singlet excitons and emits blue light; and wherein the phosphorescent emitter harvests triplet excitons and emits yellow-amber light.

In one embodiment, the interface layer further comprises a compound of Formula A:

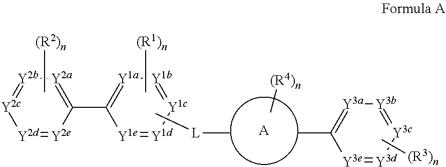

wherein

ring A is a fused polycyclic aryl or heteroaryl rings having at least 14 atoms selected from the group consisting of C and N;

Y^{1a}, Y^{1b}, Y^{1c}, Y^{1d}, Y^{1e}, Y^{2a}, Y^{2b}, Y^{2c}, Y^{2d}, Y^{2e}, Y^{3a}, Y^{3b}, Y^{3c}, Y^{3d}, and Y^{3e} each independently represents C or N;

Y^{1a} and Y^{2a} are optionally linked via linking atom Z, wherein Z represents O, S, Se, NR⁴, P═O, As═O, BR⁴, AlR⁴, Bi═O, CR⁴R⁵, C═O, SiR⁴R⁵, GeR⁴R⁵, PR⁴, PR⁴R⁵, R⁴P═O, AsR⁴, R⁴As═O, S═O, SO₂, Se═O, SeO₂, BR⁴R⁵, AlR⁴, AlR⁴R⁵, R⁴Bi═O, or BiR⁴;

L is a divalent linking group selected from the group consisting of a covalent bond, O, S, Se, alkylene, monoalkylamine, monoarylamine, monoheteroarylamine, arylene, heteroarylene, and combinations thereof; wherein L forms a bond with ring A and with one of Y^{1a}, Y^{1b}, Y^{1c}, Y^{1d}, or Y^{1e}; or L is a trivalent linking atom selected from the group consisting of B, N, P, CR⁴, SiR⁴, Al, GeR⁴, PR⁴, P═O, As, As═O, BR⁴, AlR⁴, Bi, and Bi═O, wherein L forms one bond with ring A, one bond with Y^{1a}, and one bond with Y^{2a};

R¹, R², R³, and R⁴ each independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;

any two adjacent R¹, R², R³, and R⁴ may together form a fused ring; and

each n is independently an integer, valency permitting.

In one embodiment, the compound of Formula A has one of the following structures:

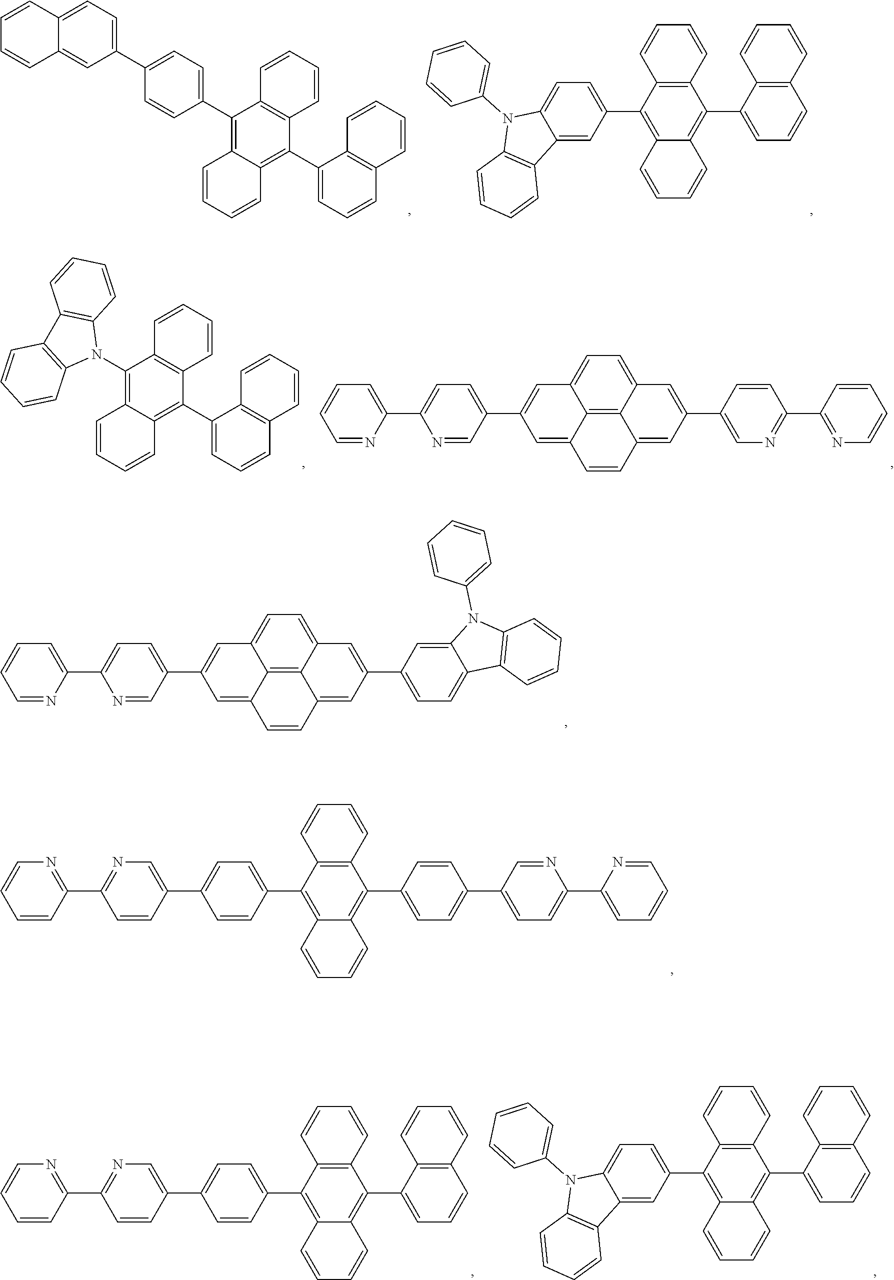

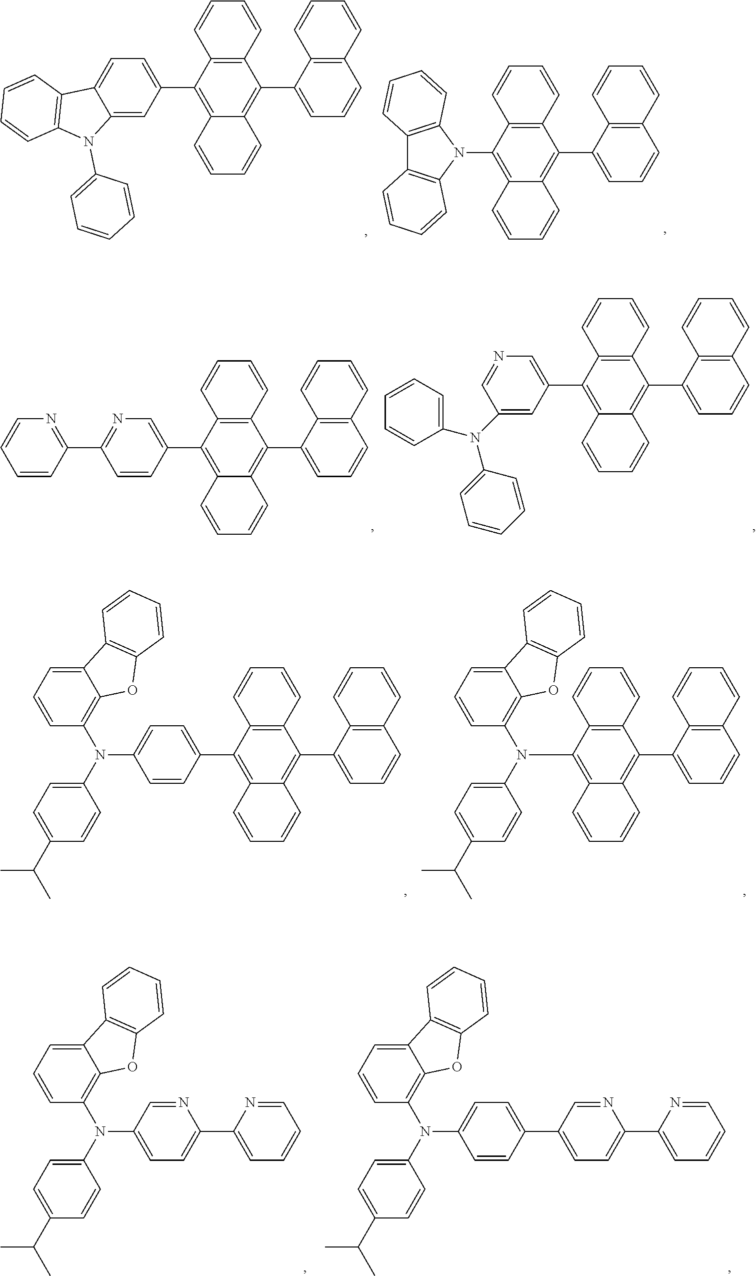

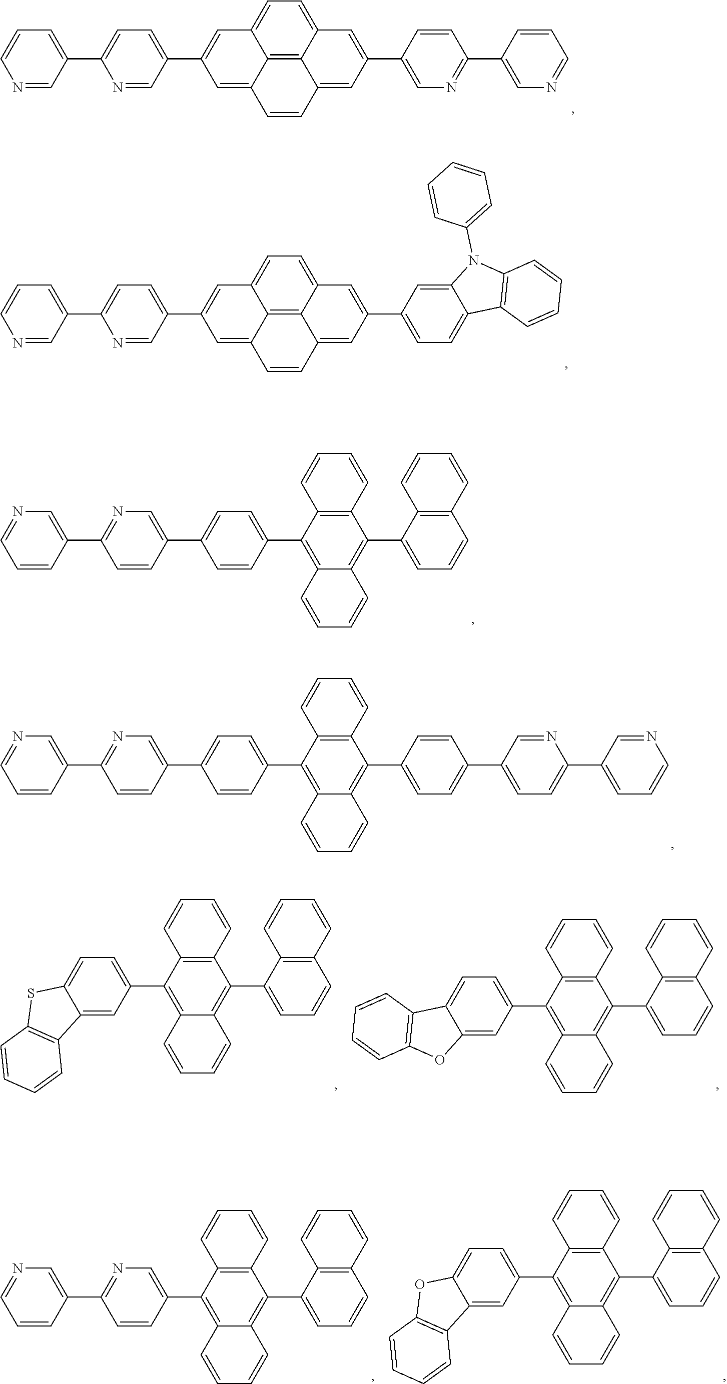

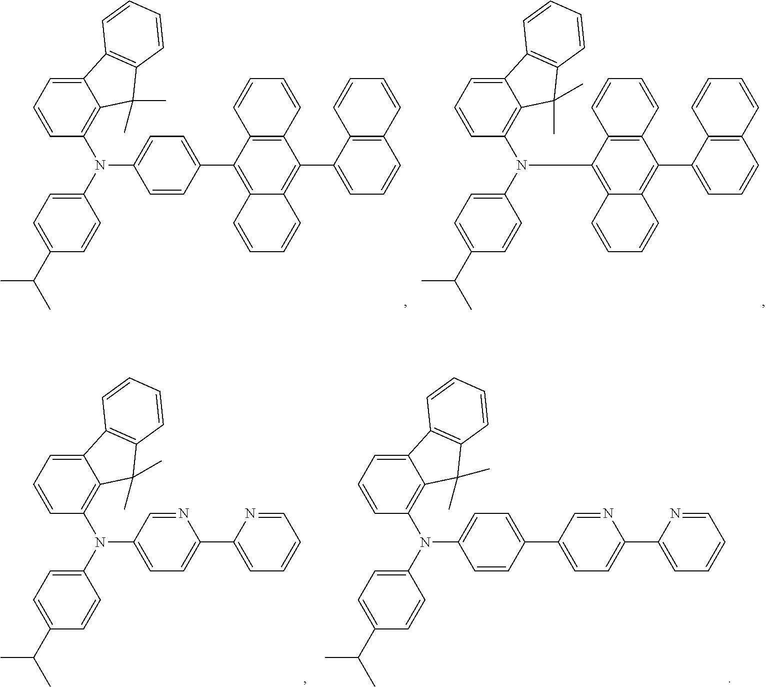 [SMILES: CC(C)c1ccc(N(c2ccc(-c3c4ccccc4c(-c4cccc5ccccc45)c4ccccc34)cc2)c2cccc3c2C(C)(C)c2ccccc2-3)cc1 ; CC(C)c1ccc(N(c2cccc3c2C(C)(C)c2ccccc2-3)c2c3ccccc3c(-c3cccc4ccccc34)c3ccccc23)cc1 ; CC(C)c1ccc(N(c2ccc(-c3ccccn3)nc2)c2cccc3c2C(C)(C)c2ccccc2-3)cc1 ; CC(C)c1ccc(N(c2ccc(-c3ccc(-c4ccccn4)nc3)cc2)c2cccc3c2C(C)(C)c2ccccc2-3)cc1]

In one embodiment, the molar ratio or the weight ratio between the compound of Formula I, Formula II, or Formula III and the compound of Formula A is between about 5:1 to about 1:5. In one embodiment, the molar ratio or the weight ratio between the compound of Formula I, Formula II, or Formula III and the compound of Formula A is about 1:4, about 1:1, or about 4:1.

In one embodiment, the weight ratio between the compound of Formula I, Formula II, or Formula III and the compound of Formula A is between about 5:1 to about 1:5. In one embodiment, the weight ratio between the compound of Formula I, Formula II, or Formula III and the compound of Formula A is about 1:4, about 1:1, or about 4:1.

The device of claim 5, wherein the interface layer has a thickness of about 2 to about 5 nm.

In one embodiment, the phosphorescent emitter is an excimer emitter. In one embodiment, the phosphorescent emitter is a square planar complex. In one embodiment, the phosphorescent emitter is a tetradentate platinum or palladium complex.

In one embodiment, the phosphorescent emitter emits light in the range of about 480 nm to about 700 nm. In one embodiment, the phosphorescent emitter emits yellow, amber, or orange light.

In one embodiment, the phosphorescent emitter is a compound of Formula X:

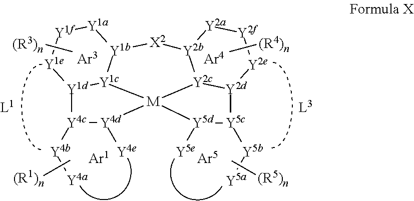

wherein, in Formula X:

M represents Pt(II) or Pd(II);

R¹, R³, R⁴, and R⁵ each independently represents hydrogen, halogen, hydroxyl, nitro, cyanide, thiol, or optionally substituted C₁-C₄ alkyl, alkoxy, amino, or aryl;

each n is independently an integer, valency permitting;

Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;

X² represents NR, PR, CRR′, SiRR′, CRR′, SiRR′, O, S═O, O═S═O, Se, Se═O, or O═Se═O, wherein R and R′ each independently represents hydrogen, halogen, hydroxyl, nitro, cyanide, thiol, or optionally substituted C₁-C₄ alkyl, alkoxy, amino, aryl, or heteroaryl;

each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;

Ar³ and Ar⁴ each independently represents a 6-membered aryl group; and

Ar¹ and Ar⁵ each independently represents a 5- to 10-membered aryl, heteroaryl, fused aryl, or fused heteroaryl.

In one embodiment, M represents Pd(II).

In one embodiment, the phosphorescent emitter is represented by one of the following compounds:

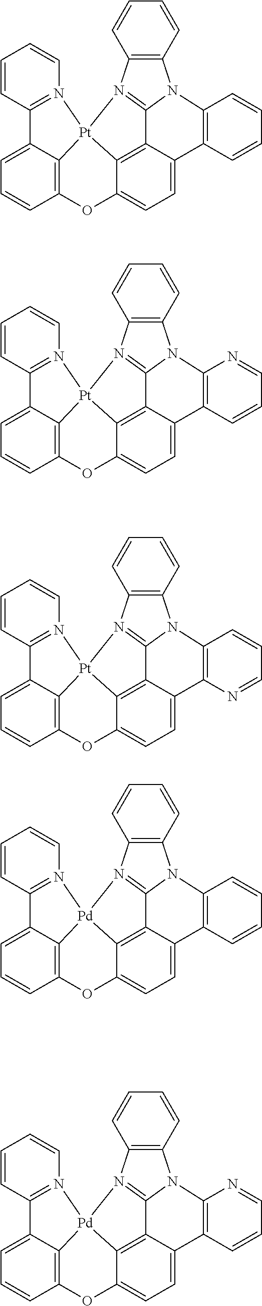

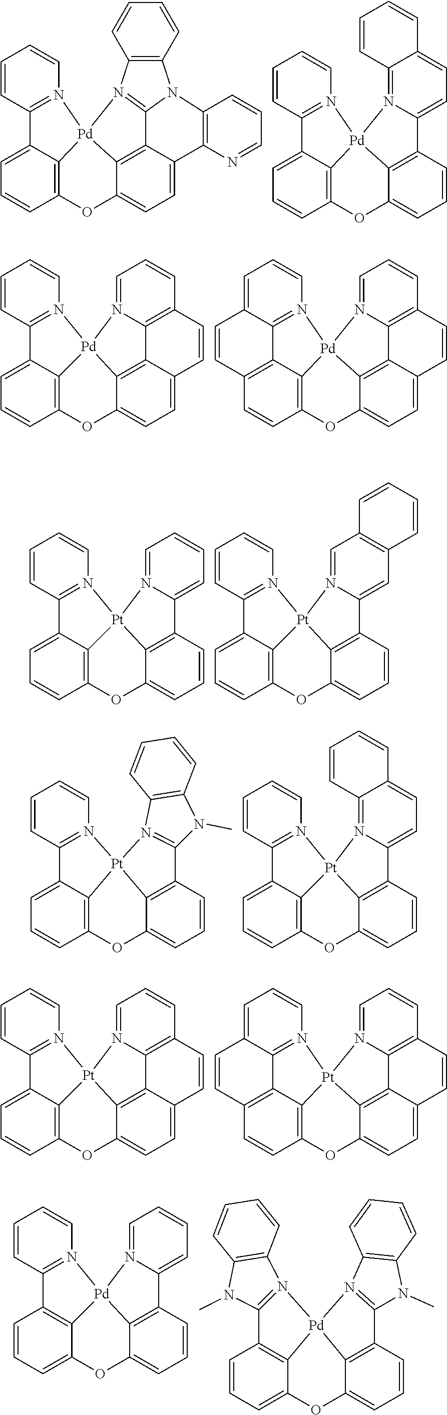

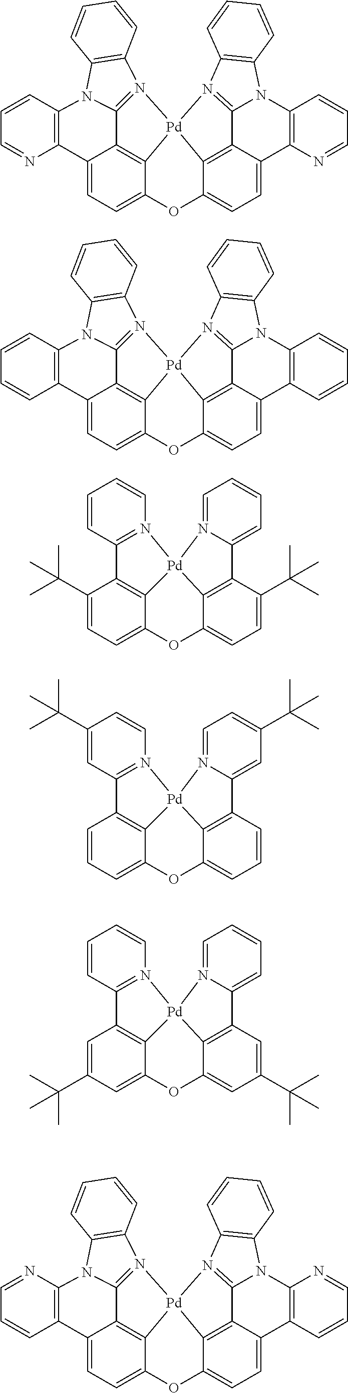

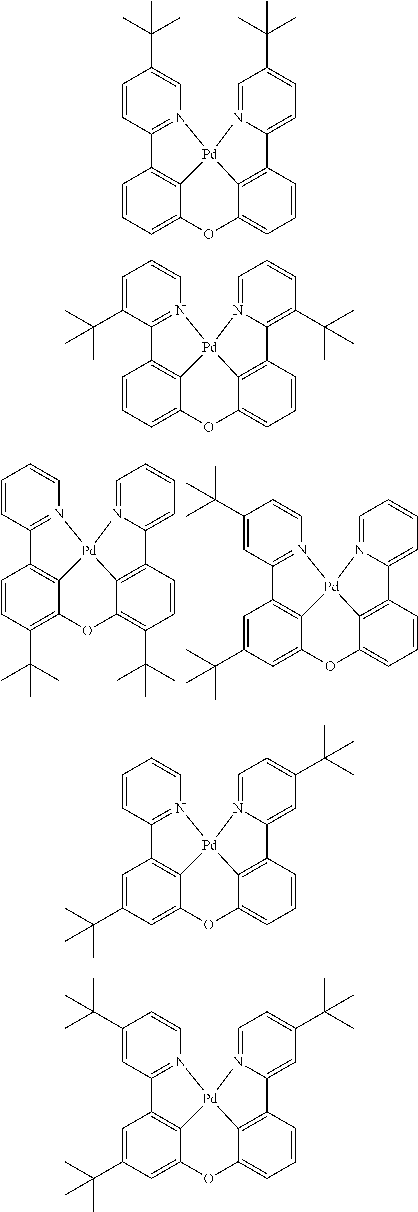

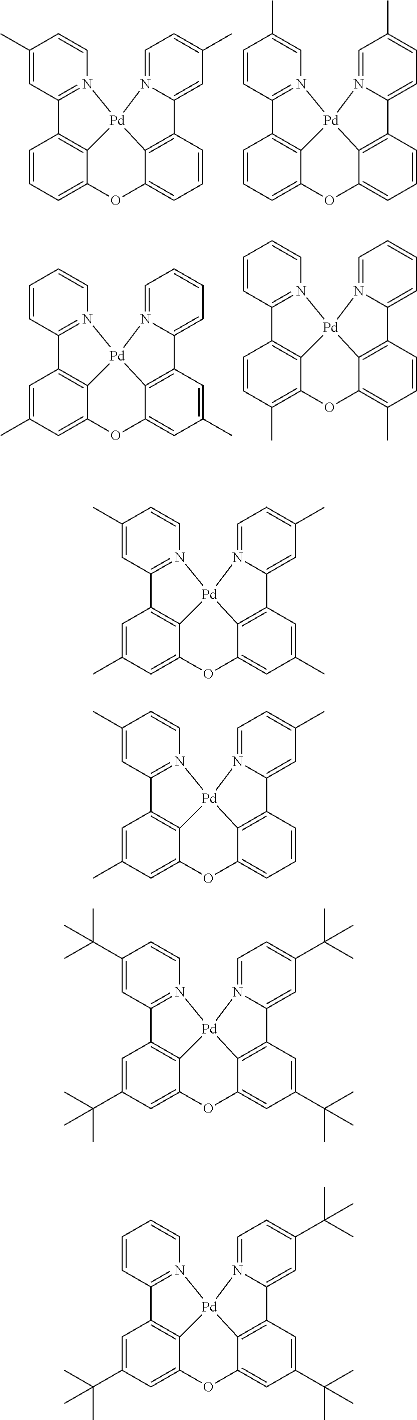

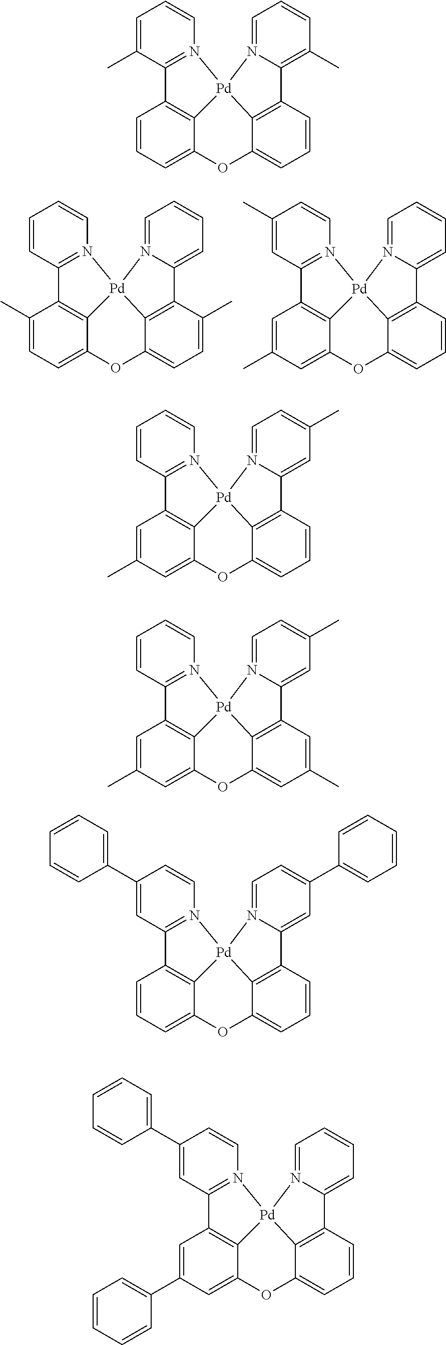

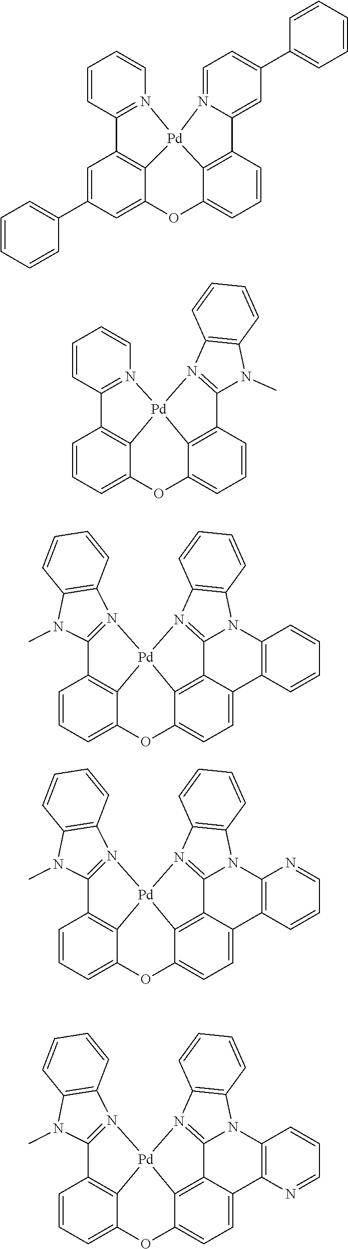

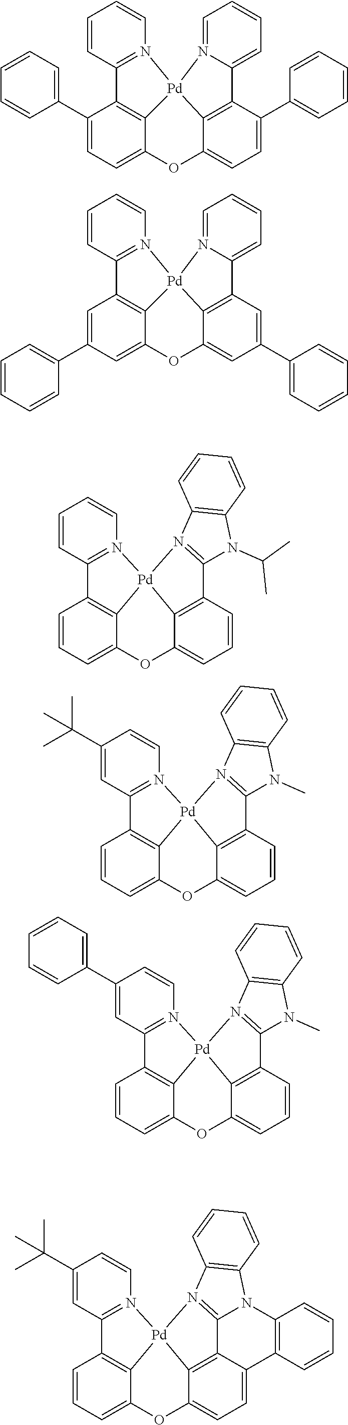

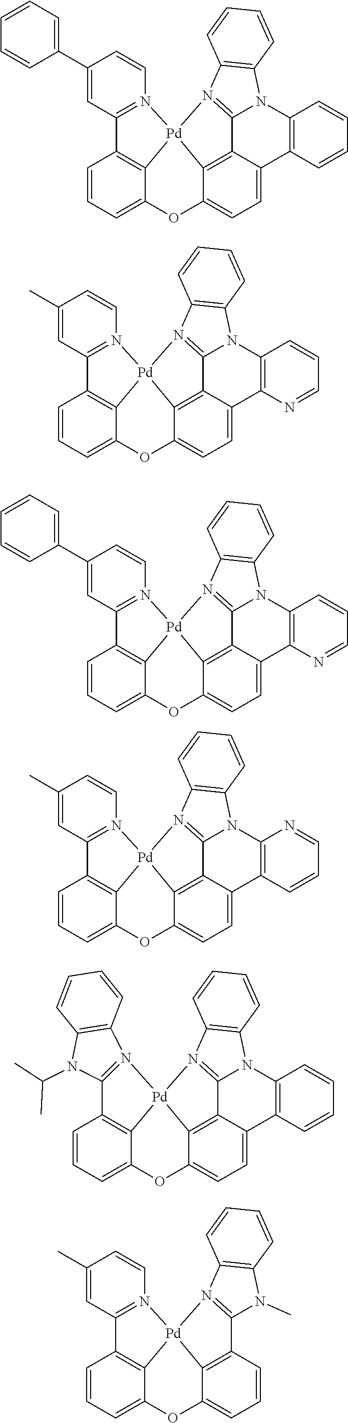

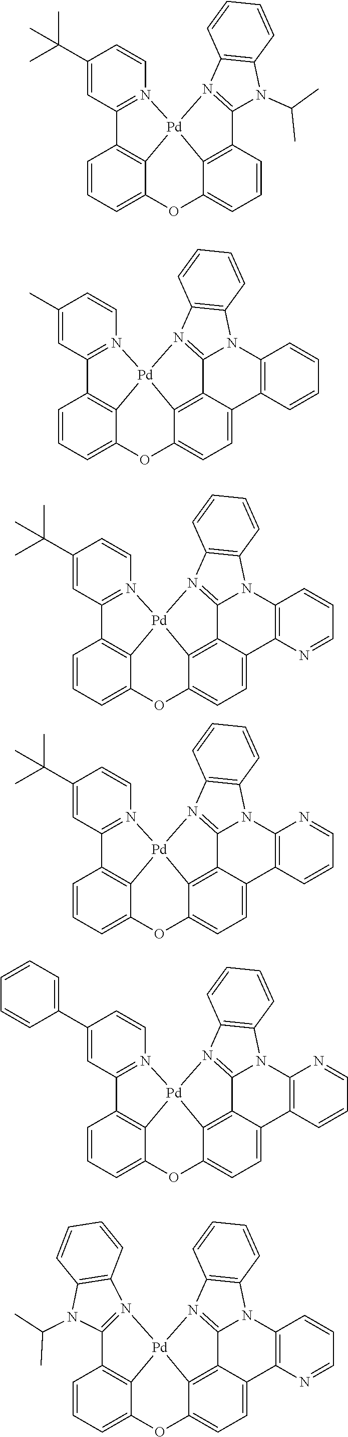

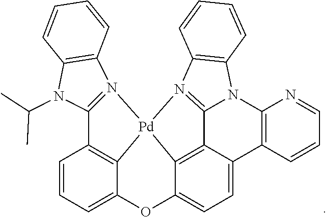

In one embodiment, the fluorescent emitter comprises one of the following compounds:
1. Aromatic Hydrocarbons and Their Derivatives

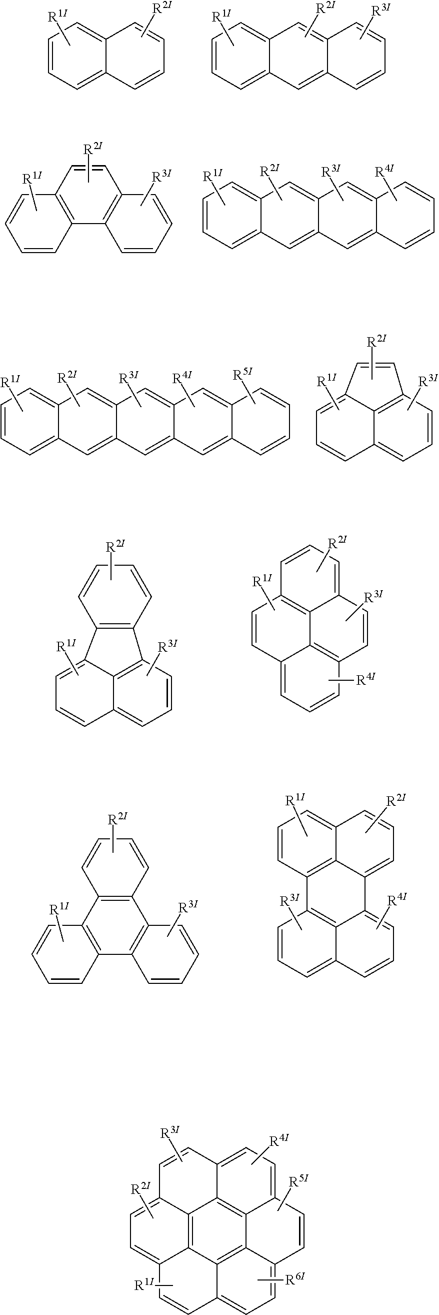

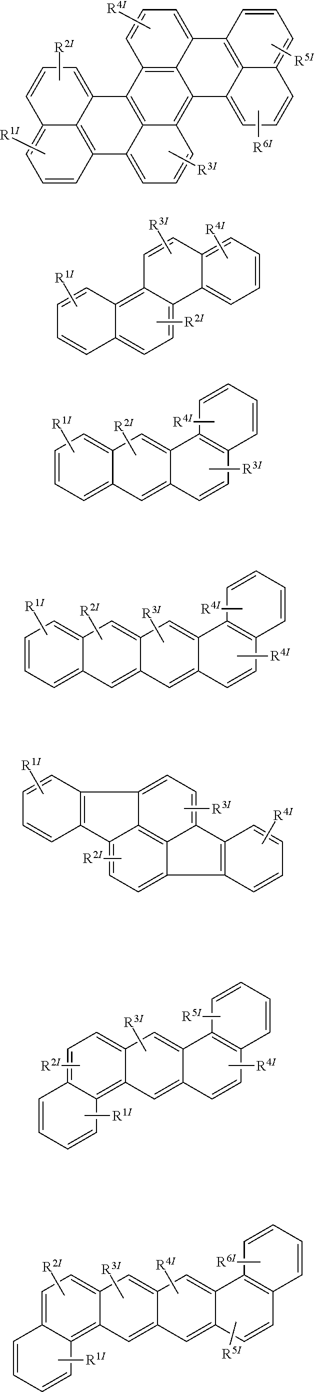

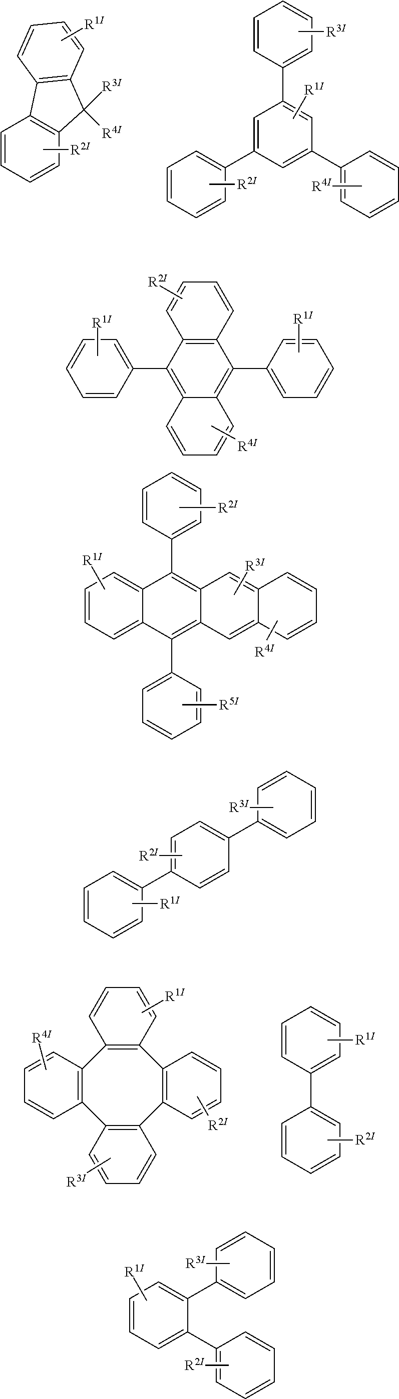

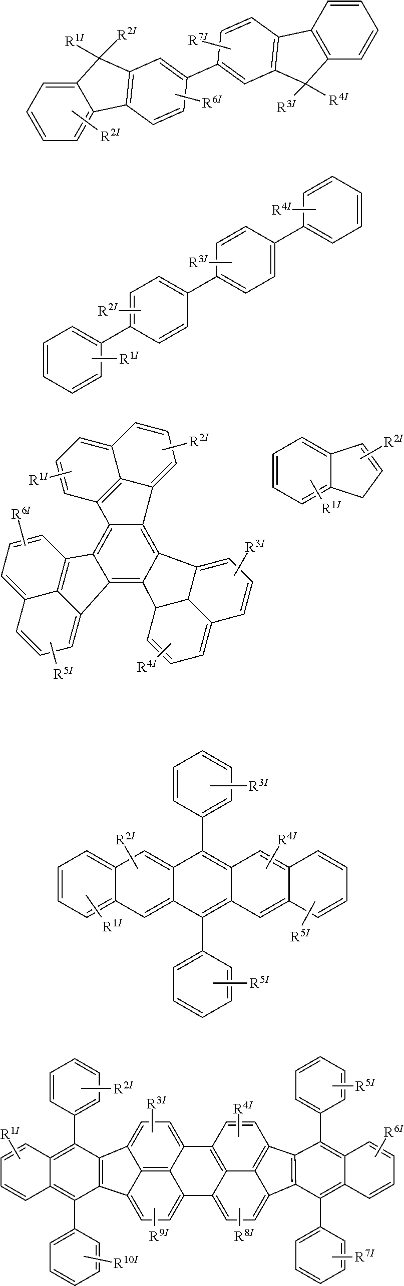

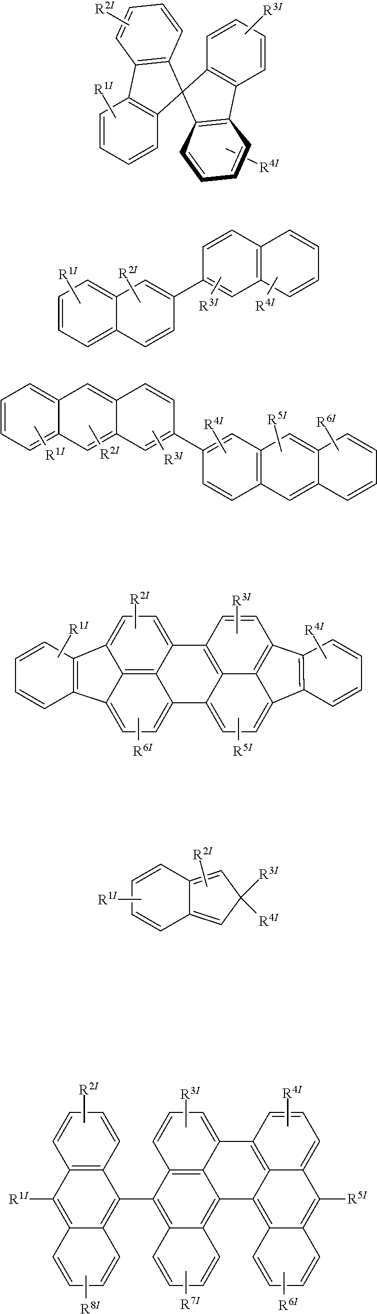

2. Arylethylene, Arylacetylene and Their Derivatives

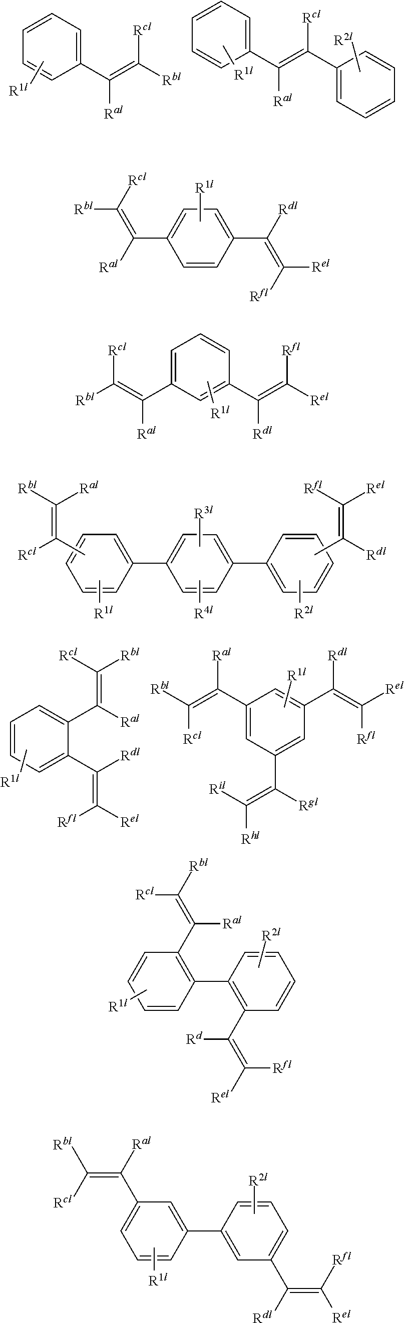

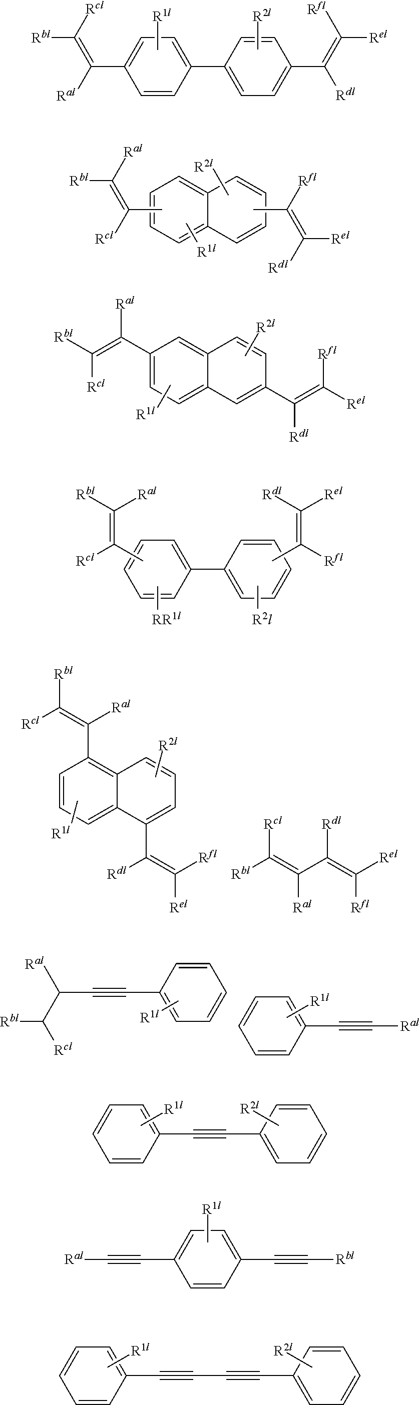

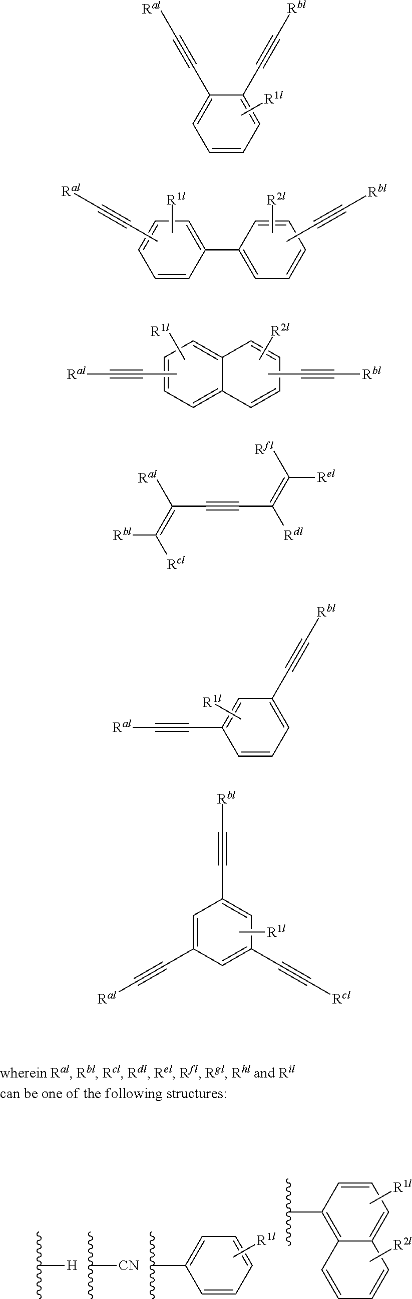

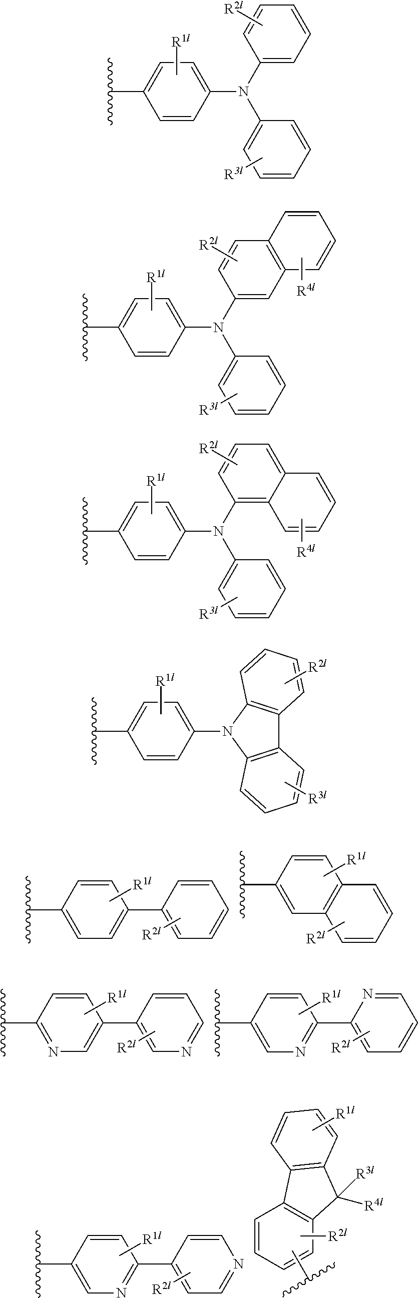

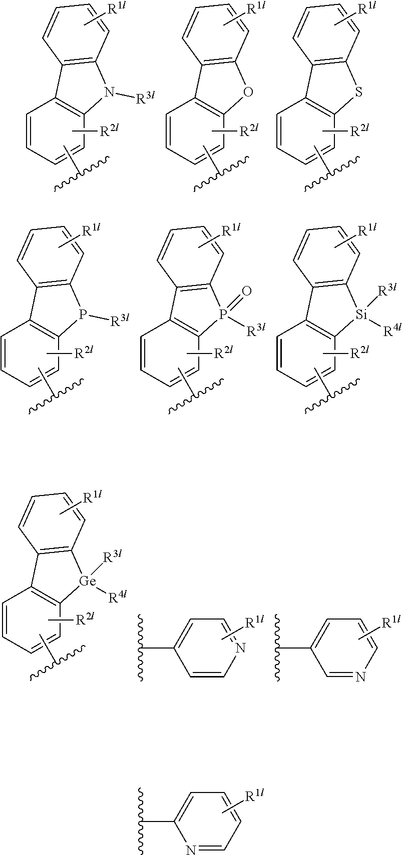

3. Heterocyclic Counpounds and Their Derivatives

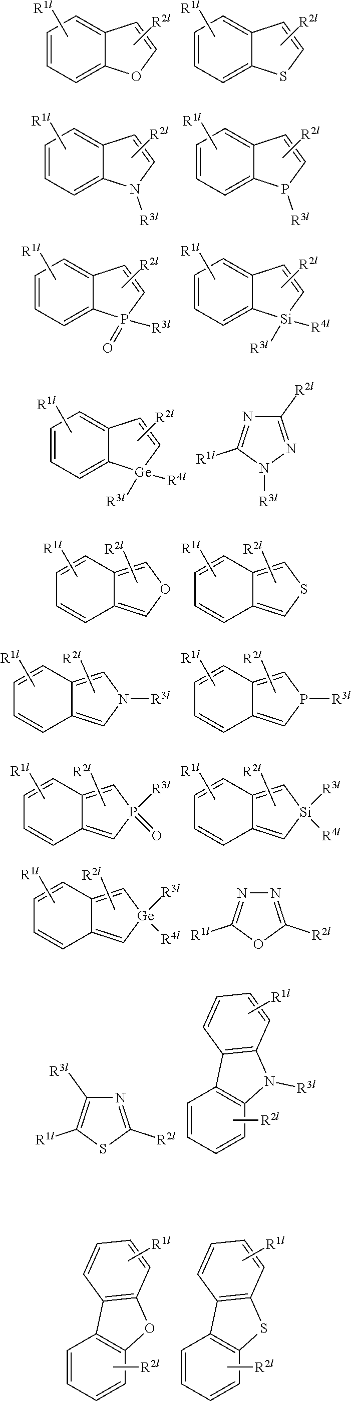

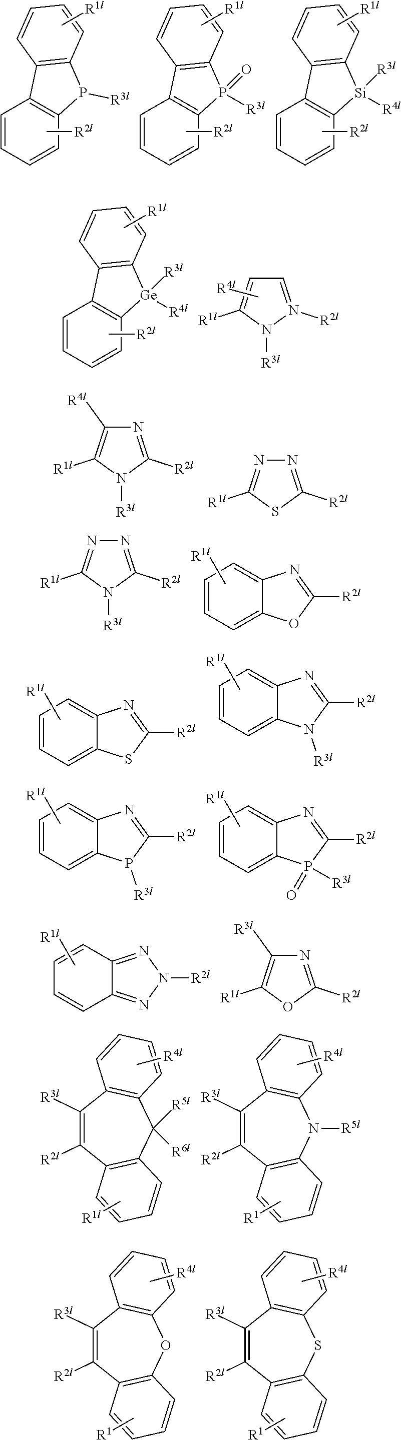

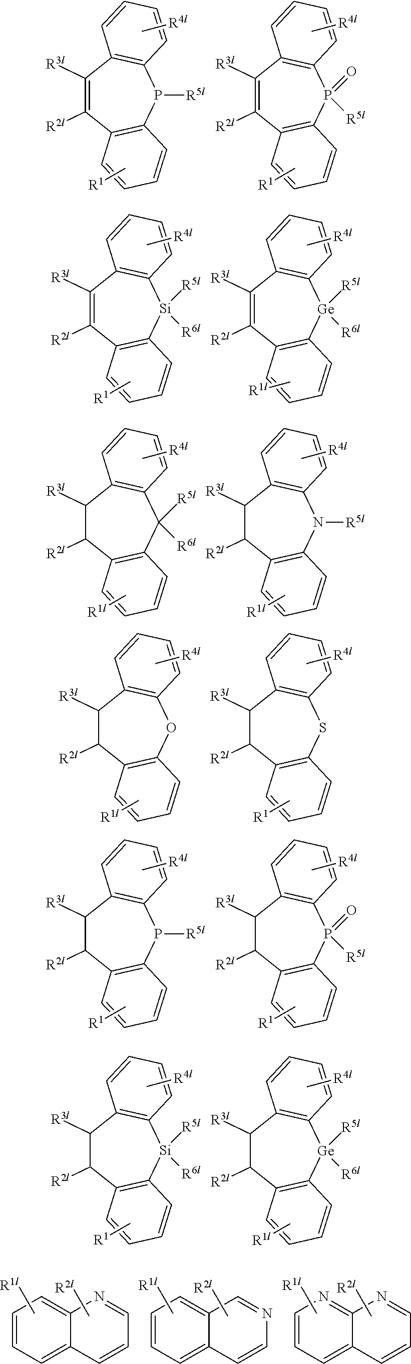

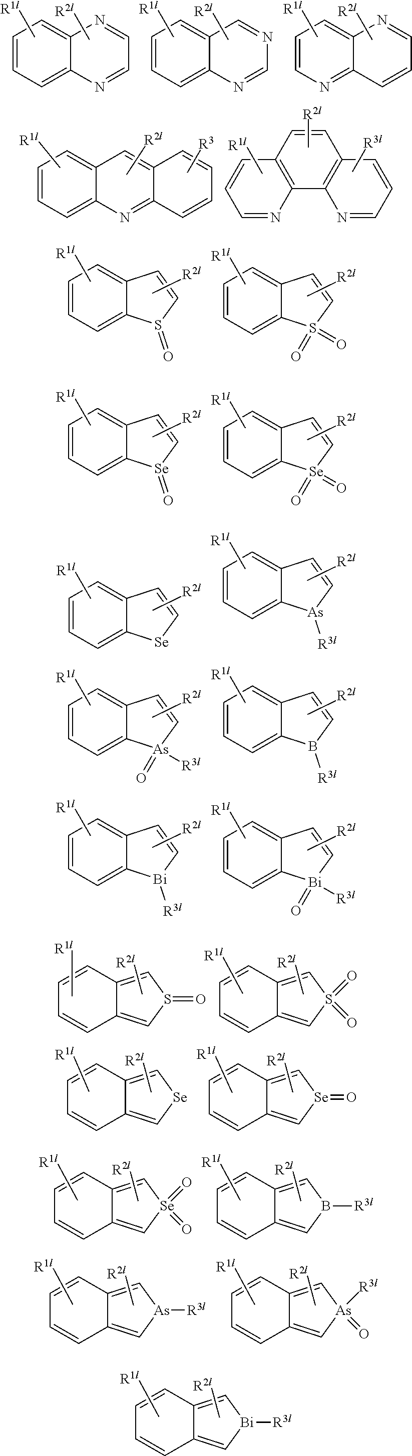

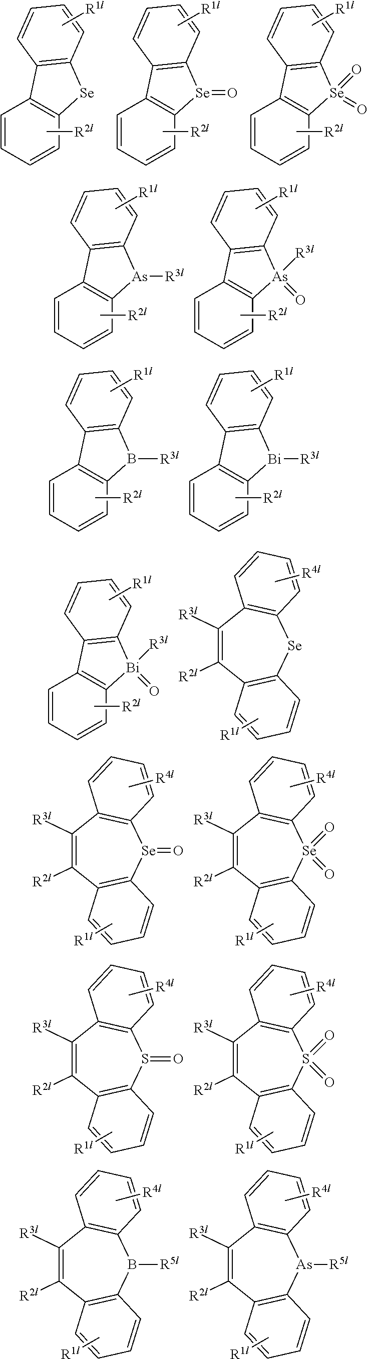

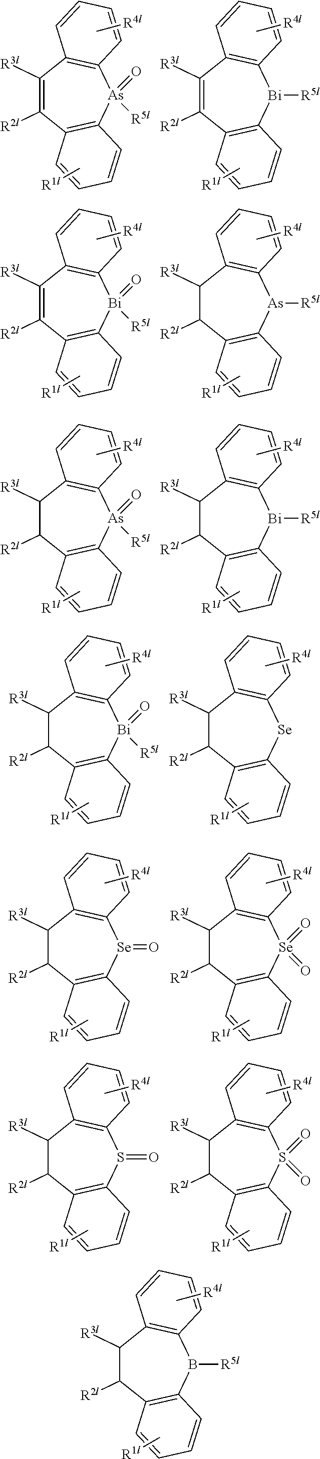

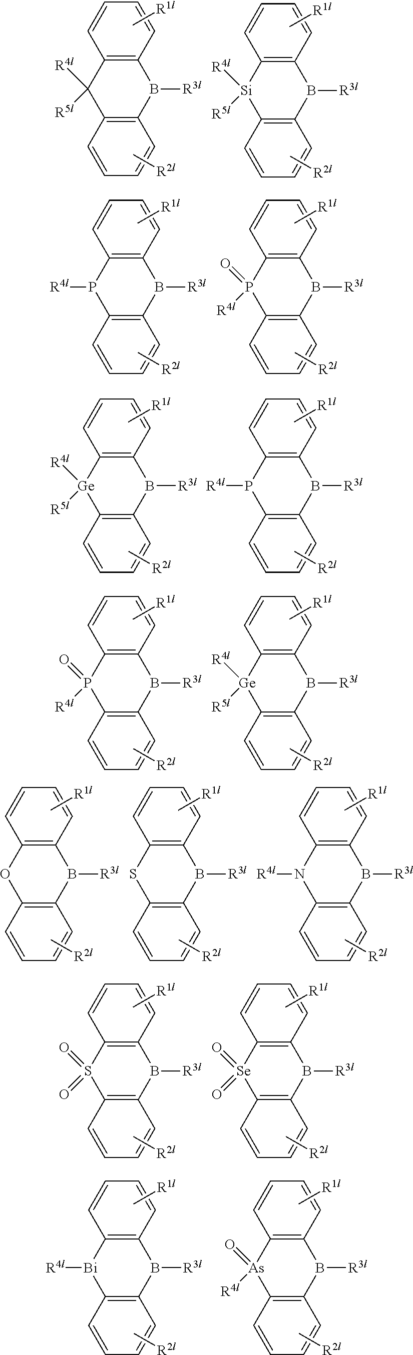

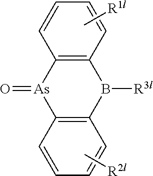

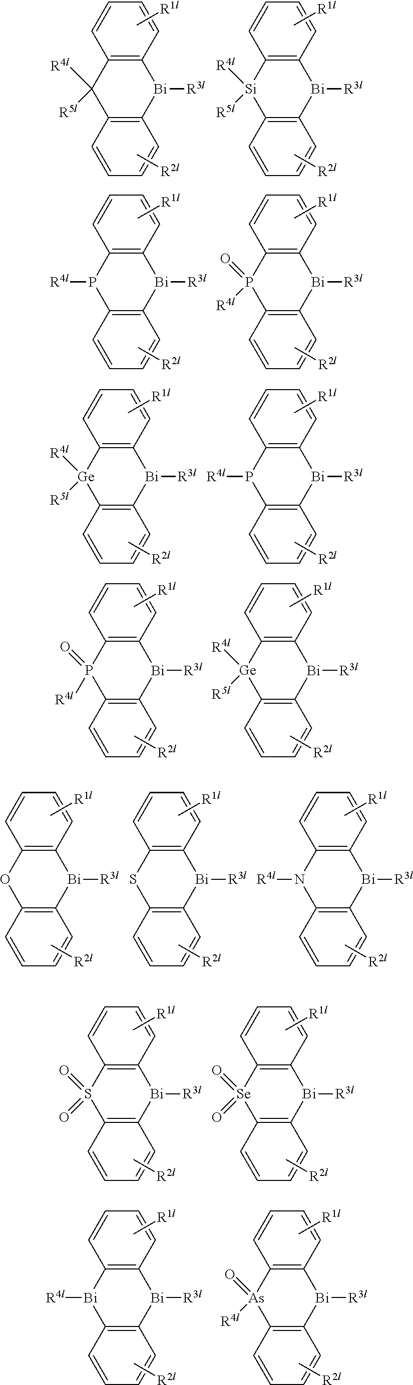

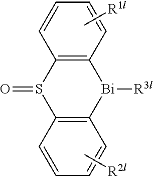

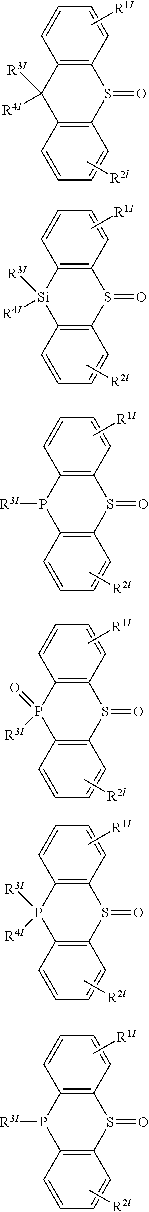

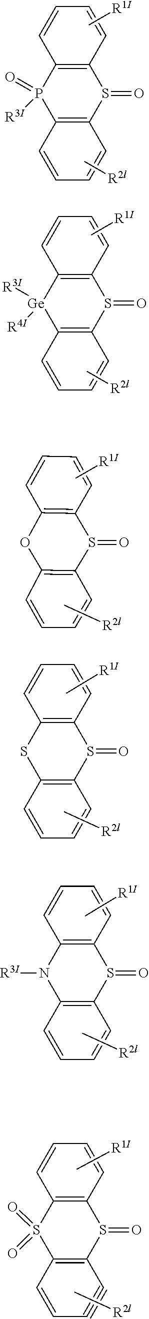

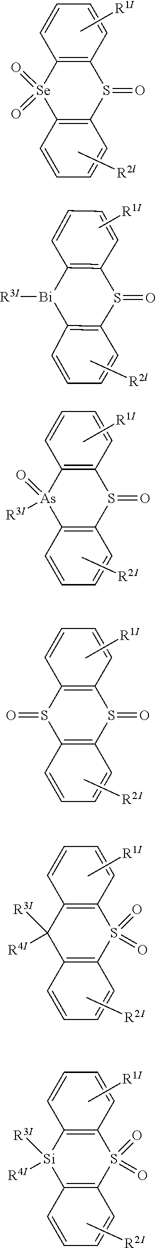

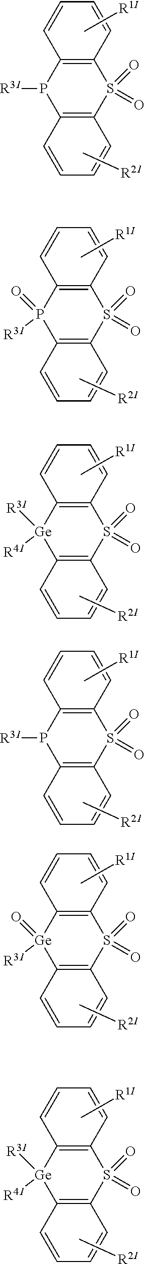

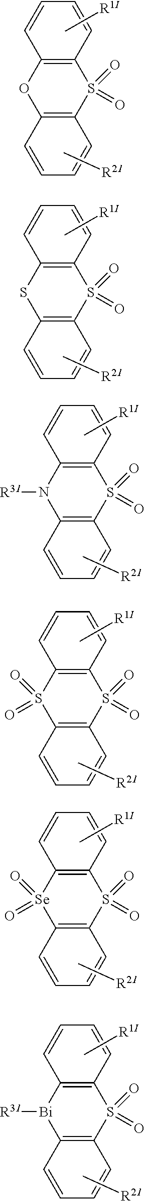

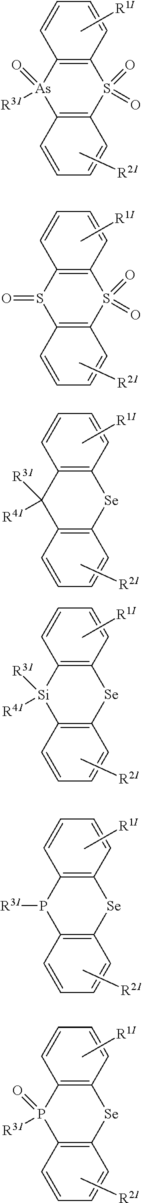

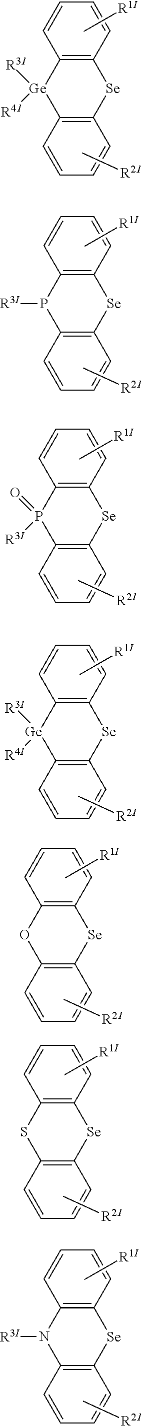

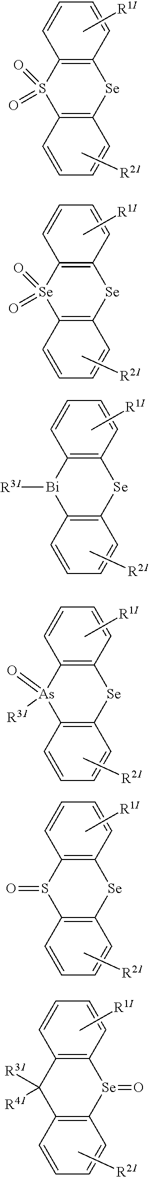

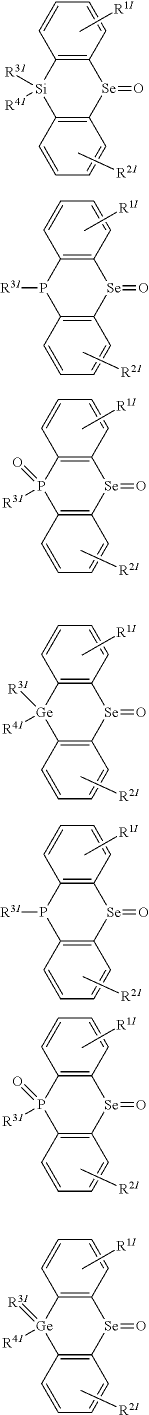

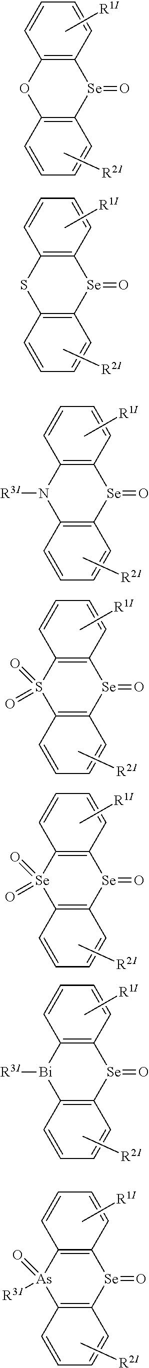

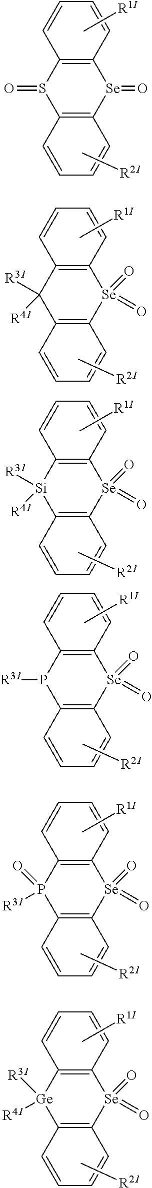

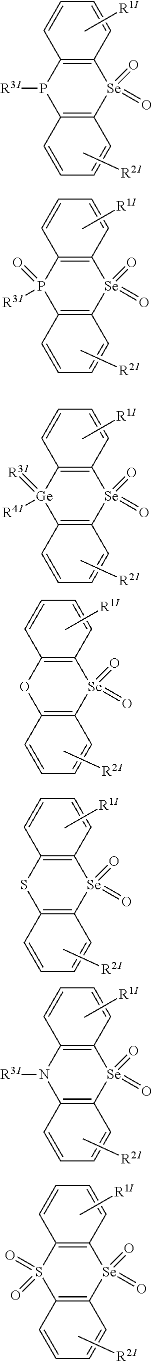

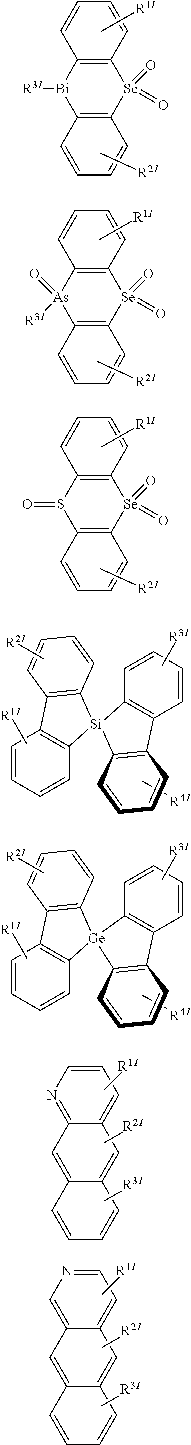

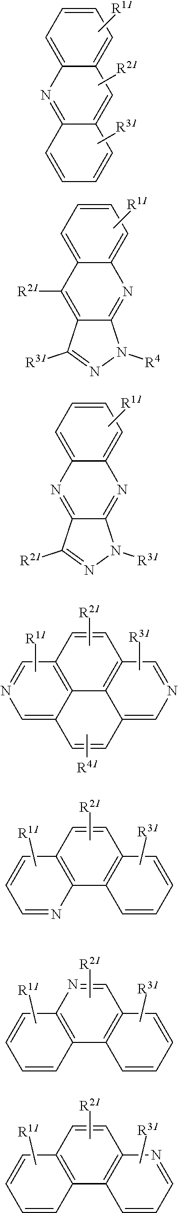

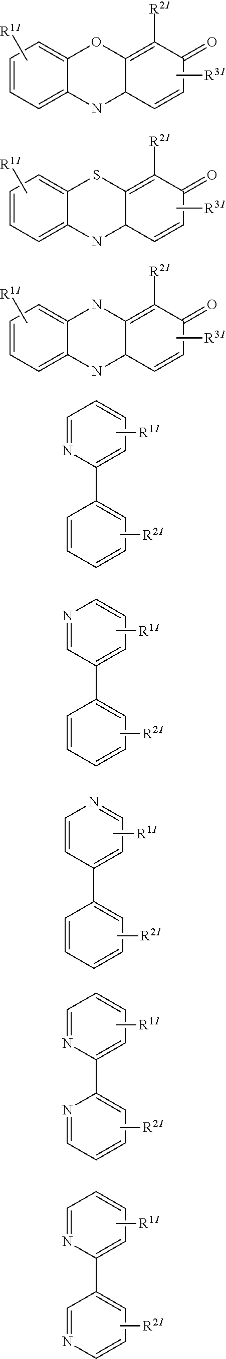

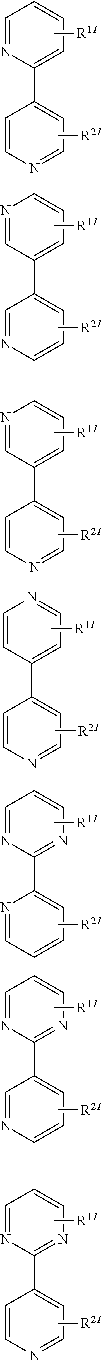

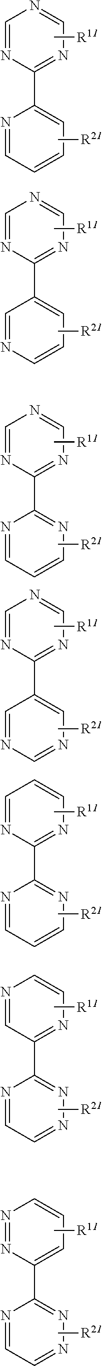

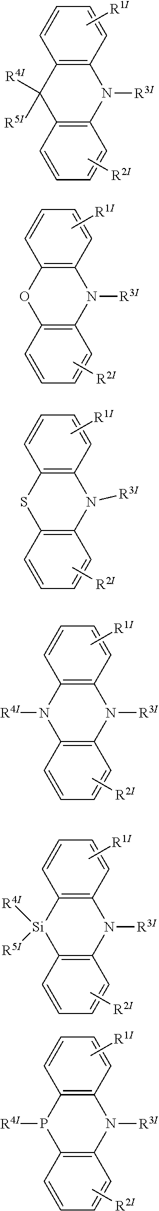

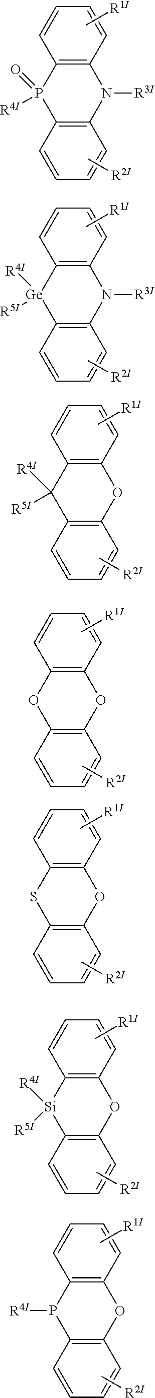

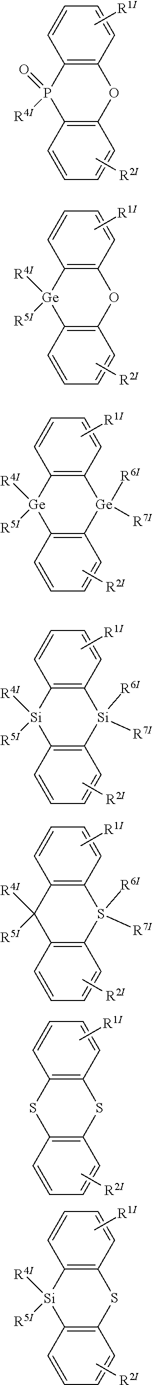

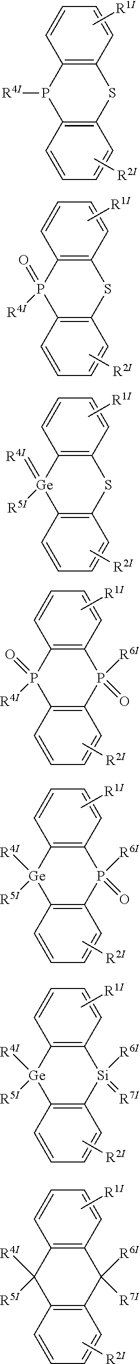

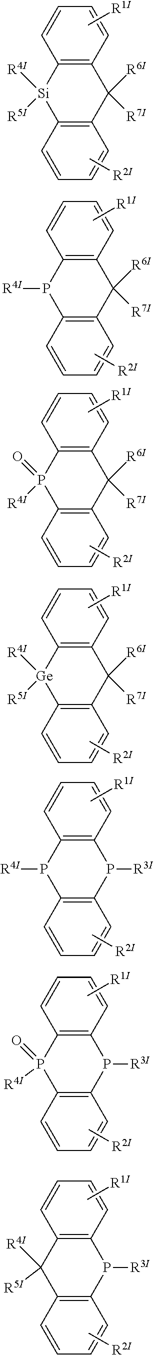

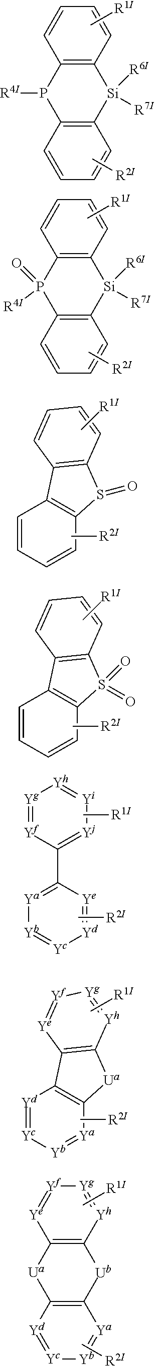

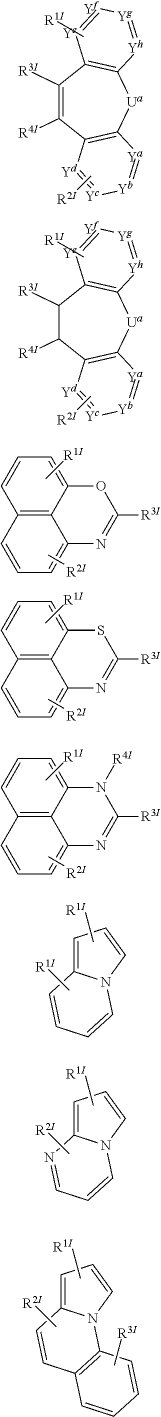

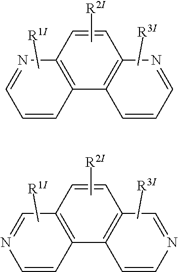

4. Other Fluorescent Luminophors

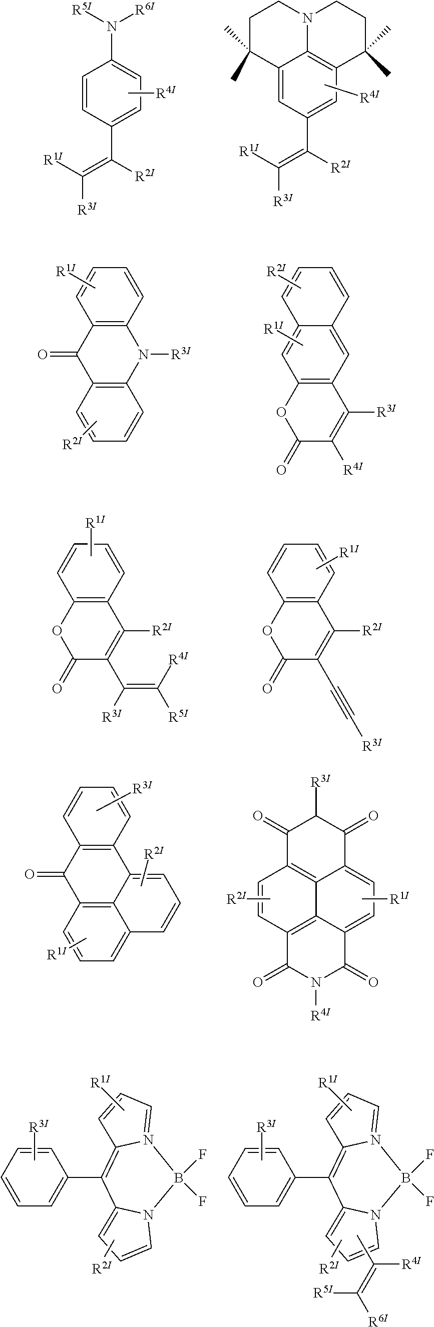

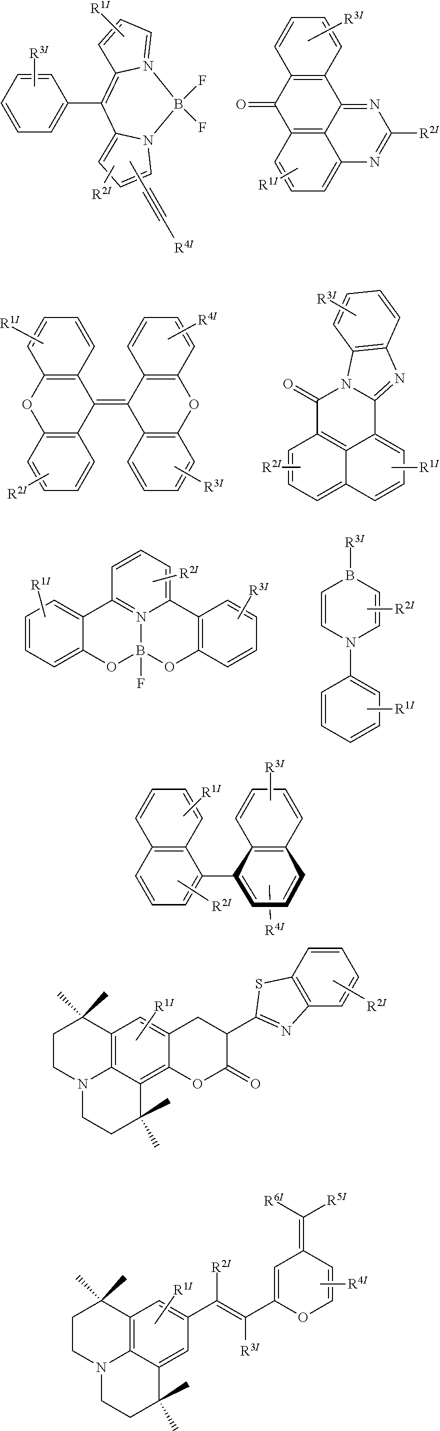

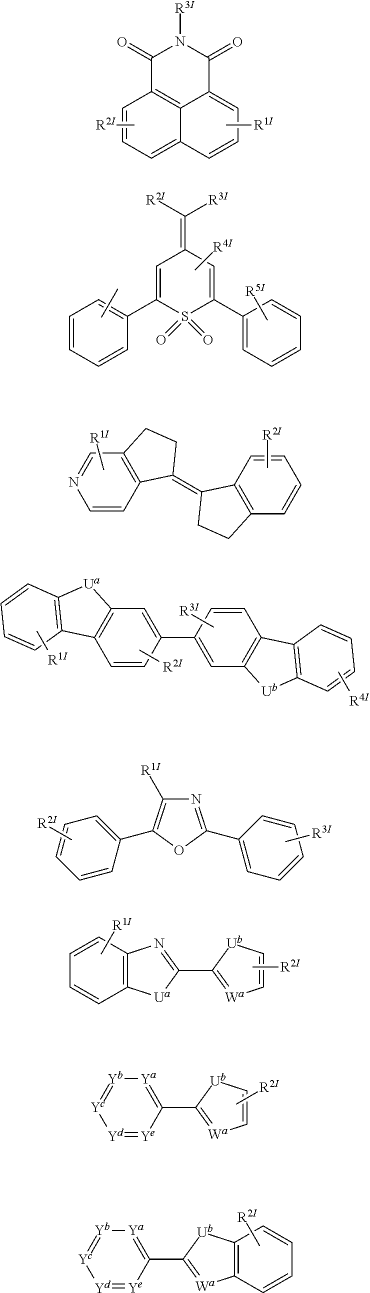

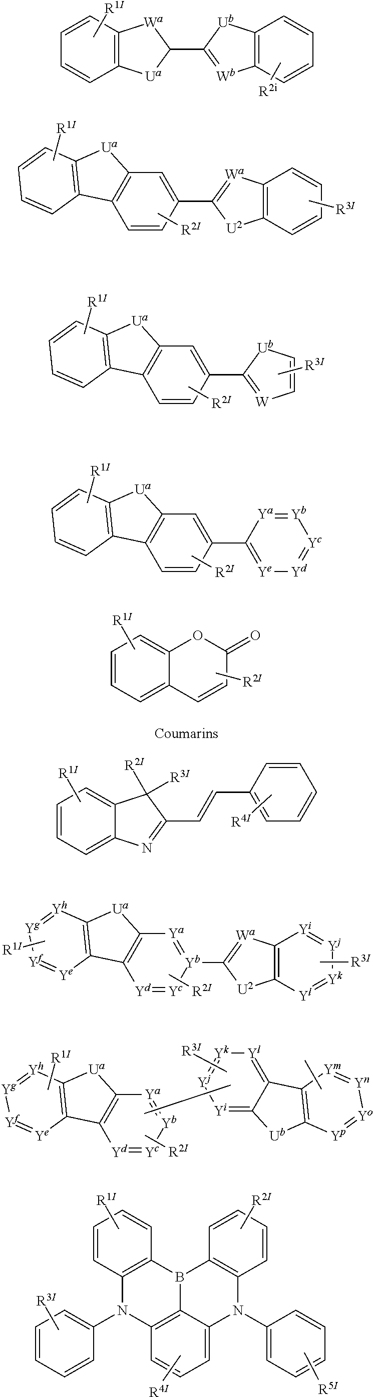

wherein each of R¹¹, R²¹, R³¹, R⁴¹, R⁵¹, R⁶¹, R⁷¹ and R⁸¹ independently are hydrogen, aryl, cycloalkyl, cycloalkenyl, heterocyclyl, heteroaryl, alkyl, alkenyl, alkynyl, deuterium, halogen, hydroxyl , thiol, nitro, cyano, amino, a mono- or di-alkylamino, a mono- or diarylamino, alkoxy, aryloxy, haloalkyl, aralkyl, ester, nitrile, isonitrile, heteroaryl, alkoxycarbonyl, acylamino, alkoxycarbonylamino, aryloxycarbonylamino, sulfonylamino, sulfamoyl, carbamoyl, alkylthio, sulfinyl, ureido, phosphoramide, mercapto, sulfo, carboxyl, hydrzino, substituted silyl, polymeric, or any conjugate or combination thereof;

wherein each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} independently are C, N or B;

wherein each of U^{a}, U^{b} and U^{c} independently represent CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³;

wherein each R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof.

In one embodiment, the fluorescent emitter comprises one of the following compounds.

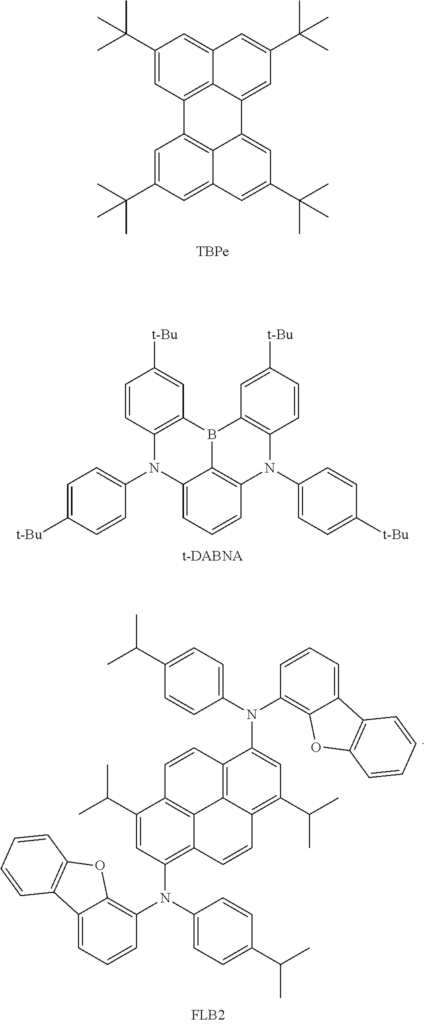

In one aspect, the device is an electro-optical device. Electro-optical devices include, but are not limited to, photo-absorbing devices such as solar- and photo-sensitive devices, organic light emitting devices, photo-emitting devices, or devices capable of both photo-absorption and emission and as markers for bio-applications. For example, the device can be an OLED.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CIE coordinates, which are well known to the art. Such devices are disclosed herein which comprise one or more of the compounds or compositions disclosed herein.

In one embodiment, the device is a white OLED. In one embodiment, the device emits amber light and blue light, which when combined is received as white light. In one embodiment, the color (i.e., warmth) of the white light can be adjusted by varying the thickness and concentration of the various emissive layers.

OLEDs can be produced by methods known to those skilled in the art. In general, the OLED is produced by successive vapor deposition of the individual layers onto a suitable substrate. Suitable substrates include, for example, glass, inorganic materials such as ITO or IZO or polymer films. For the vapor deposition, customary techniques may be used, such as thermal evaporation, chemical vapor deposition (CVD), physical vapor deposition (PVD) and others.

In an alternative process, the organic layers may be coated from solutions or dispersions in suitable solvents, in which case coating techniques known to those skilled in the art are employed. Suitable coating techniques are, for example, spin-coating, the casting method, the Langmuir-Blodgett (“LB”) method, the inkjet printing method, dip-coating, letterpress printing, screen printing, doctor blade printing, slit-coating, roller printing, reverse roller printing, offset lithography printing, flexographic printing, web printing, spray coating, coating by a brush or pad printing, and the like. Among the processes mentioned, in addition to the aforementioned vapor deposition, preference is given to spin-coating, the inkjet printing method and the casting method since they are particularly simple and inexpensive to perform. In the case that layers of the OLED are obtained by the spin-coating method, the casting method or the inkjet printing method, the coating can be obtained using a solution prepared by dissolving the composition in a concentration of 0.0001 to 90% by weight in a suitable organic solvent such as benzene, toluene, xylene, tetrahydrofuran, methyltetrahydrofuran, N,N-dimethylformamide, acetone, acetonitrile, anisole, dichloromethane, dimethyl sulfoxide, water and mixtures thereof.

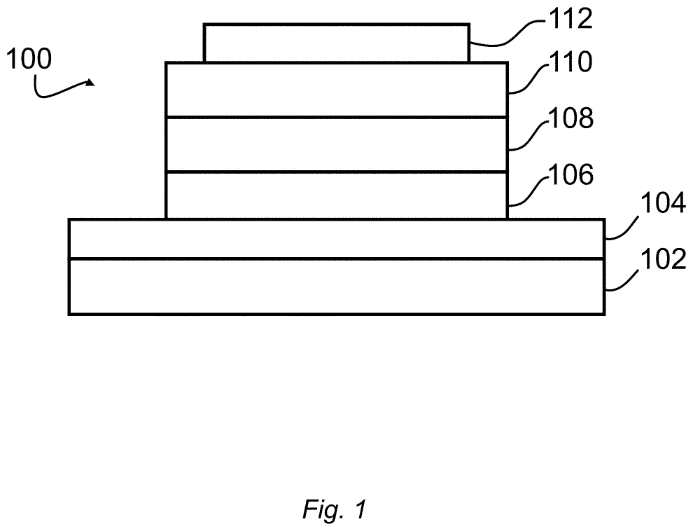

Compounds described herein can be used in a light emitting device such as an OLED. FIG. 1 depicts a cross-sectional view of an OLED 100. OLED 100 includes substrate 102, anode 104, hole-transporting material(s) (HTL) 106, light processing material 108, electron-transporting material(s) (ETL) 110, and a metal cathode layer 112. Anode 104 is typically a transparent material, such as indium tin oxide. Light processing material 108 may be an emissive material (EML) including an emitter and a host.

In various aspects, any of the one or more layers depicted in FIG. 1 may include indium tin oxide (ITO), poly(3,4-ethylenedioxythiophene) (PEDOT), polystyrene sulfonate (PSS), N,N′-di-1-naphthyl-N,N-diphenyl-1,1′-biphenyl-4,4′ diamine (NPD), 1,1-bis((di-4-tolylamino)phenyl)cyclohexane (TAPC), 2,6-Bis(N-carbazolyl)pyridine (mCpy), 2,8-bis(diphenylphosphoryl)dibenzothiophene (PO15), LiF, Al, or a combination thereof.

Light processing material 108 may include one or more compounds of the present disclosure optionally together with a host material. The host material can be any suitable host material known in the art. The emission color of an OLED is determined by the emission energy (optical energy gap) of the light processing material 108, which can be tuned by tuning the electronic structure of the emitting compounds, the host material, or both. Both the hole-transporting material in the HTL layer 106 and the electron-transporting material(s) in the ETL layer 110 may include any suitable hole-transporter known in the art.

Compounds described herein may exhibit phosphorescence. Phosphorescent OLEDs (i.e., OLEDs with phosphorescent emitters) typically have higher device efficiencies than other OLEDs, such as fluorescent OLEDs. Light emitting devices based on electrophosphorescent emitters are described in more detail in WO2000/070655 to Baldo et al., which is incorporated herein by this reference for its teaching of OLEDs, and in particular phosphorescent OLEDs.

As contemplated herein, an OLED of the present invention may include an anode, a cathode, and an organic layer disposed between the anode and the cathode. The organic layer may include a host and a phosphorescent dopant. The organic layer can include a compound of the invention and its variations as described herein.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In one embodiment, the invention relates to a consumer product comprising a device described herein. Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

In one embodiment, the consumer product is selected from the group consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, and a sign.

In some embodiments of the emissive region, the emissive region further comprises a host, wherein the host comprises at least one selected from the group consisting of metal complex, triphenylene, carbazole, dibenzothiophene, dibenzofuran, dibenzoselenophene, aza-triphenylene, aza-carbazole, aza-dibenzothiophene, aza-dibenzofuran, and aza-dibenzoselenophene.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be a triphenylene containing benzo-fused thiophene or benzo-fused furan. Any substituent in the host can be an unfused substituent independently selected from the group consisting of CₙH₂ₙ₊₁, OCₙH₂ₙ₊₁, OAr₁, N(CₙH²ⁿ⁺¹)₂, N(Ar₁)(Ar²), CH═CH—CₙH₂ₙ₊₁, C≡C—CₙH₂ₙ₊₁, Ar₁, Ar₁—Ar₂, and CₙH²ⁿ—Ar₁, or the host has no substitutions. In the preceding substituents n can range from 1 to 10; and Ar1 and Ar2 can be independently selected from the group consisting of benzene, biphenyl, naphthalene, triphenylene, carbazole, and heteroaromatic analogs thereof. The host can be an inorganic compound. For example, a Zn containing inorganic material e.g. ZnS.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

Additional suitable hosts include, but are not limited to, mCP (1,3-bis(carbazol-9-yl)benzene), mCPy (2,6-bis(N-carbazolyl)pyridine), TCP (1,3,5-tris(carbazol-9-yl)benzene), TCTA (4,4′,4″-tris(carbazol-9-yl)triphenylamine), TPBi (1,3,5-tris(1-phenyl-1-H-benzimidazol-2-yl)benzene), mCBP (3,3-di(9H-carbazol-9-yl)biphenyl), pCBP (4,4′-bis(carbazol-9-yl)biphenyl), CDBP (4,4′-bis(9-carbazolyl)-2,2′-dimethylbiphenyl), Tris-PCz (9-Phenyl-3,6-bis(9-phenyl-9H-carbazol-3-yl)-9H-carbazole), DMFL-CBP (4,4′-bis(carbazol-9-yl)-9,9-dimethylfluorene), FL-4CBP (4,4′-bis(carbazol-9-yl)-9,9-bis(9-phenyl-9H-carbazole)fluorene), FL-2CBP (9,9-bis(4-carbazol-9-yl)phenyl)fluorene, also abbreviated as CPF), DPFL-CBP (4,4′-bis(carbazol-9-yl)-9,9-ditolylfluorene), FL-2CBP (9,9-bis(9-phenyl-9H-carbazole)fluorene), Spiro-CBP (2,2′,7,7′-tetrakis(carbazol-9-yl)-9,9′-spirobifluorene), ADN (9,10-di(naphth-2-yl)anthracene), TBADN (3-tert-butyl-9,10-di(naphth-2-yl)anthracene), DPVBi (4,4′-bis(2,2-diphenylethen-1-yl)-4,4′-dimethylphenyl), p-DMDPVBi (4,4′-bis(2,2-diphenylethen-1-yl)-4,4′-dimethylphenyl), TDAF (tert(9,9-diarylfluorene)), BSBF (2-(9,9′-spirobifluoren-2-yl)-9,9′-spirobifluorene), TSBF (2,7-bis(9,9′-spirobifluoren-2-yl)-9,9′-spirobifluorene), BDAF (bis(9,9-diarylfluorene)), p-TDPVBi (4,4′-bis(2,2-diphenylethen-l-yl)-4,4′-di-(tert-butyl)phenyl), TPB3 (1,3,5-tri(pyren-1-yl)benzene, PBD (2-(4-biphenylyl)-5-(4-tert-butylphenyl)-1,3,4-oxadiazole), BCP (2,9-dimethyl-4,7-diphenyl-1,10-phenanthroline), BP-OXD-Bpy (6,6′-bis[5-(biphenyl-4-yl)-1,3,4-oxadiazo-2-yl]-2,2′-bipyridyl), NTAZ (4-(naphth-l-yl)-3,5-diphenyl-4H-1,2,4-triazole), Bpy-OXD (1,3-bis[2-(2,2′-bipyrid-6-yl)-1,3,4oxadiazo-5-yl]benzene), BPhen (4,7-diphenyl-1,10-phenanthroline), TAZ (3-(4-biphenylyl)-4-phenyl-5-tert-butylphenyl-1,2,4-triazole), PADN (2-phenyl-9,10-di(naphth-2-yl)anthracene), Bpy-FOXD (2,7-bis[2-(2,2′-bipyrid-6-yl)-1,3,4-oxadiazol-5-yl]-9,9-dimethylfluorene), OXD-7 (1,3-bis[2-(4-tert-butylphenyl)-1,3,4-oxadiazol-5-yl]benzene), HNBphen (2-(naphth-2-yl)-4,7-diphenyl-1,10-phenanthroline), NBphen (2,9-bis(naphth-2-yl)-4,7-diphenyl-1,10-phenanthroline), 3TPYMB (tris(2,4,6-trimethyl-3-(pyrid-3-yl)phenyl)borane), 2-NPIP (1-methyl-2-(4-(naphth-2-yl)phenyl)-1H-imidazo[4,5-f]-[1,10]phenanthroline), Liq (8-hydroxyquinolinolatolithium), and Alq (bis(2-methyl-8-quinolinolate)-4-(phenylphenolato)aluminum), and also of mixtures of the aforesaid substances.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified in references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

A hole injecting/transporting material to be used in the present invention is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

An emitter example is not particularly limited, and any compound may be used as long as the compound is typically used as an emitter material. Examples of suitable emitter materials include, but are not limited to, compounds which can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, metal-assisted delayed fluorescence (MADF), or combinations of these processes. In some embodiments, the emissive dopant can be a racemic mixture, or can be enriched in one enantiomer.

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof

In yet another aspect of the present disclosure, a formulation that comprises the novel compound disclosed herein is described. The formulation can include one or more components selected from the group consisting of a solvent, a host, a hole injection material, hole transport material, and an electron transport layer material, disclosed herein.

### EXPERIMENTAL EXAMPLES

The invention is further described in detail by reference to the following experimental examples. These examples are provided for purposes of illustration only, and are not intended to be limiting unless otherwise specified. Thus, the invention should in no way be construed as being limited to the following examples, but rather, should be construed to encompass any and all variations which become evident as a result of the teaching provided herein.

Without further description, it is believed that one of ordinary skill in the art can, using the preceding description and the following illustrative examples, make and utilize the composite materials of the present invention and practice the claimed methods. The following working examples therefore, specifically point out the preferred embodiments of the present invention, and are not to be construed as limiting in any way the remainder of the disclosure.

### Example 1

### Interface Layer Design for Efficient and Stable White OLED Based on Blue Fluorescent Emitter and Amber Phosphorescent Aggregates

A series of planar phosphorescent excimers, i.e. Pd3O8-p, Pd3O8-py5 and Pd3O8-py2, for potential horizontally emitting dipole aligned phosphorescent emissive materials for OLED applications was previously reported. These amber phosphorescent excimers can be used in conjunction with stable blue fluorescent emitters such as, but not limited to, FLB2 to fabricate efficient and stable white OLEDs.

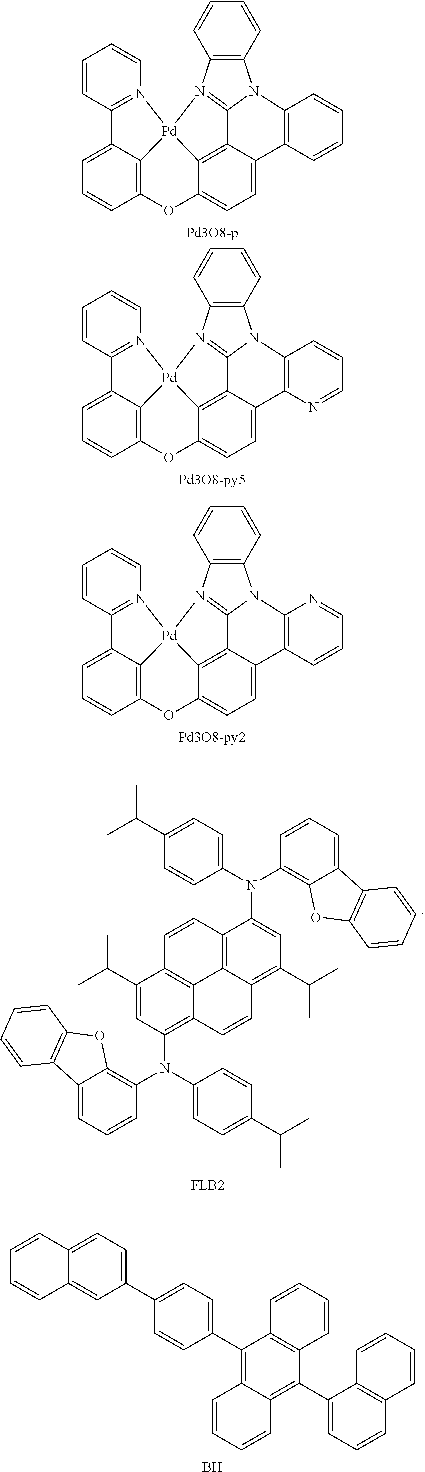

Warm white Devices 1-3 were prepared using the following device configuration: ITO (60 nm)/HATCN (10 nm)/NPD (40 nm)/Tris-PCz (10 nm)/Pd308-py5 (X nm)/2% FLB2:BH (20 nm)/2% FLB2:BH2 (20 nm)/BPyTP (40 nm)/LiF (1 nm)/AL (100 nm).

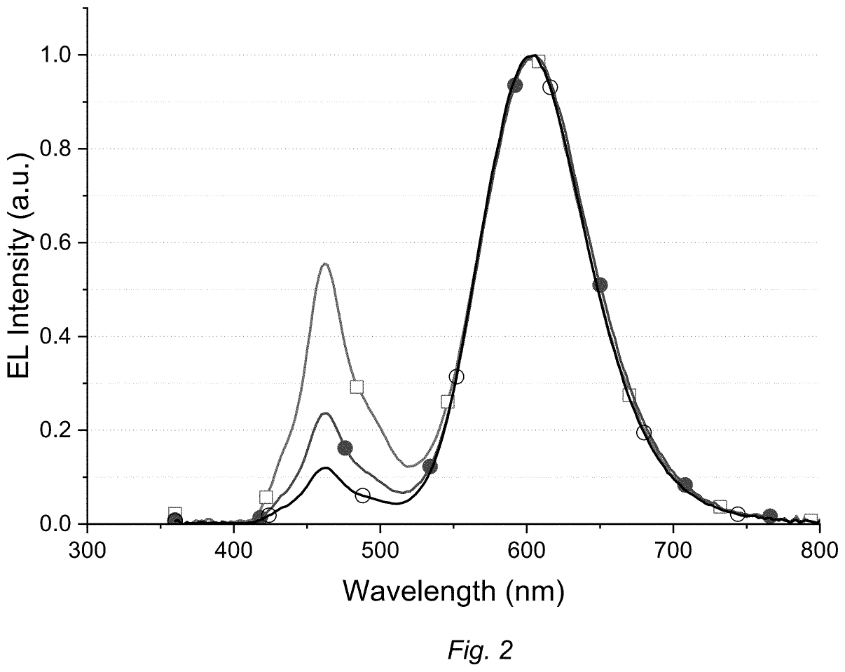

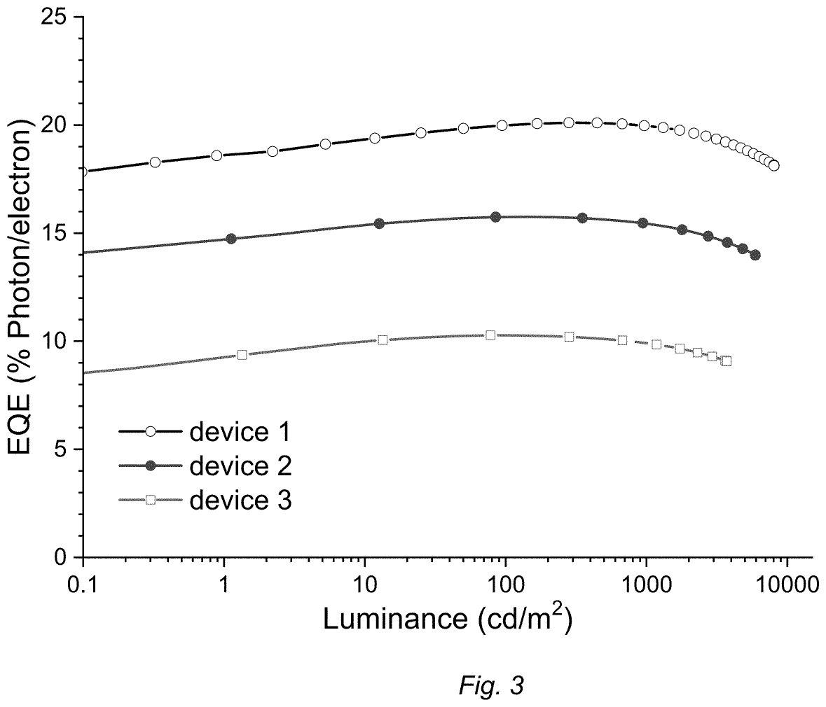

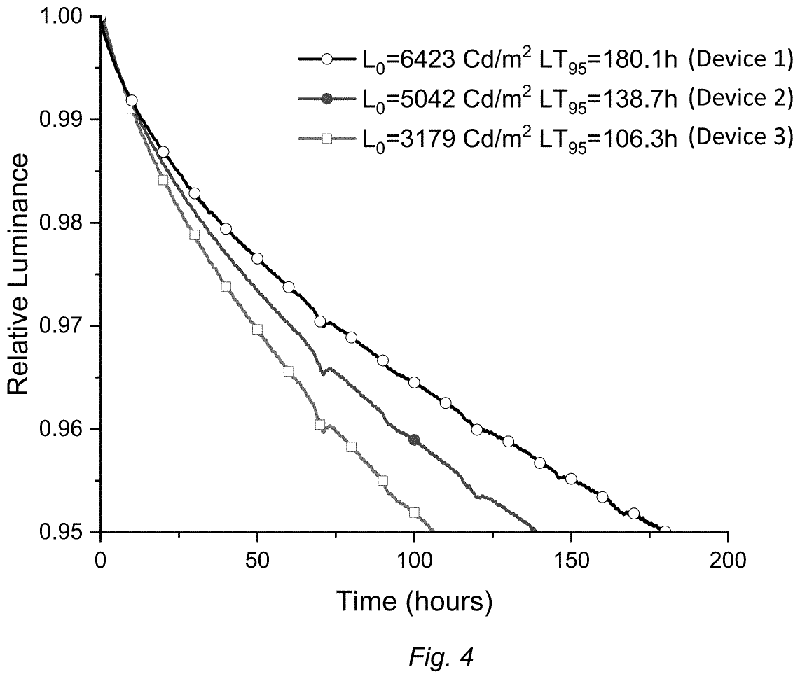

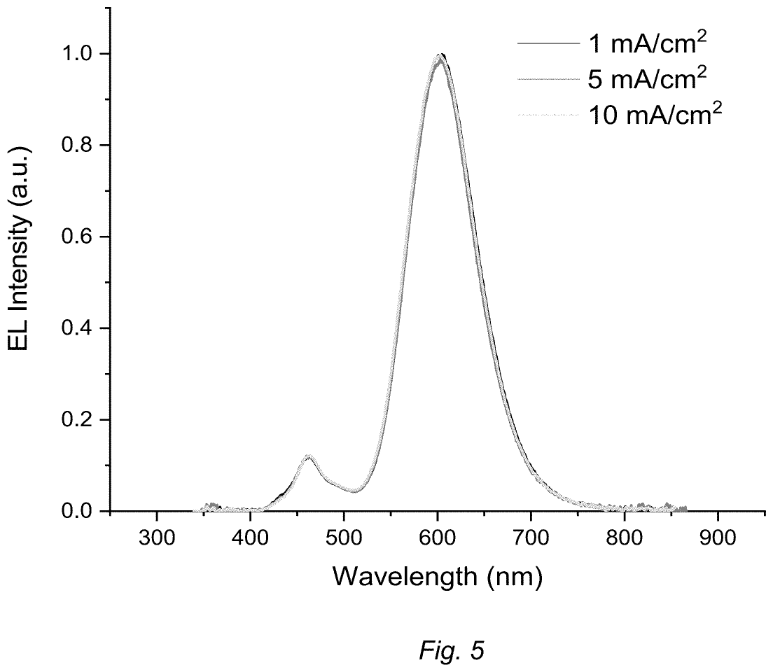

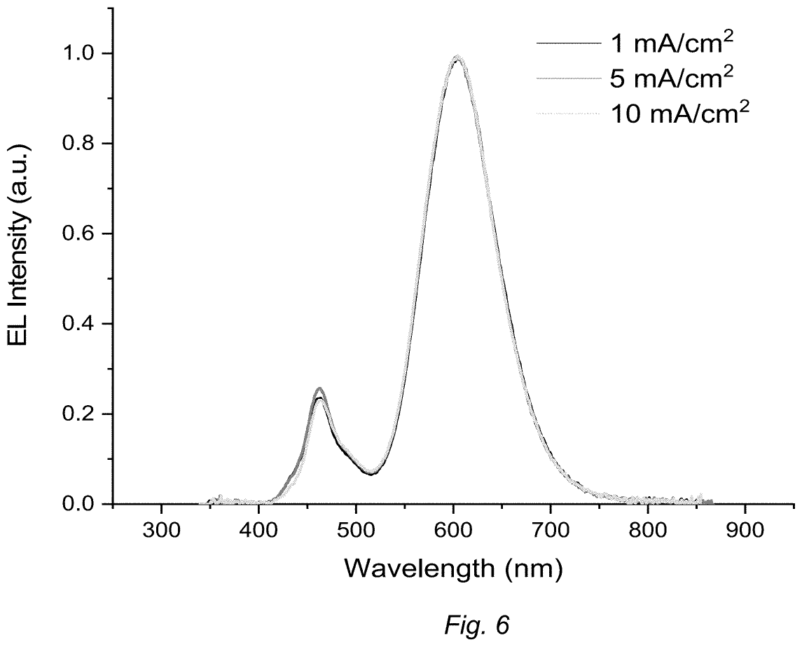

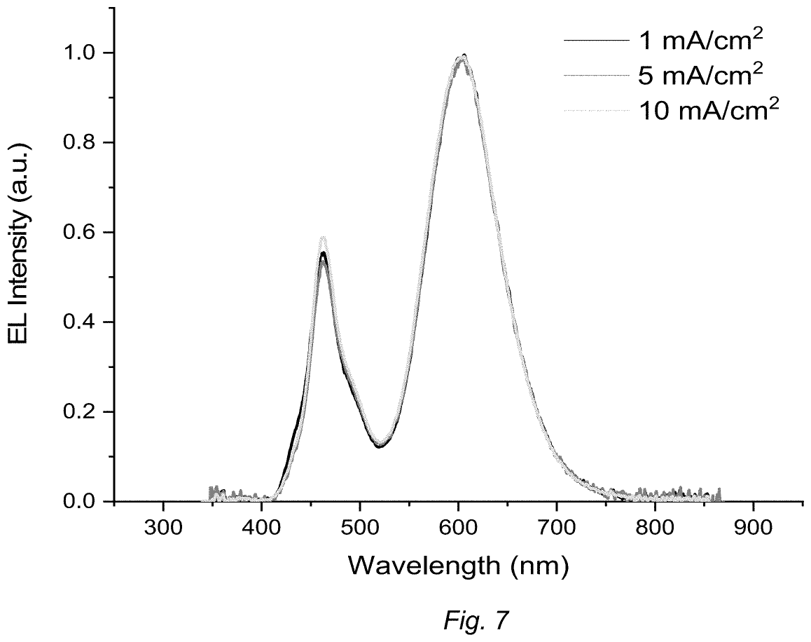

In Device 1, the Pd308-py5 layer is 5 nm thick. In Device 2, the Pd308-py5 layer is 4 nm thick. In Device 3, the Pd308-py5 layer is 3 nm thick. A warm white OLED (FIG. 2) exhibited an EQE of close to 20% (FIG. 3) and estimated LT95 of over 175 hrs at the brightness of over 8000 cd/m² (FIG. 4). The EL spectra at driving currents of 1, 5, and 10 mA/cm² for devices 1, 2, and 3 are shown in FIGS. 5, 6, and 7, respectively. The device operational stability is extremely encouraging. A single-stack white OLED that can achieve that device operational lifetime requirement, even for high brightness applications, can reduce the unit expense of OLED lighting products.

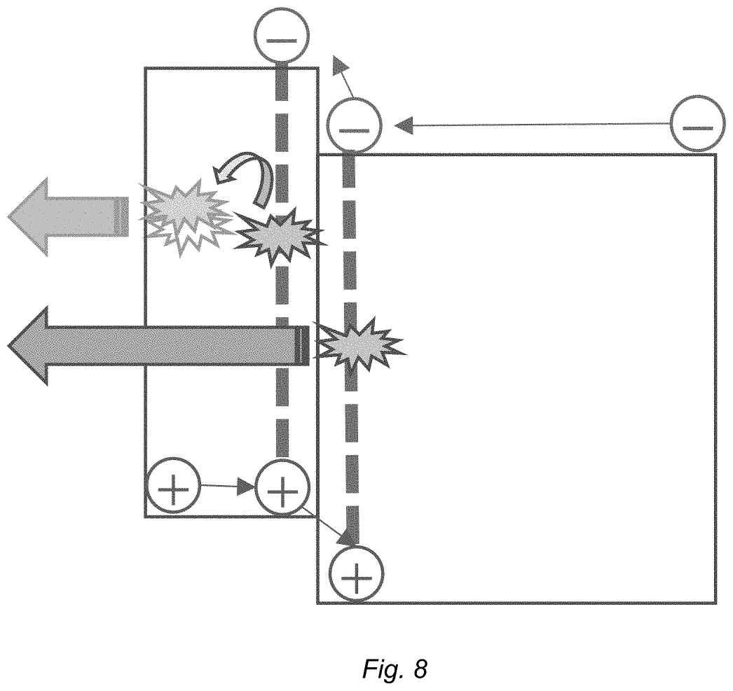

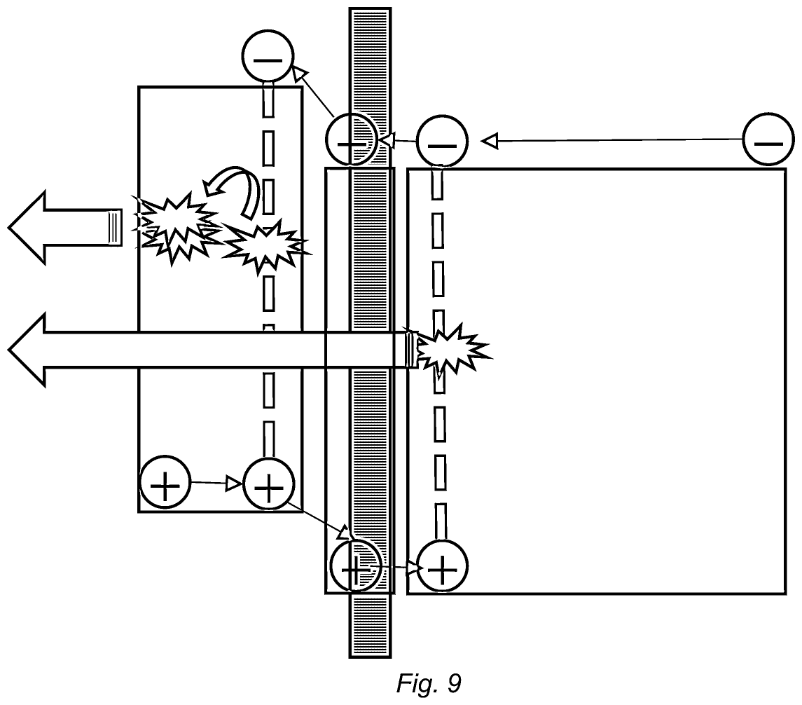

A more pronounced blue fluorescent emission can be accomplished with the decrease of Pd3O8-py5 layer thickness, although the device efficiency and operational lifetime are compromised (FIG. 8). It becomes apparent that the low triplet energy of BH materials (anthracene based materials) could lead to the possible quenching of Pd3O8-py5 excitons and the reduction of device efficiency. The decrease of Pd3O8py5 layer thickness will worsen the effect of Pd3O8-py5 exciton quenching. Thus, it will be ideal that a thin interfacial layer will be placed between the amber excimer layer and blue fluorescent layer (FIG. 9). This interface layer consists of a thin layer of mixed BH (transporting holes and electrons) and at least one high energy gap material, which can act as a spacing layer and prevent the quenching of excimers from low triplet energy BH materials. An exemplary high energy gap material is high triplet energy ETL material 2py22-dp.

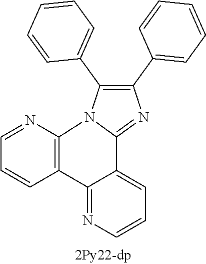 [SMILES: c1ccc(-c2nc3c4cccnc4c4cccnc4n3c2-c2ccccc2)cc1]

A 5-nm layer of co-deposited BH:2py22-dp interfacial layer (1:1 weight ratio preferred) was placed as an interfacial layer inside of EML layers. Devices were fabricated with the following configuration: 100 nm ITO/HATCN (10 nm)/NPD (70 nm)/TrisPcz (10 nm)/Pd308-py5 (5 nm)/X/2% FLB3:BH (30 nm)/BPYTP (40 nm)/Liq (2 nm)/Al, where X is (i) 2 nm 2py22-dp, (ii) 5 nm 20% 2py22-dp:BH, (iii) 5 nm 50% 2py22-dp:BH and (iv) 5 nm 80% 2py22-dp:BH. In some embodiments, the ratio of materials is a weight ratio. In some embodiments, the ratio of materials is a molar ratio.

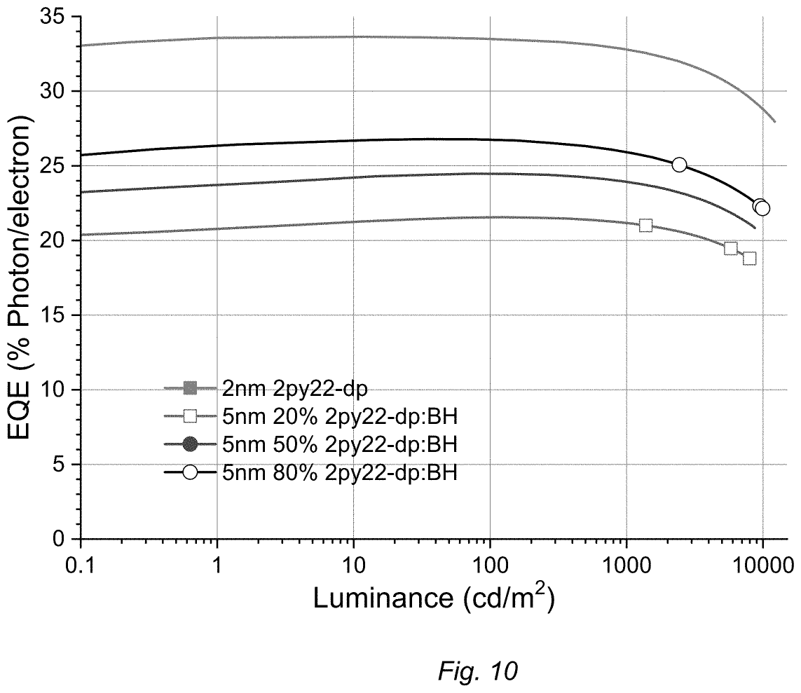

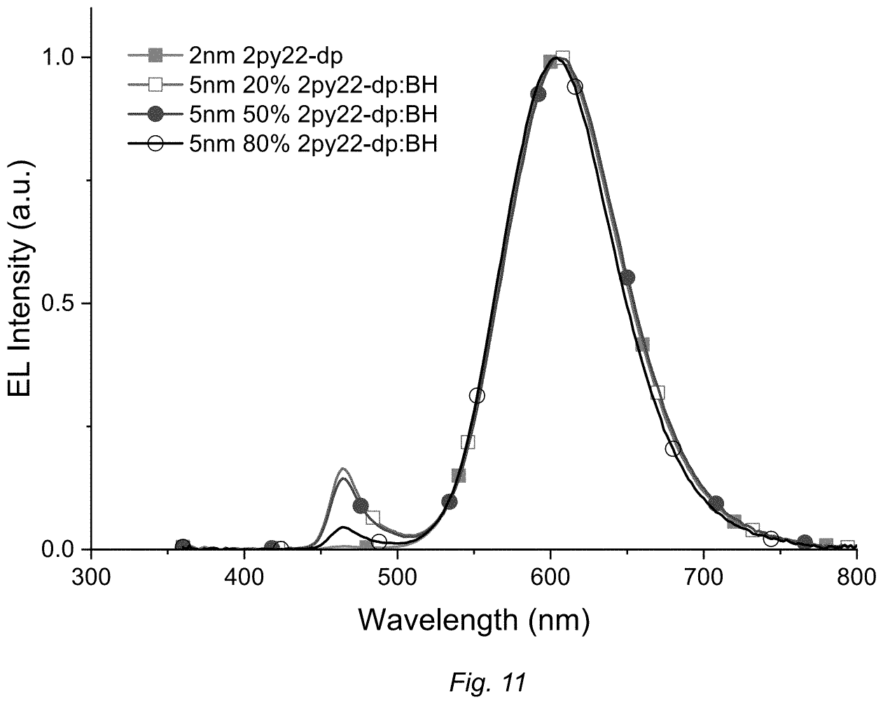

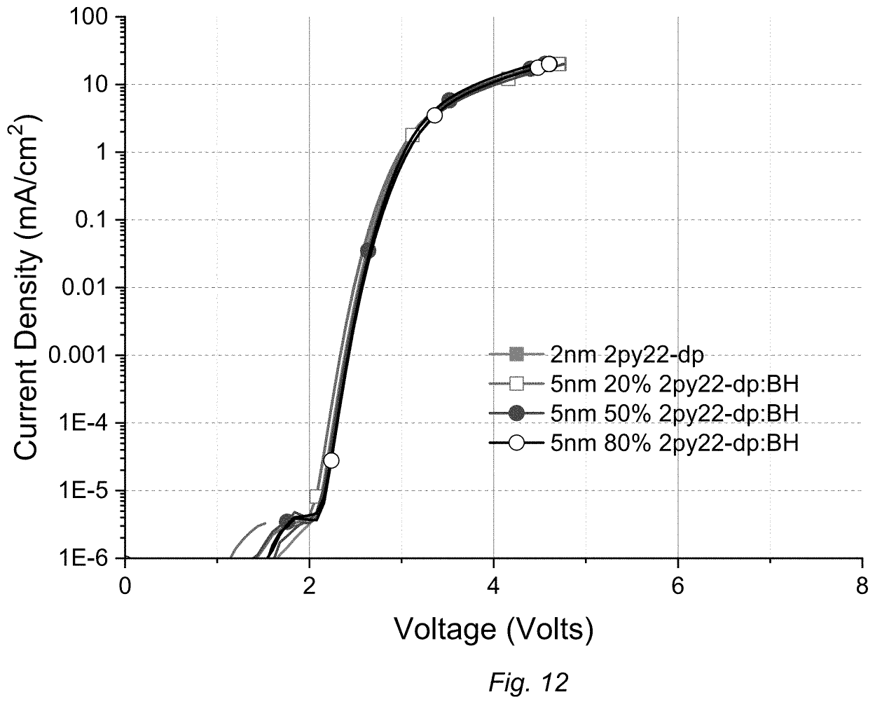

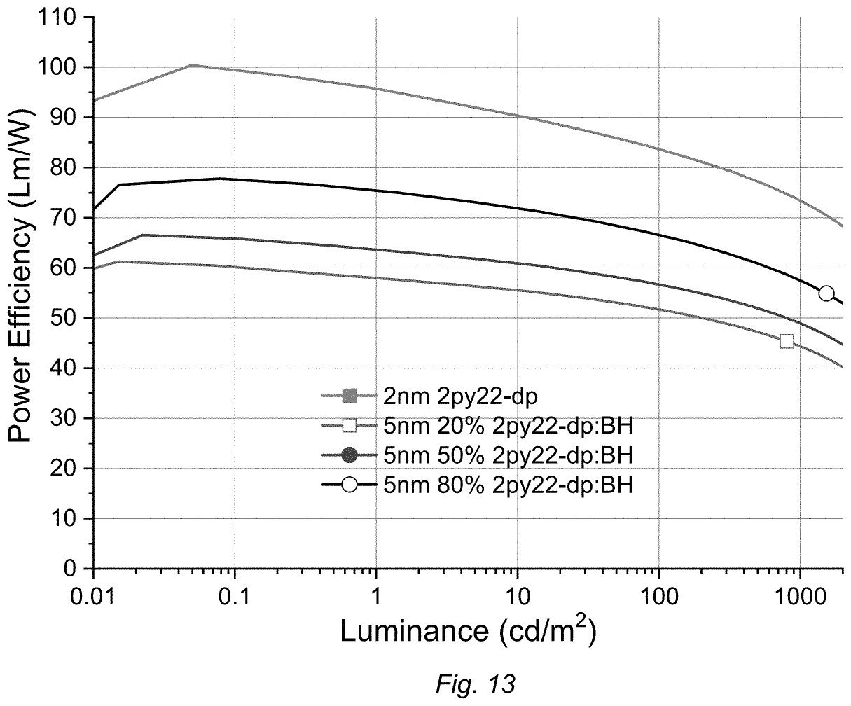

A plot of EQE vs luminance for these novel devices is presented in FIG. 10. The EL spectra of these devices are shown in FIG. 11. J-V curves for these devices are presented in FIG. 12. A plot of PE vs. Luminance for these devices is presented in FIG. 13. The interfacial layer increased device efficiency to close to 25% while maintaining a warm white EL spectrum.

### Example 2

### Efficient, Color-Stable and Long-Lived White Organic Light-Emitting Diode Utilizing Phosphorescent Molecular-Aggregates

Highly efficient and stable single-stack hybrid white organic light-emitting diode (WOLED) devices are developed using two emissive layers, one with amber colored phosphorescent molecular aggregate emission from the Pd (II) complex, Pd(II) 7-(3-(pyridine-2-yl-κN)phenoxy-κC)(benzo-κC)([c]benzo[4,5]imidazo-κN)[1,2-a] [1,5]naphthyridine, Pd3O8-Py5, and the other with blue fluorescence emission. An optimized device structure achieved high color stability under various current densities, an external quantum efficiency (EQE) of 45.5%, a power efficiency of 97.4 Lm W⁻¹, and an estimated LT₉₅ (operational time to 95% of the initial luminance) of 50,744 hours at an initial luminance of 1000 cd m⁻².

The invention of the first practical organic light-emitting diode (OLED) in 1987 sparked widespread attention among researchers within the academic and industry communities, leading to decades of rapid advancements in material design and device architecture (C. W. Tang, S.A. VanSlyke, Applied Physics Letters, 51, 913-915 (1987)). As a result, OLEDs have become market disruptors in the display industry and have been implemented in various applications, including televisions, phones, smartwatches, with ongoing research being conducted on their use in virtual and augmented reality displays (C. Kang, H. Lee, Journal of Information Display 23, 19-32 (2022); S. R. Forrest, 428, 911-918 (2004)). Their success in the display industry has ignited a rising interest in applying OLEDs for solid-state lighting applications through the development of white organic light-emitting diodes (WOLEDs), which have been considered an attractive replacement for common light sources, such as fluorescent and incandescent bulbs, due to their lower power consumption, mechanical flexibility, homogeneous large area illumination and potential low-cost fabrication (G. Schwartz, et al., Advanced Functional Materials 19, 1319-1333 (2009); B. W. D'Andrade, S. R. Forrest, Advanced Materials 16, 1585-1595 (2004); M. C. Gather, et al., Advanced Materials 23, 233-248 (2011); H. Sasabe, J. Kido, Journal of Materials Chemistry C 1, 1699-1707 (2013)). However, to enter the market as a serious competitor, WOLEDs must achieve excellent color qualities, high external quantum efficiencies (EQE) and long operational lifetimes.

The device architectures used to develop WOLEDs are generally complex, consisting of either single or multiple emissive layers (EML) doped with emitters based on the primary colors (red, green, and blue) or a combination of complementary colors (commonly orange and blue) to generate a broad emission spectrum (S.-H Eom, et al., Applied Physics Letters 94, 153303 (2009); P. Tyagi, et al., Journal of Luminescence 136, 249-254 (2013)). The complications associated with such architectures stem from the employment of multiple emitters which require intricate device engineering strategies to avoid voltage-dependent changes in the electroluminescent (EL) spectrum, typically caused by a shift of the exciton recombination zone in multi-EML WOLEDs (P. Tyagi, et al., Journal of Luminescence 136,249-254 (2013)) or deviations in the energy transfer processes in single-EML WOLEDs (Z. Wu, D. Ma, Materials Science and Engineering: R: Reports 107, 1-42 (2016)). Therefore, the materials must be judiciously selected with properties that can mitigate such effects. In the meantime, the ongoing progress of pursuing highly efficient WOLEDs hinges on the use of phosphorescent emitters due to their abilities to reach 100% internal electron-to-photon conversion efficiency (M.A. Baldo, et al., Nature 395,151-154 (1998); M.A. Baldo, et al., Applied Physics Letters 75,4-6 (1999); E.L. Williams, et al., Advanced Materials 19,197-202 (2007); Q. Wang, et al., Advanced Functional Materials 19, 84-95 (2009); J. H. Seo, et al., Organic Electronics 11,1759-1766 (2010)). However, white phosphorescent OLEDs suffer from the short operational lifetimes of blue phosphorescent emitters due to their poor electrochemical stability and incompatibility with state-of-the-art host and blocking materials (R. de Moraes, et al., Organic Electronics 12,341-347 (2011); R. de Moraes, et al., Organic Electronics 12,341-347 (2011); T. B. Fleetham, et al., Chemistry of Materials 28,3276-3282 (2016)). Alternative emitters such as thermally activated delayed fluorescence (TADF) (Z. Wu, et al., Advanced Functional Materials 26,3306-3313 (2016); C.-Y. Chan, et al., Nature Photonics 15,203-207 (2021)) and metal assisted delayed fluorescence (MADF) emitters (Z.-Q. Zhu, et al., Advanced Materials 27, 2533-2537 (2015); Z.-Q. Zhu, et al., Advanced Optical Materials 7,1801518 (2019)), which have also demonstrated the ability to harvest all electrogenerated excitons, exhibited similar fates and haven't demonstrated long enough operational lifetimes for lighting applications.

On the contrary, blue fluorescent emitters have realized longer operational lifetimes than their phosphorescent or TADF counterparts (S.-W. Wen, et al., Journal of Display Technology 1,90-99 (2005); S.-J. Yeh, M et al., Advanced Materials 17,285-289 (2005)), which prompted the development of hybrid WOLEDs based on a combination of blue fluorescent emitters and red and green phosphorescent emitters (Y. Sun, et al., Nature 440,908-912 (2006)). The challenge with using this type of device architecture is the potential quenching of red and green phosphorescent emitters from the blue fluorescent emitters with low triplet energy, leading to unstable emission color under various driving conditions (J. Ye, et al., Advanced Materials 24,3410-3414 (2012); G. Schwartz, et al., Advanced Materials 19, 3672-3676 (2007); M. A. Baldo, S. R. Forrest Physical Review B 62, 10958-10966 (2000); M. A. Baldo, et al., Physical Review B 62, 10967-10977 (2000)). Thus, it becomes more technically feasible to produce WOLEDs in a tandem device structure, with the goal of isolating the blue fluorescent emissive layer from the red and green phosphorescent emissive layer to avoid unwarranted interference (J. Birnstock, et al., SID Symposium Digest of Technical Papers 39, 822-825 (2008); L.-S. Liao, et al., SID Symposium Digest of Technical Papers 39, 818-821 (2008); Y.-S. Tyan, et al., SID Symposium Digest of Technical Papers 40, 895-898 (2009)). Furthermore, the operational lifetimes of tandem WOLEDs have surpassed their single-stack counterparts by allowing the device to operate at higher brightness or at lower current densities for the same targeted brightness (J. Kido, 61.1: SID Symposium Digest of Technical Papers 39, 931-932 (2008)). However, the practical general lighting will have to be manufactured in a large volume at a high speed to meet targeted cost-effectiveness. The raised fabrication cost, due to the complexity of tandem WOLEDs, can be the biggest obstacle for the commercialization of lighting device using OLED technology. Therefore, it is still highly desirable to develop a single-stack WOLED that can simultaneously realize high efficiencies, long operational lifetime, and stable color emission under various driving conditions.

Recently, an excimer based phosphorescent emitter, Pd(II) 7-(3-(pyridine-2-yl-κN)phenoxy-κC)(benzo-κC)([c]benzo[4,5]imidazo-κN)[1,2-a][1,5]naphthyridine (Pd308-Py5), was shown to exhibit amber-colored emission arising from its aggregate species (L. Cao, et al., Advanced Materials 33, 2101423 (2021)). A device employing the Pd308-Py5 emitter realized a high peak EQE of 37.3% which was able to maintain a high value of 36% at 1000 cd m⁻². Moreover, the device demonstrated a long operational lifetime of 48,246 hours at 1000 cd In⁻². Such results illuminate the superior properties of molecular aggregate-based emitters that would make them desirable candidates for use in the development of WOLEDs (L. Cao, et al., Nature Photonics 15, 230-237 (2021)). Here, the performance of a single-stack WOLED is examined by exploring a novel multi-layer WOLED device concept that employs a neat layer of the Pd(II) complex, Pd308-Py5, with an amber emission and a blue fluorescent emissive layer. An optimized device structure realized a peak EQE and power efficiency (PE) of 45.6% and 118 Lm W⁻¹, respectively, with no observable variances in the EL emission spectra at various current densities. Furthermore, the device exhibited an estimated LT95 (time to 95% of the initial luminance) of 50,744 hours at 1000 cd m⁻², which to the authors' knowledge is the longest device operational lifetime for a WOLED reported in literature. The comprehensive performance of the proposed device architecture competes with tandem WOLED devices that are commercially available and reported within the literature domain, providing a strong foundation to further advance the development of highly efficient and stable single-stack WOLEDs.

A series of Pd(II) complexes had been previously examined for their amber colored molecular aggregate emission, of which Pd3O8-Py5 demonstrated the highest PLQY of 88±10% and an estimated horizontal emitting dipole ratio of 95% (L. Cao, et al., Advanced Materials 33, 2101423 (2021)), making it an ideal choice for an emissive material in OLEDs. The fabrication process is also simplified as a host material is not required to achieve high efficiencies and stabilities in the device settings. The blue EML consists of a blue fluorescent emitter doped in an anthracene type host as this combination has previously been used to develop stable blue OLEDs. Thus, 9-(naphthalen-1-yl)-10-(4-(naphthalen-2-yl)phenyl)anthracene (BH) was selected as the blue host material (T. Sato, et al., Organic Electronics 74, 118-125 (2019)) and 2,12 di-tert-butyl-5,9-bis(4-(tert-butyl)phenyl)-5,9-dihydro-5,9-diaza-13b-boranaphtho[3,2,1-de]anthracene (t-DABNA) was explored as the blue emitter, which also produces a deep blue emission color (K. H. Lee, J. Y. Lee, Organic Electronics 75, 105377 (2019)). Additionally, anthracene type hosts have shown to improve the EQE by harvesting additional electrogenerated triplet excitons through triplet-triplet annihilation (TTA) process (H. Fukagawa, et al., Organic Electronics 13, 1197-1203 (2012)). Furthermore, the ambipolar charge transporting properties of BH and Pd3O8-Py5 would help to form a recombination zone that extends across both EMLs to ultimately generate white light. Since the operational lifetime of the blue emitter is not parallel to that of the aggregate emitters, a thicker blue EML (30 nm) is explored to broaden the recombination zone and maintain its device operational stability.

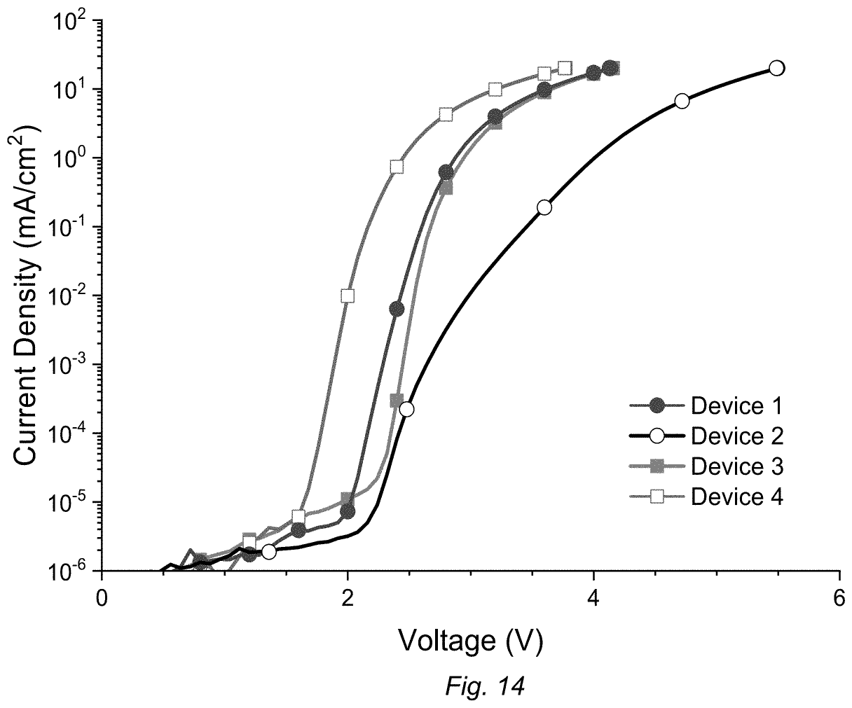

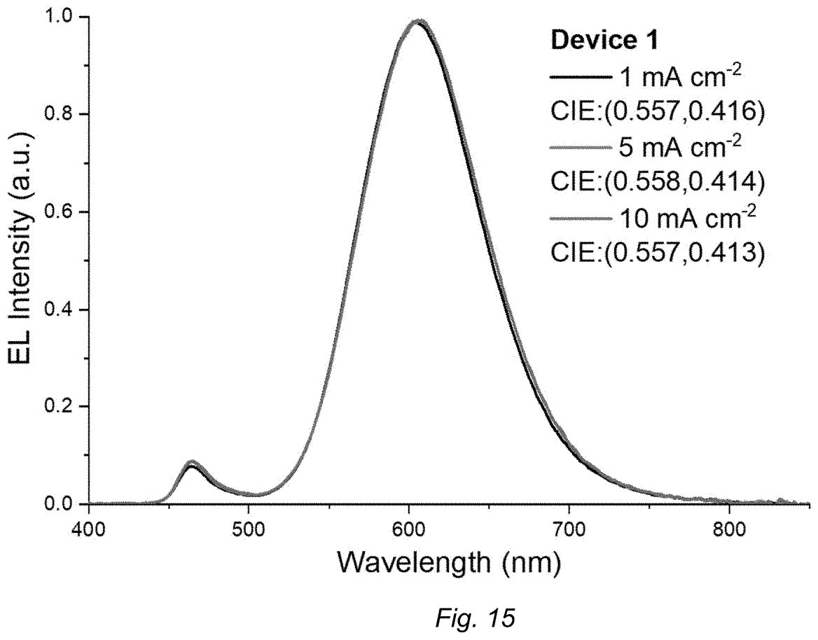

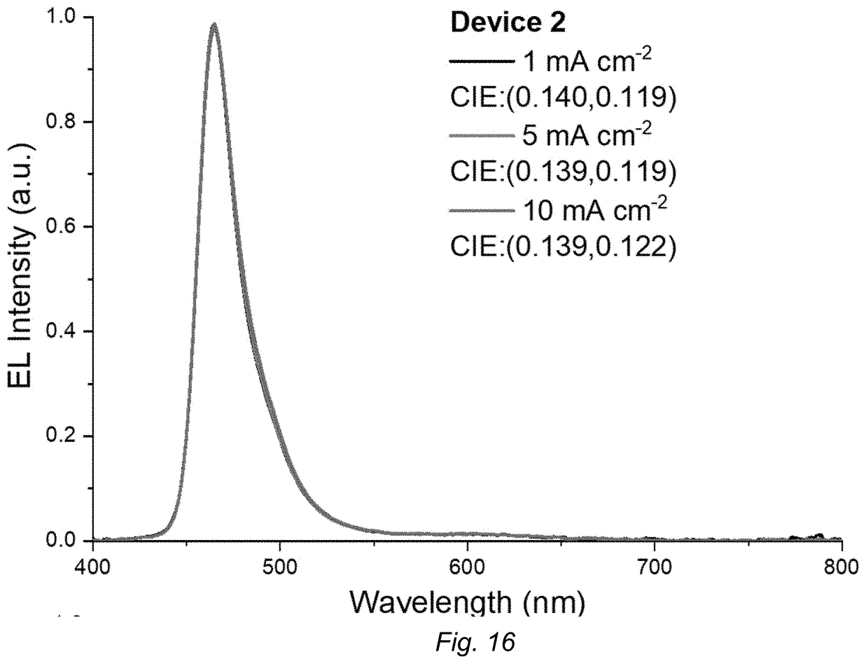

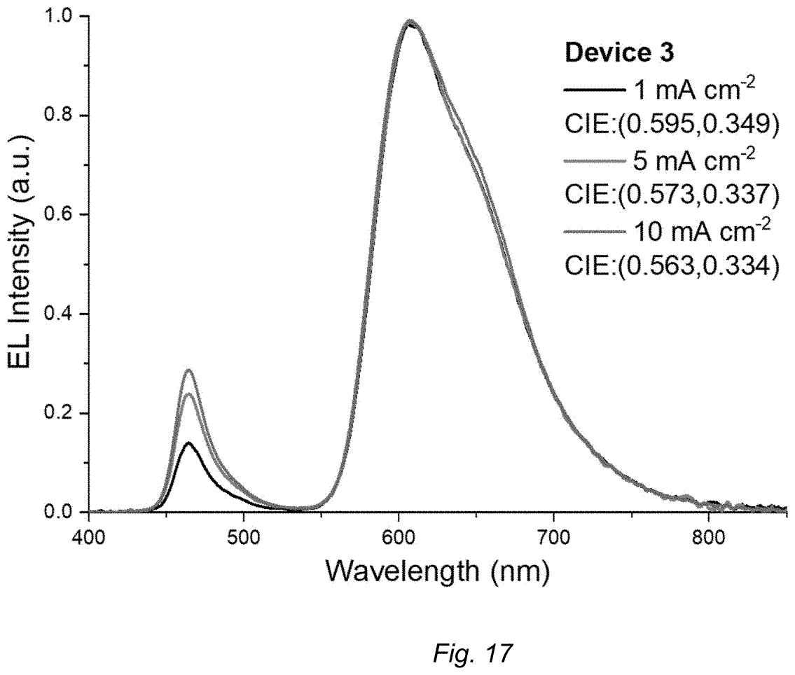

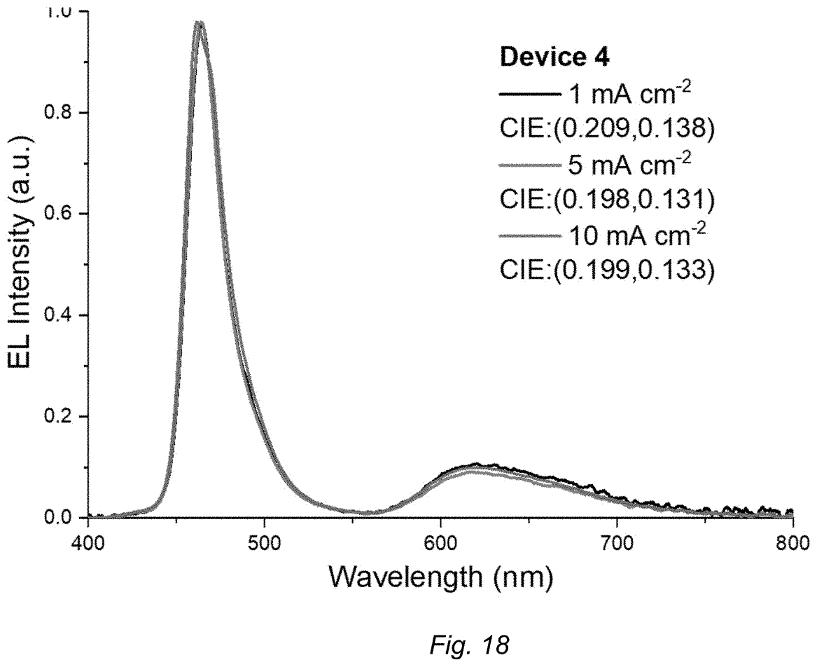

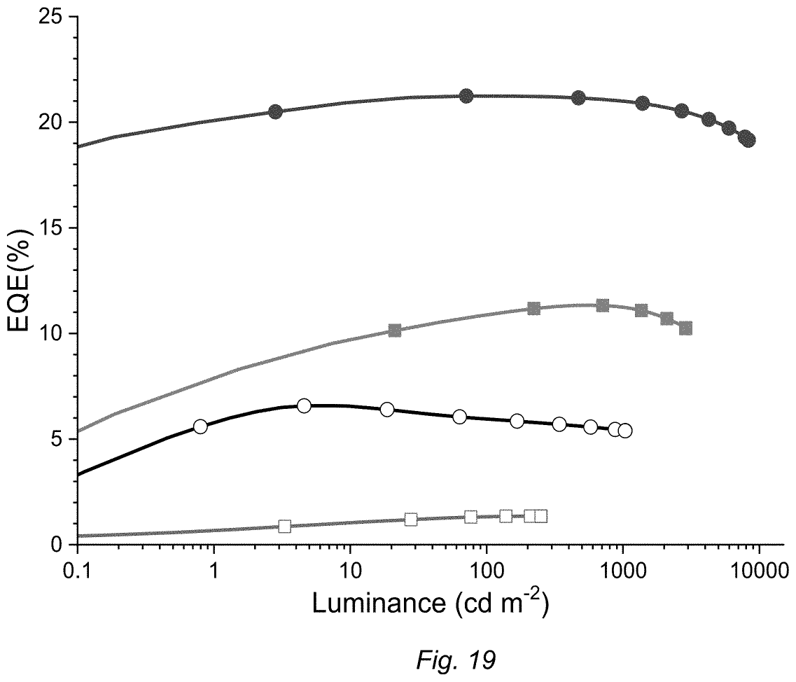

To determine the arrangement of materials that will produce balanced white emission with high performance, a set of devices were fabricated in the following general structure of ITO/HATCN (10 nm)/NPD (70 nm)/TrisPCz (10 nm)/EML/BPyTP (40 nm)/Liq (2 nm)/Al where HATCN is 1,4,5,8,9,11-hexaazatriphenylene-hexacarbonitrile, NPD is N,N′-diphenyl-N,N′-bis(1-naphthyl)-1,1′-biphenyl-4,4″-diamine, TrisPCz is 9,9′,9″-triphenyl-9H,9′H,9″H-3,3′:6′,3″-tercarbazole, BPyTP is 2,7-di(2,2′-bipyridine-5-yl)triphenylene, and Liq is 8-hydroxyquinolinolato-lithium. The EML is Pd3O8-Py5 (5 nm)/2 wt. % t-DABNA:BH (30 nm) for device 1 and is 2 wt. % t-DABNA:BH (30 nm)/Pd3O8-Py5 (5 nm) for device 2. The current density—voltage characteristics, shown in FIG. 14, reveals a turn-on voltage (defined as the voltage required to reach an external brightness of 1 cd m⁻²) of 2.32 V for device 1 and 3.03 V for device 2. Device 1 also realized a lower driving voltage of 3.5 V at 10 mA cm⁻² compared to 4.95 V of device 2. As illustrated in FIGS. 15-18, a considerable difference in the EL spectra between the two devices were observed where device 1 revealed a dominant amber emission peak at 604 nm and a small blue emission peak at 464 nm, whereas device 2 revealed a dominant blue emission peak at 464 nm and no observable Pd3O8-Py5 emission. The dual emission observed in device 1 implies the recombination zone was formed at the interface of the two EMLs, unlike device 2 which appeared to be centralized on the blue EML. Plots of EQE versus luminance are shown in FIG. 19, which reveals that the enhanced Pd3O8-Py5 aggregate emission allowed device 1 to achieve a high peak EQE of 21.2% with an impressively low efficiency roll-off retaining an EQE of 20.9% at 1000 cd m ⁻². The low contribution from the Pd3O8-Py5 aggregate emission resulted in a reduced peak EQE of 6.58% for device 2.

To assess the unique utility of Pd3O8-Py5 aggregate as an amber emitter, its performance was compared to an octahedral Ir-based phosphorescent emitter, without known aggregate formation in the solid state, in a similar device setting. The red phosphorescent emitter, Ir(III) bis-(2-phenylquinolyl-N,C²′) acetylacetonate (PQIr), was selected as it has been widely used in the development of WOLEDs and would provide a reasonable comparison against the amber emitting Pd3O8-Py5 aggregate (B. W. D'Andrade, et al., Advanced Materials 16, 624-628 (2004)). Using the same general device structure as device 1, the EML is 10 wt. % PQIr:CBP (5 nm)/2 wt. % t-DABNA:BH (30 nm) for device 3 and is PQIr (5 nm)/2 wt. % t-DABNA:BH (30 nm) for device 4. Device 3 and 4 reached turn-on voltages of 3.0 V and 2.2 V and driving voltages of 3.7 V and 3.2 V at 10 mA cm', respectively. The EL spectra of device 3 and 4 showed emission from both PQIr and t-DABNA emitters; however, device 3 exhibited dominant amber emission whereas dominant blue emission was observed for device 4. Both devices realized lower peak EQEs compared to device 1, with device 3 reaching a peak EQE of 11.3% and device 4 realizing the lowest peak EQE of 1.35% among all the devices.

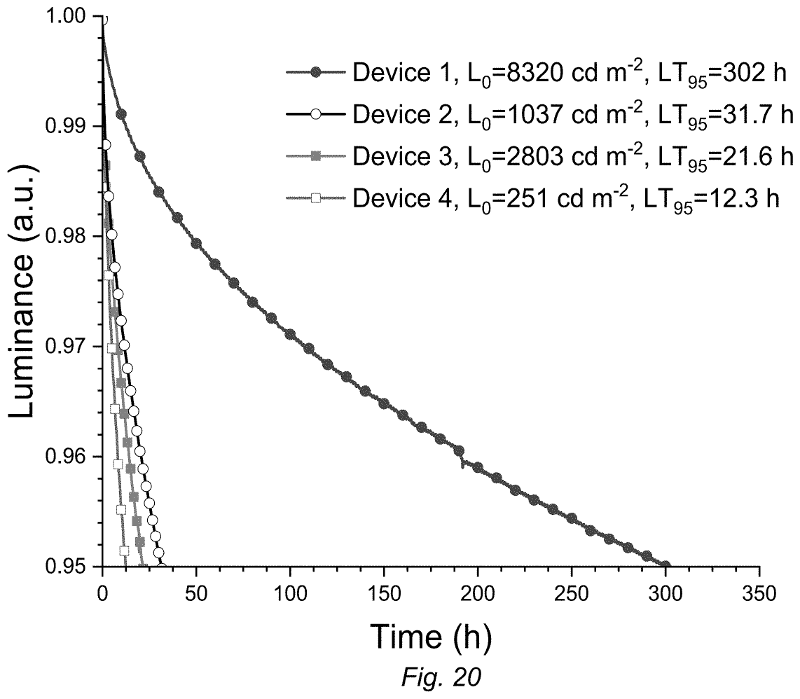

To examine the color stability of the devices, the EL spectra were collected at current densities of 1, 5 and 10 mA cm⁻², as depicted in FIGS. 15-18. High color stability with negligible changes in the EL spectra were observed for devices 1 and 4, whereas a color shift is observed for device 3. It has been suggested that high color stability observed in WOLEDs can be attributed to the ambipolar charge transporting properties of the neat film EML materials, like Pd3O8-Py5 and PQIr, which will generate no changes to the charge trapping effects and prevent a shift of the exciton recombination zone with increasing current (B. Liu, L et al., Journal of Materials Chemistry C 2, 9836-9841 (2014); Q. Wang, D. Ma, Chemical Society Reviews 39, 2387 (2010)). The device operational stabilities of devices 1-4 were also examined. FIG. 20 shows the normalized EL intensity versus operational time for the devices at constant driving current densities of 20 mA cm⁻². LT95 was chosen as the metric due to the long operational lifetimes reported for devices employing a neat layer of Pd3O8-Py5 and to compare with the standards set by the display industry to minimize the image sticking effect. The measured LT95 value of devices 1-4 was 302, 31.7, 21.6, and 12.3 hours. Overall, the electroluminescent properties analyzed through this series of devices supports the choice of using an aggregate emitter in a single-stack hybrid WOLED to achieve excellent color stability, high EQE and long operational lifetime over conventional hybrid WOLED devices that only employ traditional monochromatic emitters.

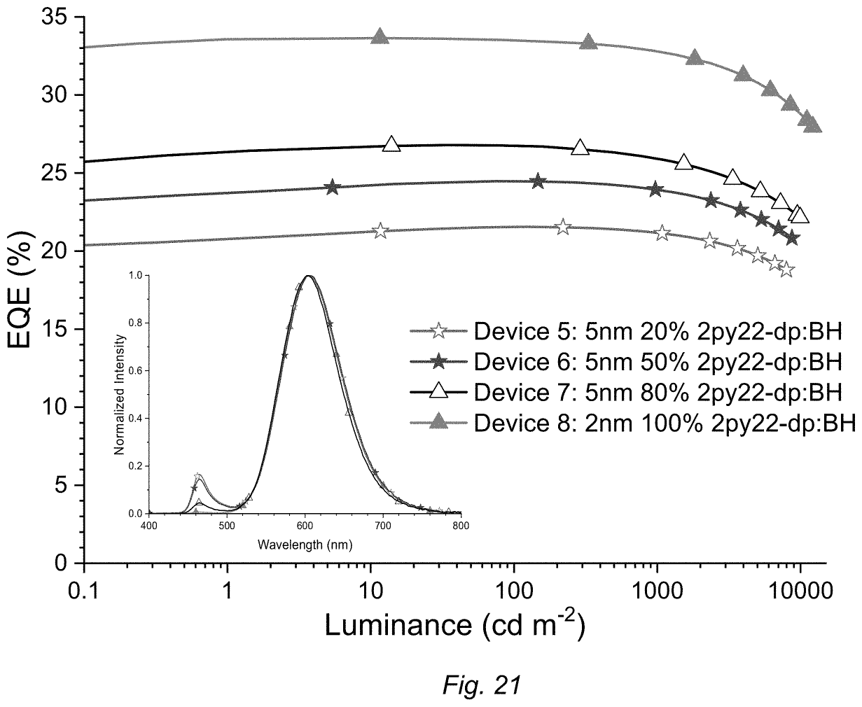

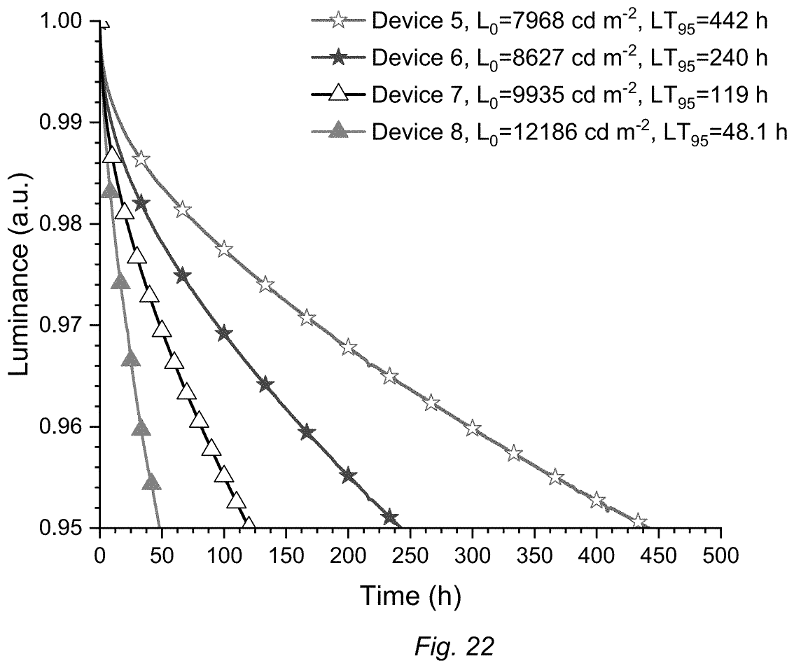

BH is a critical material in the device architecture as it promotes efficient transport of both electrons and holes to form a recombination zone across both EMLs, assists to stabilize the singlet and triplet excitons of the blue emitter and enhance device efficiency through potential TTA process. However, due to its low triplet energy, BH (E_{T}˜1.7eV) could potentially quench the triplet excitons of the Pd3O8-Py5 emitter and consequently lower the EQE of the overall WOLED device. To further improve the efficiency, devices were fabricated in a similar device setting but with the addition of a thin interlayer (around 5 nm) composed of BH and 2py22-dp between the Pd3O8-Py5 and blue EMLs as depicted in FIG. 8 and FIG. 9. The role of the BH is to help facilitate the transport of both electrons and holes between the two EMLs, whereas the high triplet energy material, 2py22-dp (E_{T}˜2.7eV), would serve as a spacer to reduce quenching of the Pd3O8-Py5 excitons by the BH. The concentration of 2py22-dp in BH was varied from 20 to 100 wt. % to determine the appropriate ratio needed while increasing device efficiency. The EQE vs luminance plots are shown in FIG. 21 with the EL spectra depicted in the inset. Devices 5, 6, 7 and 8 showed blue-to-amber peak emission intensity ratios of 0.16, 0.14, 0.04, and 0 while they exhibited peak device efficiencies of 21.5%, 24.4%, 26.7% and 33.6%, respectively. The improvement in EQEs can be attributed to the reduced concentration of BH that would quench the Pd3O8-Py5 excitons. All devices also achieved low efficiency roll-off within the high brightness range. Accelerated operational lifetime testing was carried out on devices 5-8, exhibiting measured LT₉₅ lifetimes of 442, 240, 119, and 48.1 hours at 20 mA cm⁻²(FIG. 22). Based on the overall results, device 6 with a 5 nm 50 wt. % 2py22-dp:BH interlayer provides the best performance by attaining a comparably high EQE, long device lifetime, and maintaining reasonable portions of blue emission compared to the other devices.

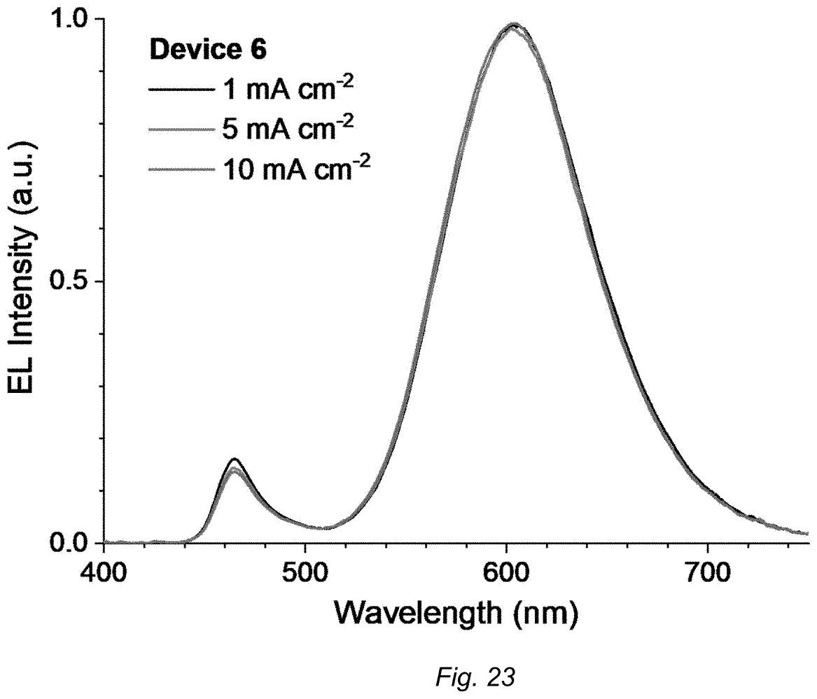

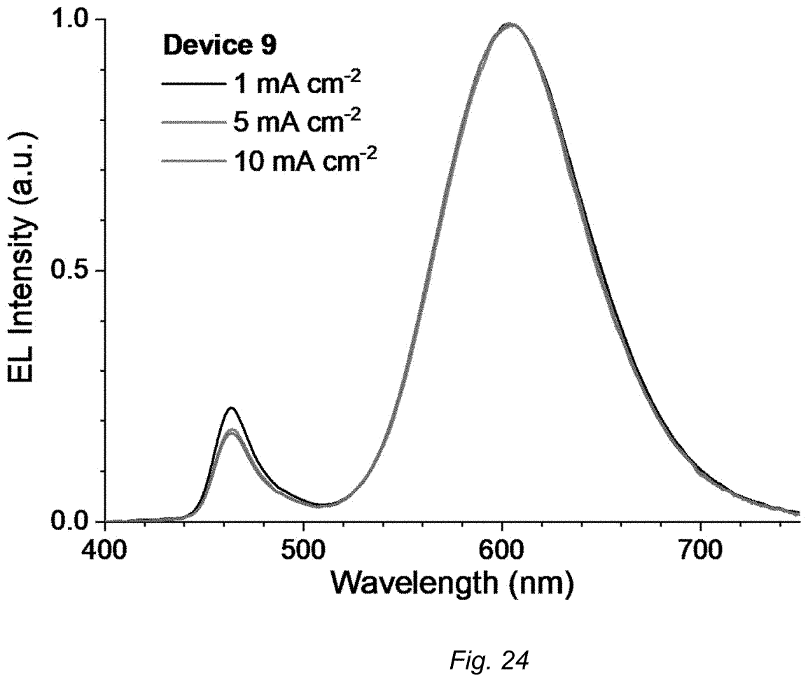

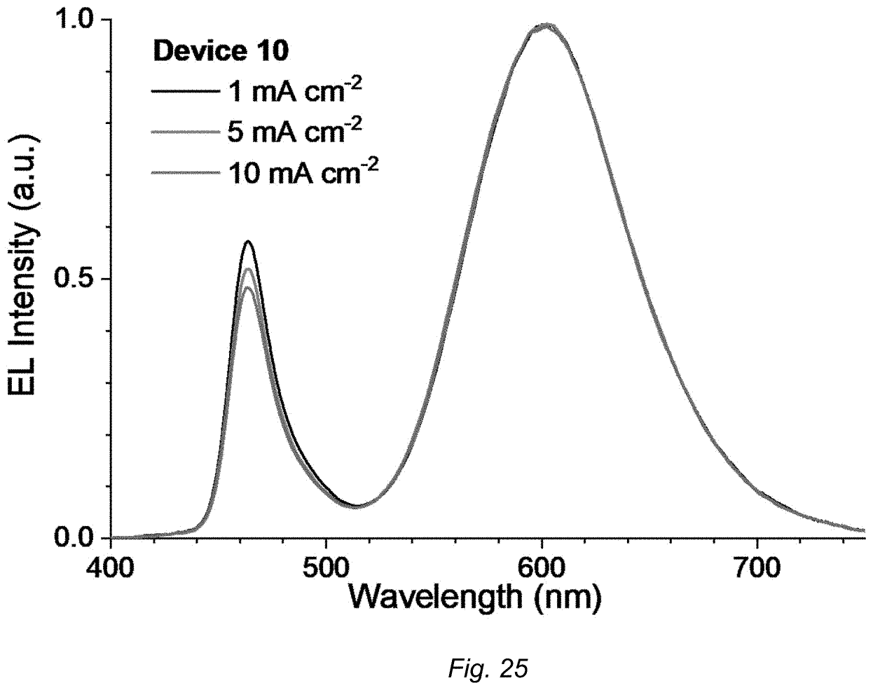

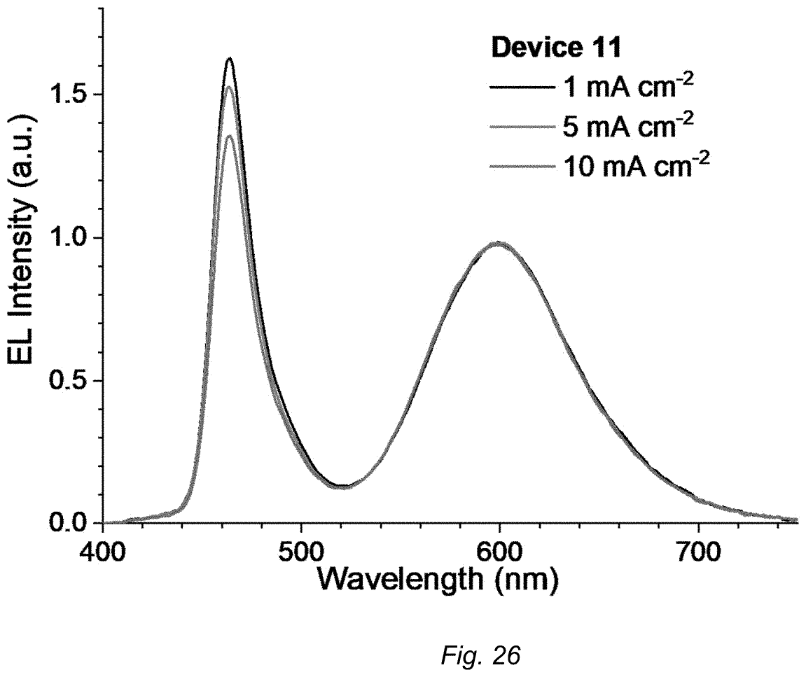

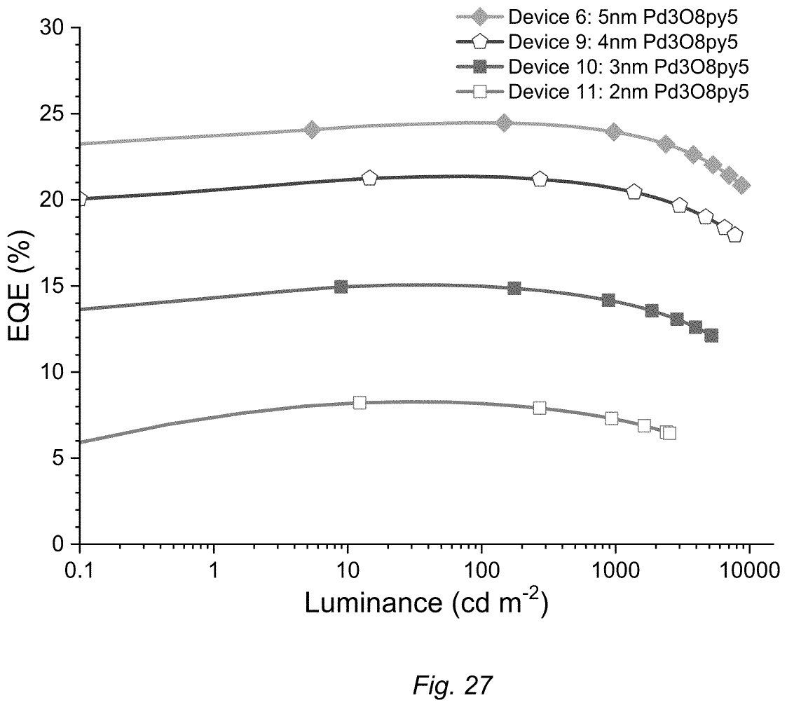

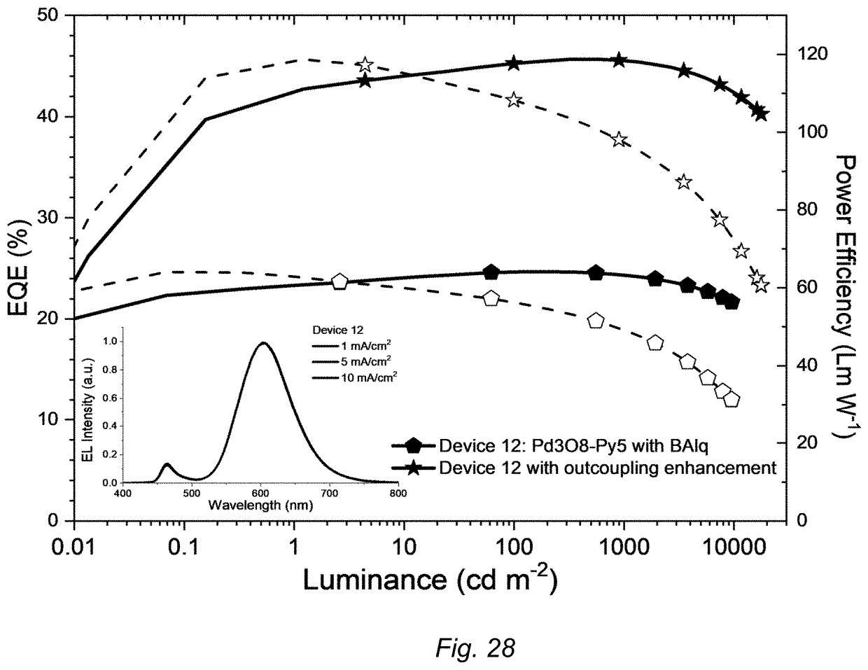

The ratio of blue to amber peak emission intensity can be increased by using a thinner layer of Pd3O8-Py5. Devices 6, 9 to 11 were fabricated with Pd3O8-Py5 thicknesses of 5, 4, 3, and 2 nm, respectively. All devices obtained similar turn on voltages within the range of 2.43-2.54V and the ratios of blue to amber emission peak intensity at 1 mA cm⁻² for devices 6, 9-11 were 0.14, 0.23, 0.58, and 1.68 (FIGS. 23-26), respectively while all devices showed a slight decrease in the blue to amber emission peak ratio at higher current densities. The efficiency was subsequently reduced with an increase in blue emission as revealed in FIG. 27, with peak EQEs of 24.4, 21.3, 15.0 and 8.25% for devices 6, 9-11, respectively. At a constant driving current density of 20 mA cm⁻², the LT₉₅ values of devices 6, 9-11 were 240, 301, 217, and 164 hours (FIG. 28).

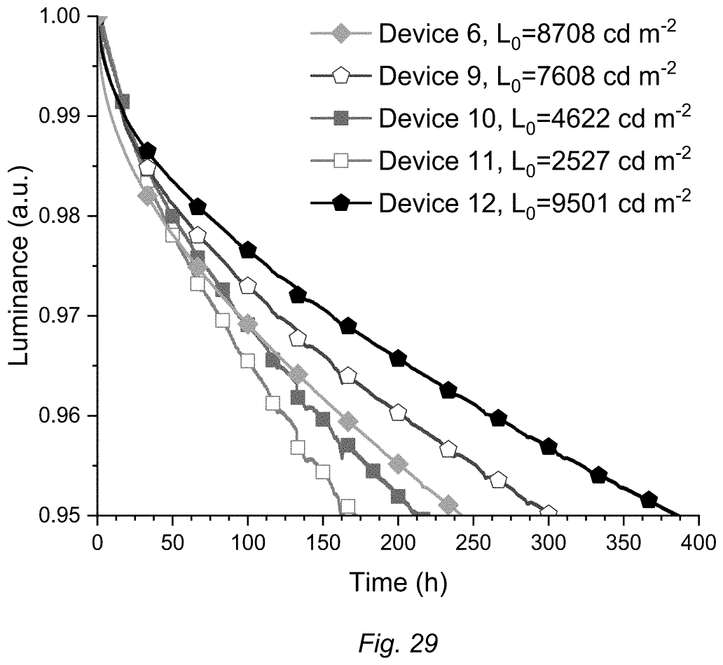

To further improve the device performance, device 12 was fabricated in a similar device setting as device 6 with the addition of a 10 nm BAlq layer of between the EML and BPyTP with the aim of slowing electron injection to the EML and broadening the exciton recombination zone. Device 12 achieved a peak EQE of 24.5% and a blue to amber emission peak intensity ratio of 0.14, similar to those of device 6; however, the EL spectra demonstrated a stable EL emission under various driving conditions (FIG. 29). Additionally, the presence of the BAlq layer helped to further improve the device stability, as intended, reaching a LT₉₅ of 385 hours at an initial luminance of 9501 cd m⁻².

By applying an index matching gel between the silicon photodiode and the OLED glass substrate without an air gap (J. Lee, et al., Advanced Energy Materials 1, 174-178 (2011); Y. Sun, S. R. Forrest, Nature Photonics 2, 483-487 (2008)), the remeasured peak EQE of device 12 reached 45.6%, which consists of both air mode and substrate mode device efficiencies. The device maintained its high efficiencies within a high brightness range, reaching an EQE of 45.5% and a PE of 97.4 Lm W⁻¹ at 1000 cd m⁻². Based on a measured LT₉₅ of 385 hours at the initial luminance of 17,661 cd m⁻², device 12 exhibited an estimated LT₉₅ of 50,744 hours at a practical luminance of 1000 cd m⁻², using the formula LT(L₁)═LT(L₀)(L₀/L₁)ⁿ, where L₁ is the desired luminance and the exponent n is assumed to be a moderate value of 1.7 (44, 45). Such an extraordinary long device operational lifetime is the longest reported lifetime of a single stack WOLED in the public domain (FIGS. 28 and 29).

The proposed device concept for a single-stack WOLED utilizing phosphorescent molecular aggregates provides a comprehensive performance that is unmatched to any WOLED device reported within the literature domain or available in the commercial market. While most recent demonstrations of single-stack hybrid or all phosphorescent WOLEDs have realized peak EQEs over 20%, they lack to meet all commercialization standards simultaneously. Various strategies, such as managing singlet and triplet exciton distribution (Y. Sun, et al., Nature 440, 908-912 (2006)) or developing blue fluorescent materials with high triplet energy (G. Schwartz, et al., Advanced Materials 19, 3672-3676 (2007)), have been previously explored. For example, a hybrid WOLED developed by Wang and coworkers, employing materials with hybridized local and charge-transfer excited states, realized a peak EQE of 25.4% and a high EQE of 25.2% at 1000 cd m⁻² (H. Zhang, et al., Advanced Functional Materials 31, 2100704 (2021)). However, the EL spectra of such devices showed minimal blue contribution. An all phosphorescent WOLED by Ma and coworkers was also able to obtain low efficiency roll-off by adopting an ultra-thin non-doped orange emission layer in between two blue emission layers to reduce TTA effects, which realized a maximum EQE of 23.1% and retained an EQE of 22.2% at 1000 cd M⁻² (L. Zhu, et al., Journal of Applied Physics 115, 244512 (2014)). TADF emitters, which have captured much interest for their abilities to reach 100% IQE without the use of heavy metal atoms, have also been explored for their use in WOLED device structures. For example, a highly efficient WOLED employing TADF emitters, developed by Lee and coworkers, reached a peak EQE of 32.8% by doping an orange-red TADF emitter into a blue TADF host material (J.-X. Chen, et al., Advanced Functional Materials 31, 2101647 (2021)). Fung and coworkers were also able to fabricate a highly efficient WOLED by using a TADF exciplex host, which reached a peak EQE of 28.1% (S.-F. Wu, et al., Advanced Functional Materials 27, 1701314 (2017)). However, both devices experienced an efficiency roll-off which reduced the EQE to 24.1% and 21.5% at a practical brightness of 1000 cd m⁻², respectively. In comparison, the device discussed in this report achieved an EQE of 24.3% at 1000 cd M⁻² on a regular glass substrate.

The WOLED reported herein also showed exceptional operational stability which has not been achieved by any other WOLED reported in literature or available commercially. Examples of stable WOLEDs reported in literature include a hybrid WOLED device by Ma and coworkers, which used an assistant layer to promote TTA enhancement and demonstrated a LT₅₀ of 600 hours at 1000 cd m⁻² (Y. Chen, et al., Journal of Materials Chemistry C 8, 6577-6586 (2020)). A hybrid WOLED developed by Hosokawa and coworkers (K. Nishimura, et al., SID Symposium Digest of Technical Papers 40, 310-313 (2009)) was able to achieve a PE of 27.4 Lm W⁻¹ and a LT₅₀ of about 200,000 h at 1000 cd m⁻². Meanwhile, the inventive device can realize an estimated LT₅₀ of 1,828,483 hours and a high PE of 49.2 Lm W⁻¹ at 1000 cd m⁻² without outcoupling enhancement technologies, due to the selection of highly stable phosphorescent aggregates and blue fluorescent emitters.

All of the previously discussed devices from literature also exhibited unstable emission color under various driving conditions, which presents one of main technical challenges in the development of single-stack WOLED and impedes its commercialization progress for lighting applications. On the other hand, tandem WOLEDs can achieve improved color stabilities by confining the blue emissive layer and amber (or mixed green and red) emissive layers in their own OLED stacks and tuning the device architecture to enable each monochromic OLED stack to maintain similar efficiency-current density characteristics. Additionally, the stacked design can afford to drive the device at lower current densities to achieve targeted brightness and thus improve the device operational stability. To develop efficient and stable white phosphorescent OLEDs, Forrest and coworkers fabricated a five-stack WOLED consisting of 48 separate layers which realized an EQE of 170%, PE of 44.7 Lm W⁻¹ and a LT7o of 80,000 hours at 1000 cd m⁻² on a glass substrate (C. Coburn, et al., ACS Photonics 5, 630-635 (2018)). Despite achieving a long operational lifetime using a blue phosphorescent EML, the complexity of the device structure may not be feasible or cost effective at a high production volume scale. The single stack WOLED presented in this report not only employs a simpler device architecture, but also attained a longer LT₇₀ of 561,408 hours and a higher PE of 49.2 Lm W⁻¹, making it more commercially viable. The current commercially available OLED lighting panels are three-stack WOLEDs (manufactured by OLEDWorks) employing the state-of-the-art blue fluorescent emitters and green and red phosphorescent emitters, with a reported PE of 80 Lm W⁻¹ and a LT₇₀ of 100,000 hours at 3000 cd 111⁻² with the integration of both internal and external extraction techniques. In comparison, the inventive single-stack WOLED was able to realize a PE of 88.5 Lm W⁻¹ and an estimated LT₇₀ of 248,823 hours at 3000 cd m⁻² by using an external light extraction technique, which demonstrated a great potential of employing single-stack hybrid WOLED for lighting applications.

TABLE 1
Summary of selected device performance data
(*remeasured with optical matching glue).

| | | EQE (%) | | PE (Lm W⁻¹) | | LT₉₅ | | |
|---|---|---|---|---|---|---|---|---|
| | | | @1000 | | @1000 | | | @1000 |
| Device | CIE | Peak | cdm⁻² | Peak | cdm⁻² | L₀ | @L₀ | cdm⁻² |
| 1 | (0.557, 0.416) | 21.2 | 20.9 | 58.7 | 47.0 | 8315 | 302 | 11060 |
| 6 | (0.551, 0.404) | 24.4 | 23.9 | 66.5 | 48.9 | 8708 | 240 | 9507 |
| 9 | (0.532, 0.398) | 21.3 | 20.6 | 58.9 | 43.9 | 7608 | 301 | 9478 |
| 10 | (0.480, 0.368) | 15.0 | 14.1 | 39.2 | 28.3 | 4622 | 217 | 2928 |
| 11 | (0.384, 0.301) | 8.27 | 7.2 | 18.7 | 12.3 | 2527 | 164 | 793 |
| 12 | (0.546, 0.408) | 24.5 | 24.3 | 64.0 | 49.2 | 9501 | 385 | 17687 |
| 12* | (0.546, 0.408) | 45.6 | 45.5 | 118 | 97.4 | 17661 | 385 | 50744 |

In summary, the present disclosure introduces a single-stack WOLED concept employing amber phosphorescent molecular-aggregates and blue fluorescent emitters which ultimately realized an EQE of 45.5%, a PE of 97.4 Lm W⁻¹ and an estimated LT₉₅ of 50,744 hours at 1000 cd m⁻². In addition, such device demonstrated exceptional color stability with negligible changes in the emission color under various current densities. The overall device performance of this developed single-stack WOLED has met or exceeded the benchmark set for early adoption of commercially viable OLED lighting product. The emission color can be tuned to achieve better color balance by managing the Pd3O8-Py5 layer thickness with potential loss of device efficiency. The performance of single-stack WOLED can be further improved by adopting more electrochemically stable and preferably horizontal aligned blue fluorescent emitter (T. D. Schmidt, et al., Physical Review Applied 8, 037001 (2017); Y. Fu, et al., Science Advances 7, eabj2504 (2021)). Moreover, recent advancements in stable and efficient tetradentate Pt based blue phosphorescent emitters could be integrated with these developed amber phosphorescent aggregates to fabricate single stack white phosphorescent OLEDs with improved quality of white emission (J. Sun, et al., Nature Photonics 16, 212-218 (2022); T. Fleetham, et al., Advanced Materials 29, 1601861 (2017)). Overall, the remarkable performance of the inventive WOLED lays the groundwork for the further advancement and eventual commercialization of WOLED technology for lighting applications.

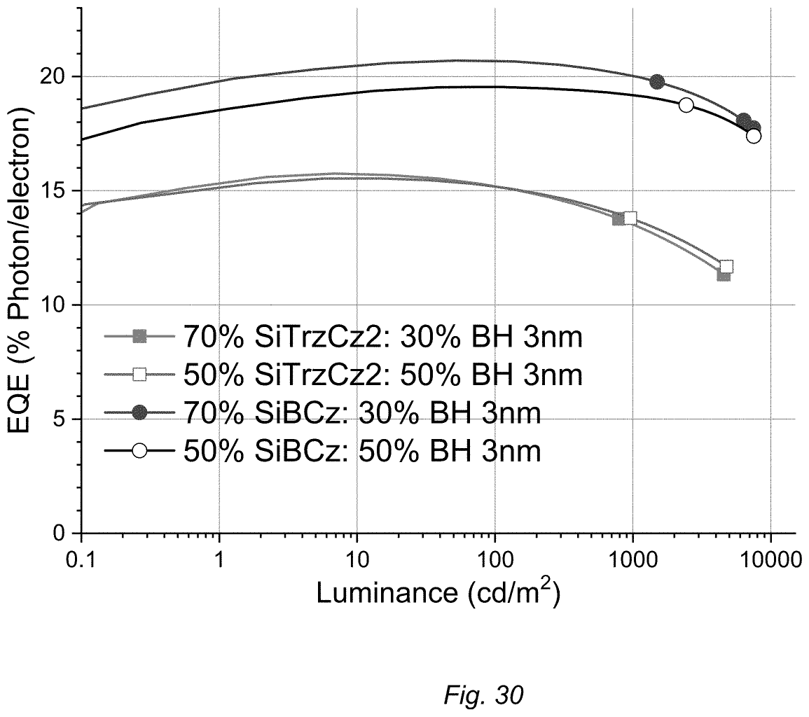

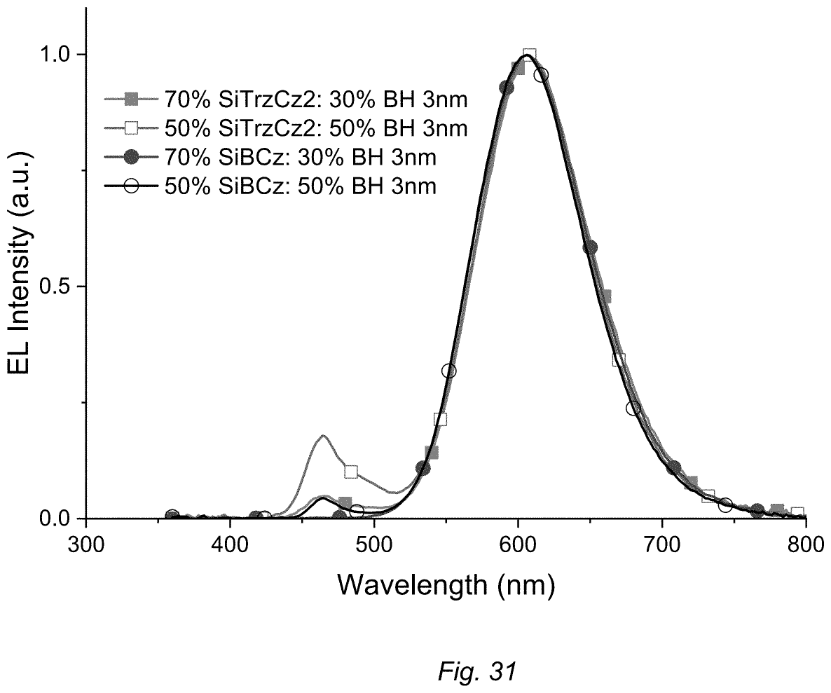

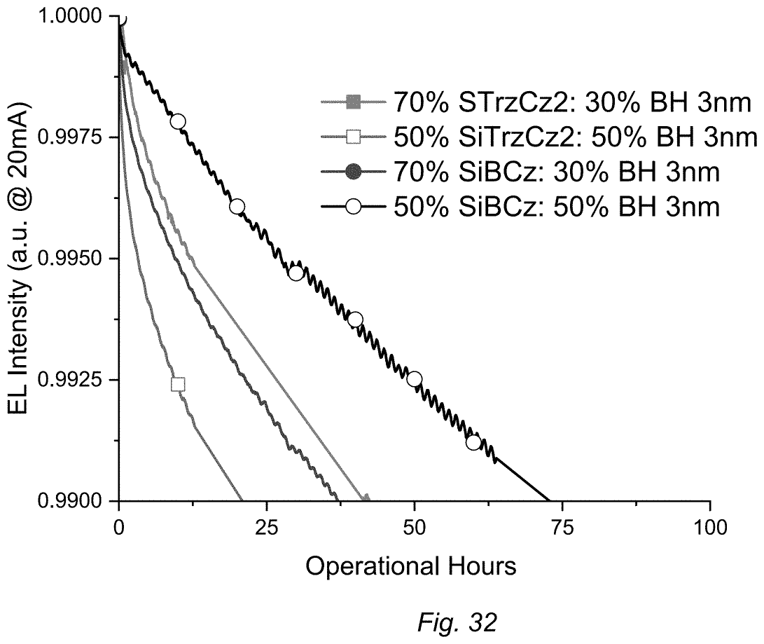

Devices were also constructed using SiBCz and SiTrzCz2 as high energy gap materials. The devices had the structure of 100 nm ITO/HATCN (10 nm)/NPD (70 nm)/TrisPcz (10 nm)/P d3 08-py 5 (5 nm)/X/2% FLB2:BH (30 nm)/BPYTP (40 nm)/Liq (2 nm)/Al, where X is, 3 nm 50% SiBCz:BH, 3 nm 70% SiBCz:BH, 3 nm 50% SiTrzCz2:BH and 3 nm 70% SiTrzCz2:BH. EQE of these devices are shown in FIG. 30. The electroluminescent spectra of the devices are shown in FIG. 31. Device performances over time at an EL intensity of 20 mA/cm² are shown in FIG. 32.

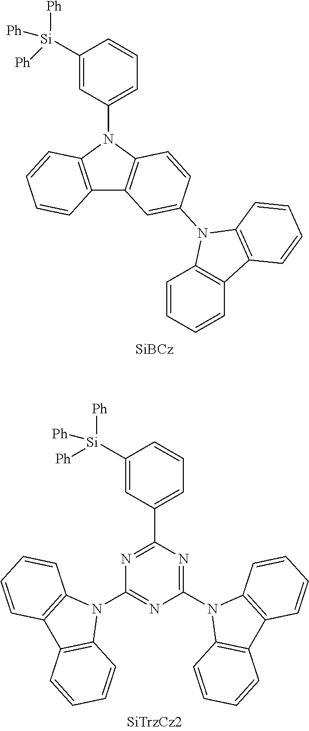 [SMILES: c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

We claim:

1. A white organic light emitting device comprising:
a first emissive layer comprising a phosphorescent emitter;
a second emissive layer comprising a fluorescent emitter; and
an interface layer, disposed between the first emissive layer and the second emissive layer;
wherein the interface layer comprises a high energy gap material represented by Formula I, Formula II, or Formula III: 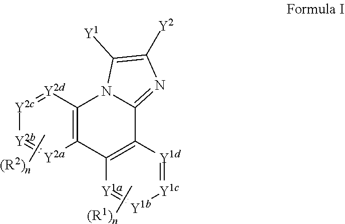
wherein in Formula I:
Y^{1a}, Y^{1b}, Y^{1c}, Y^{1d}, Y^{2a}, Y^{2b}, Y^{2c}, Y^{2d}, each independently represents C or N; wherein at least two of Y^{1a}, Y^{1b}, Y^{1c}, Y^{1d}, Y^{2a}, Y^{2b}, Y^{2c}, and Y^{2d} represent N;
Y¹ and Y² independently represent hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; Y¹ and Y² may together form a ring which is optionally further studied;
R¹ and R² are independently absent or present, valency permitting, and each R¹ and R² independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; any two adjacent R¹ and R² may together form a ring; and
each n is an integer, valency permitting; 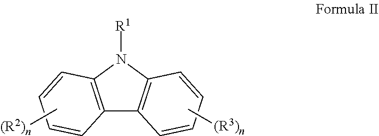
wherein in Formula II:
Each of R¹, R², and R³ is independently absent or present as a single substituent or multiple substituents, valency permitting, and each R¹, R², and R³ present independently represents hydrogen, deuterium, halogen, hydroxyl, thiol, nitro, cyanide, isocyanide, sulfinyl, mercapto, sulfo, carboxyl, hydrazino; substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof; and
each n is an integer, valency permitting; 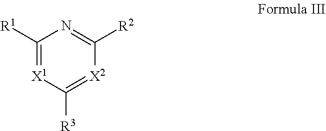
wherein in Formula III:
each of X¹ and X² is independently N or C—R⁴.
each of R¹, R², R³, and R⁴ independently represents hydrogen, deuterium, halogen, hydroxyl, thiol, nitro, cyanide, isocyanide, sulfinyl, mercapto, sulfo, carboxyl, hydrazino;
substituted or unsubstituted: triphenylsilyl, carbazolyl, aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof.

2. The device of claim 1, wherein the high energy gap material is represented by Formula I.

3. The device of claim 1, wherein the high energy gap material is represented by Formula II.

4. The device of claim 1, wherein the high energy gap material is represented by Formula III.

5. The device of claim 1, wherein, in Formula I, at least one of Y^{1a}, Y^{1b}, Y^{1c}, and Y^{1d} is N, and at least one of Y^{2a}, Y^{2b}, Y^{2c}, and Y^{2d} is N.

6. The device of claim 1, wherein, in Formula I, Y¹ and Y² are each selected from the group consisting of alkyl, aryl, heteroaryl, and combinations thereof.

7. The device of claim 1, wherein the high energy gap material is selected from the group consisting of:

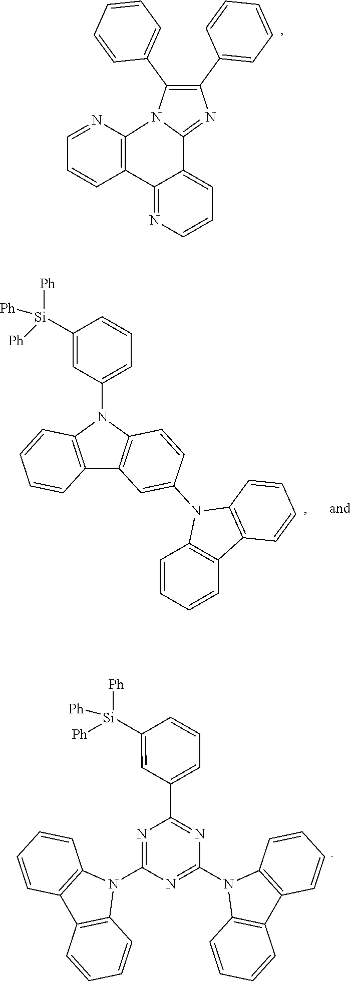 [SMILES: c1ccc(-c2nc3c4cccnc4c4cccnc4n3c2-c2ccccc2)cc1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

8. The device of claim 1, wherein the fluorescent emitter harvests singlet excitons and emits blue light; and wherein the phosphorescent emitter harvests triplet excitons and emits yellow-amber light.

9. The device of claim 1, wherein the interface layer further comprises a compound of Formula A: 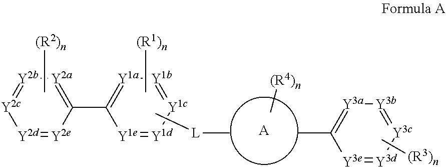
wherein
ring A is a fused polycyclic aryl or heteroaryl rings having at least 14 atoms selected from the group consisting of C and N;
Y^{1a}, Y^{1b}, Y^{1c}, Y^{1d}, Y^{1e}, Y^{2a}, Y^{2b}, Y^{2c}, Y^{2d}, Y^{2e}, Y^{3a}, Y^{3b}, Y^{3c}, Y^{3d}, and Y^{3e} each independently represents C or N;
Y^{1a} and Y^{2a} are optionally linked via linking atom Z, wherein Z represents O, S, Se, NR⁴, P═O, As═O, BR⁴, AlR⁴, Bi═O, CR⁴R⁵, C═O, SiR⁴R⁵, GeR⁴R⁵, PR⁴, PR⁴R⁵, R⁴P═O, AsR⁴, R⁴As═O, S═O, SO₂, Se═O, SeO₂, BR⁴R⁵, AlR⁴, AlR⁴R⁵, R⁴Bi═O, or BiR⁴;
L is a divalent linking group selected from the group consisting of a covalent bond, O, S, Se, alkylene, monoalkylamine, monoarylamine, monoheteroarylamine, arylene, heteroarylene, and combinations thereof; wherein L forms a bond with ring A and with one of Y^{1a}, Y^{1b}, Y^{1c}, Y^{1d}, or Y^{1e}; or L is a trivalent linking atom selected from the group consisting of B, N, P, CR⁴, SiR⁴, Al, GeR⁴, PR⁴, P═O, As, As═O, BR⁴, AlR⁴, Bi, and Bi═O, wherein L forms one bond with ring A, one bond with Y^{1a}, and one bond with Y^{2a};
R¹, R², R³, and R⁴ each independently represents hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric; or any conjugate or combination thereof;
any two adjacent R¹, R², R³, and R⁴ may together form a fused ring; and
each n is independently an integer, valency permitting.

10. The device of claim 9, wherein the compound of Formula A has one of the following structures:

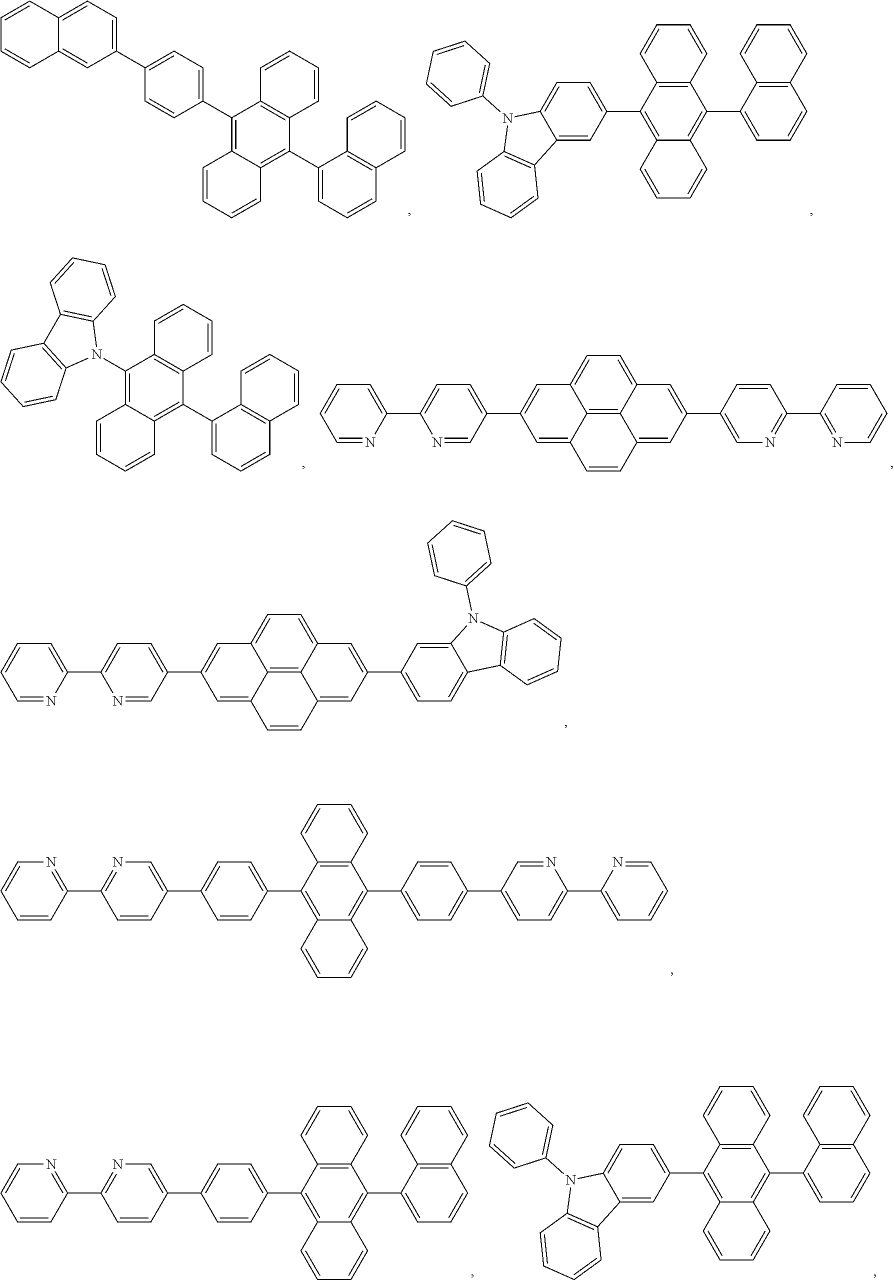

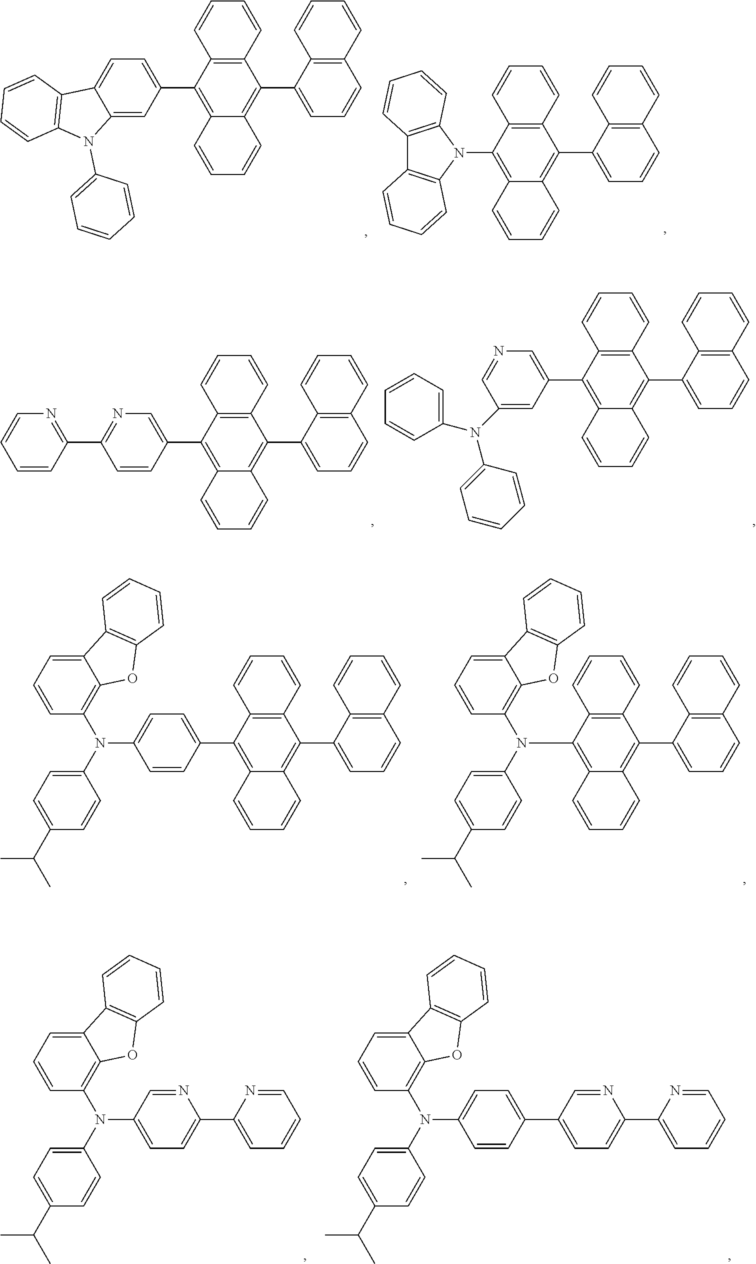

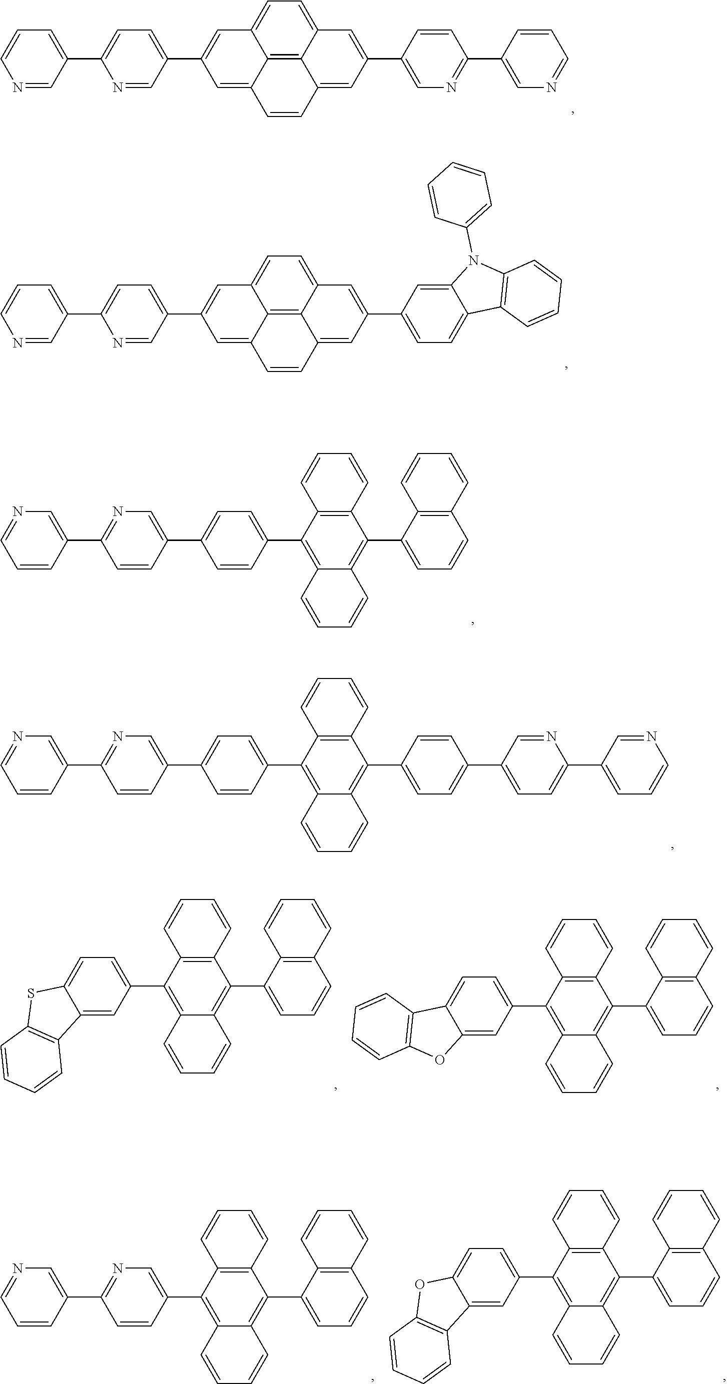

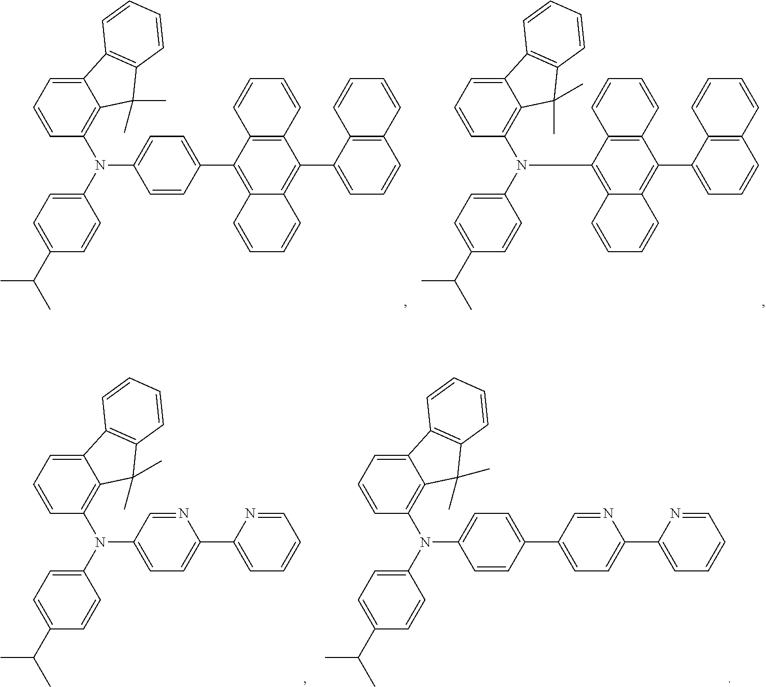 [SMILES: CC(C)c1ccc(N(c2ccc(-c3c4ccccc4c(-c4cccc5ccccc45)c4ccccc34)cc2)c2cccc3c2C(C)(C)c2ccccc2-3)cc1 ; CC(C)c1ccc(N(c2cccc3c2C(C)(C)c2ccccc2-3)c2c3ccccc3c(-c3cccc4ccccc34)c3ccccc23)cc1 ; CC(C)c1ccc(N(c2ccc(-c3ccccn3)nc2)c2cccc3c2C(C)(C)c2ccccc2-3)cc1 ; CC(C)c1ccc(N(c2ccc(-c3ccc(-c4ccccn4)nc3)cc2)c2cccc3c2C(C)(C)c2ccccc2-3)cc1]

11. The device of claim 9, wherein the molar ratio or the weight ratio between the compound of Formula I, Formula II, or Formula III and the compound of Formula A is between about 4:1 to about 1:4.

12. The device of claim 9, wherein the molar ratio or the weight ratio between the compound of Formula I, Formula II, or Formula III and the compound of Formula A is about 1:1.

13. The device of claim 1, wherein the interface layer has a thickness of about 2 to about 5 nm.

14. The device of claim 1, wherein the phosphorescent emitter is a compound of Formula X: 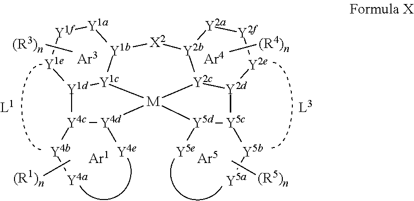
wherein, in Formula X:
M represents Pt(II) or Pd(II);
R¹, R³, R⁴, and R⁵ each independently represents hydrogen, halogen, hydroxyl, nitro, cyanide, thiol, or optionally substituted C₁-C₄ alkyl, alkoxy, amino, or aryl;
each n is independently an integer, valency permitting;
Y^{1a}, Y^{1b}, Y^{1c}, Y^{1d}, Y^{1e}, Y^{1f}, Y^{2a}, Y^{2b}, Y^{2c}, Y^{2d}, Y^{2e}, Y^{2f}, Y^{4a}, Y^{4b}, Y^{4c}, Y^{4d}, Y^{4e}, Y^{5a}, Y^{5b}, Y^{5c}, Y^{5d}, and Y^{5e} each independently represents C, N, Si, O, S;
X² represents NR, PR, CRR′, SiRR′, CRR′, SiRR′, O, S, S═O, O═S═O, Se, Se═O, or O═Se═O, wherein R and R′ each independently represents hydrogen, halogen, hydroxyl, nitro, cyanide, thiol, or optionally substituted C₁-C₄ alkyl, alkoxy, amino, aryl, or heteroaryl;
each of L¹ and L³ is independently present or absent, and if present, represents a substituted or unsubstituted linking atom or group, where a substituted linking atom is bonded to an alkyl, alkoxy, alkenyl, alkynyl, hydroxy, amine, amide, thiol, aryl, heteroaryl, cycloalkyl, or heterocyclyl moiety;
Ar³ and Ar⁴ each independently represents a 6-membered aryl group; and
Ar¹ and Ar⁵ each independently represents a 5- to 10-membered aryl, heteroaryl, fused aryl, or fused heteroaryl.

15. The device of claim 14, wherein, in Formula X, M is Pd(II).

16. The device of claim 1, wherein the phosphorescent emitter has one of the following structures:

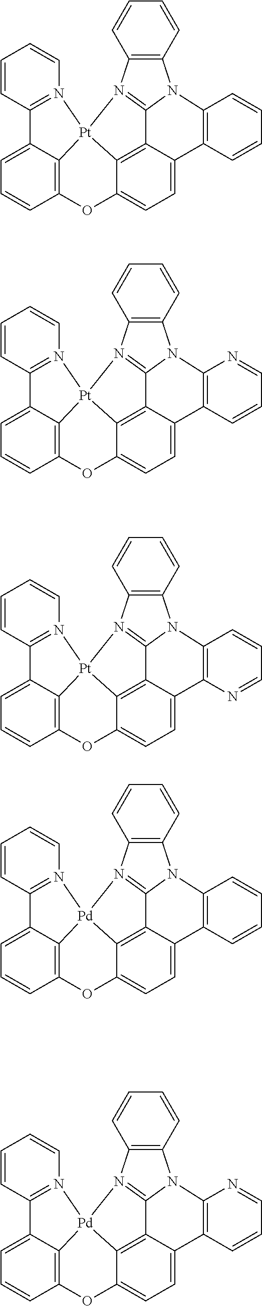

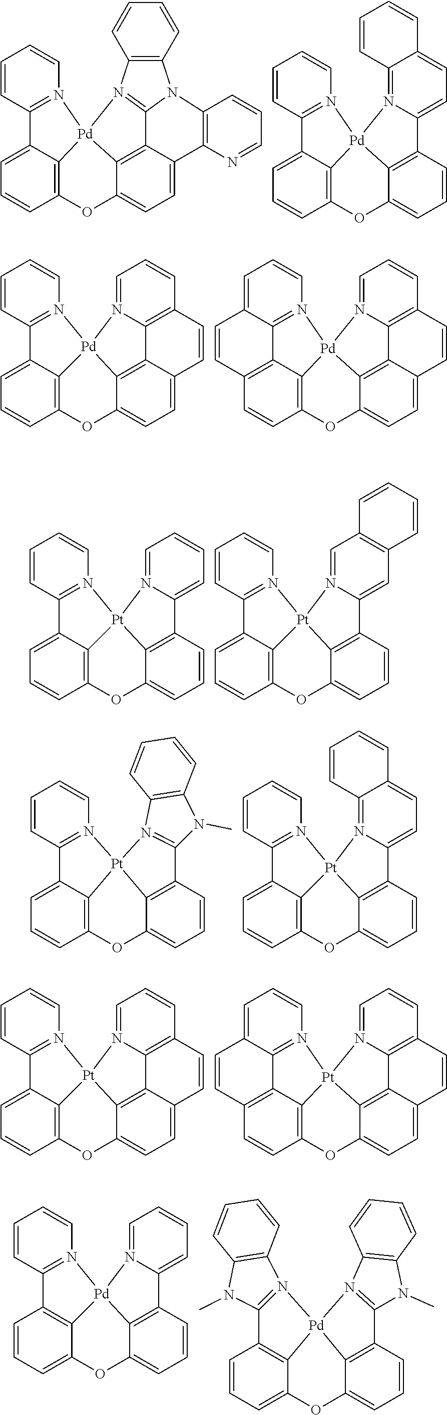

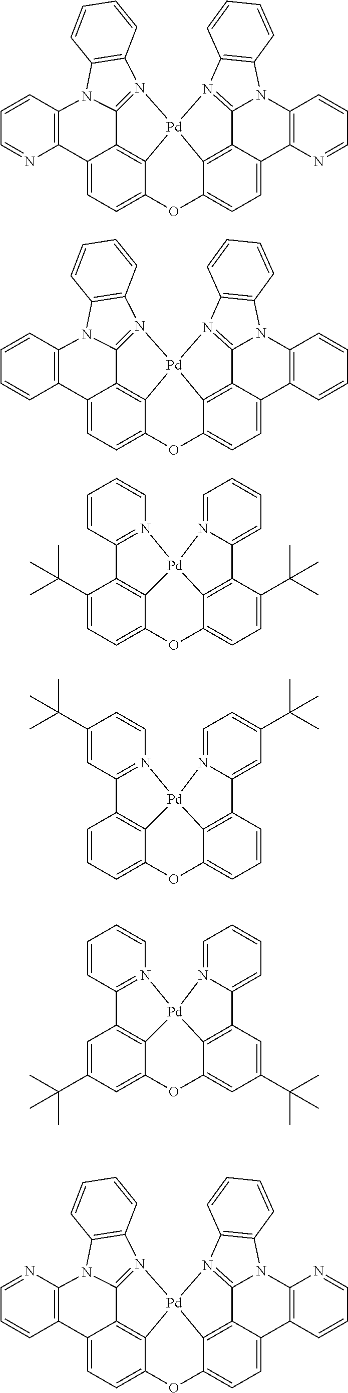

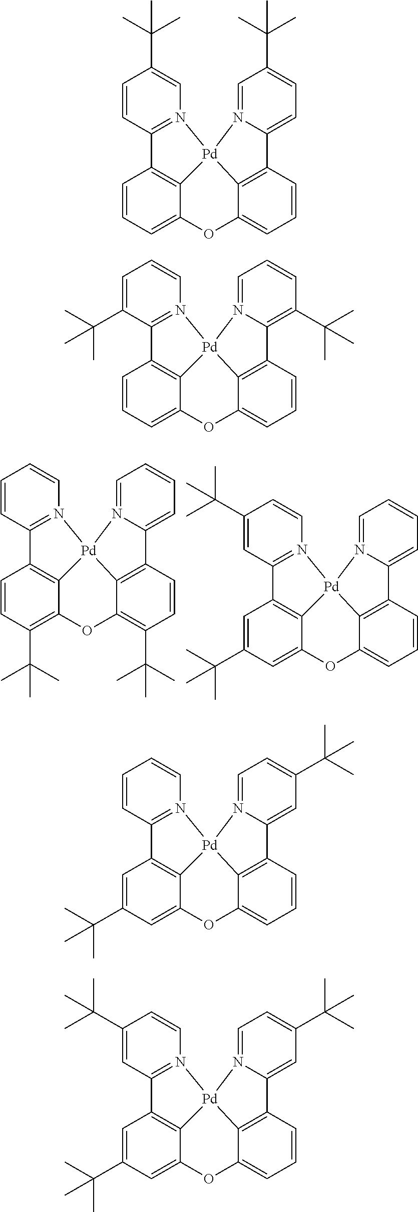

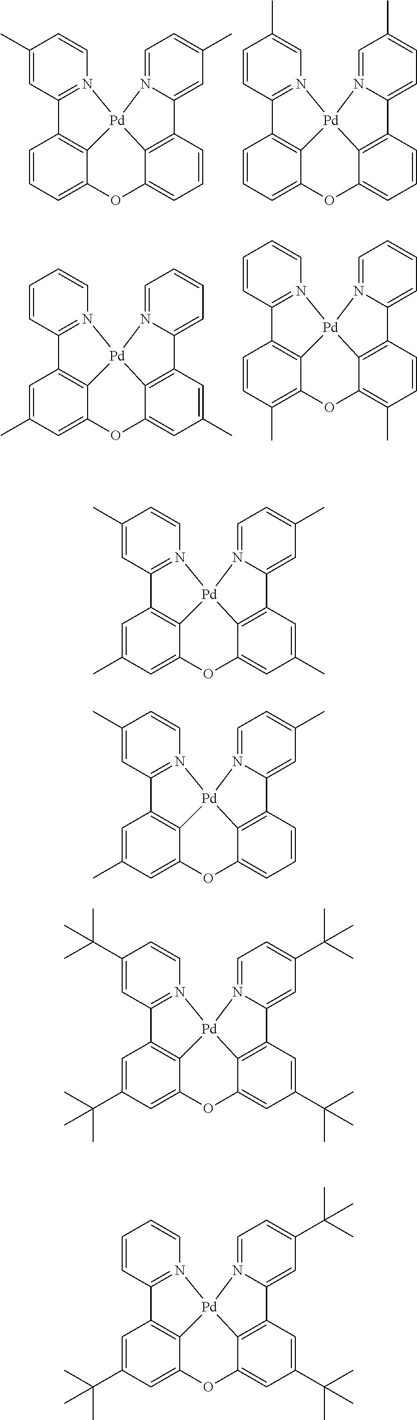

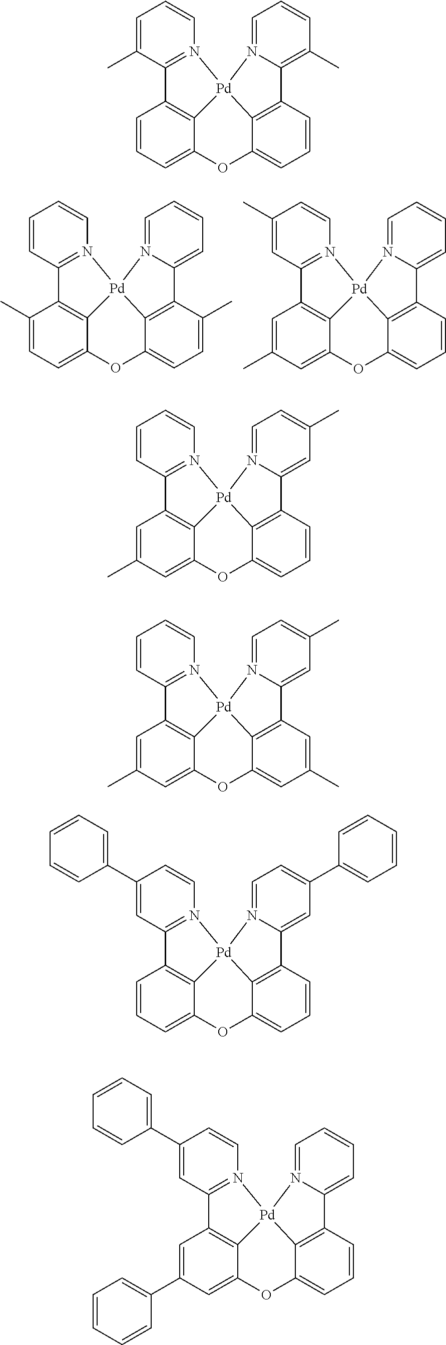

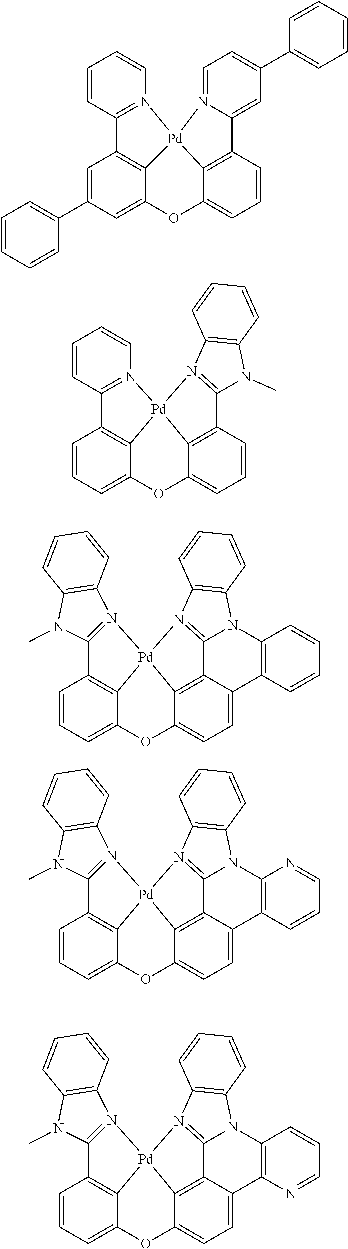

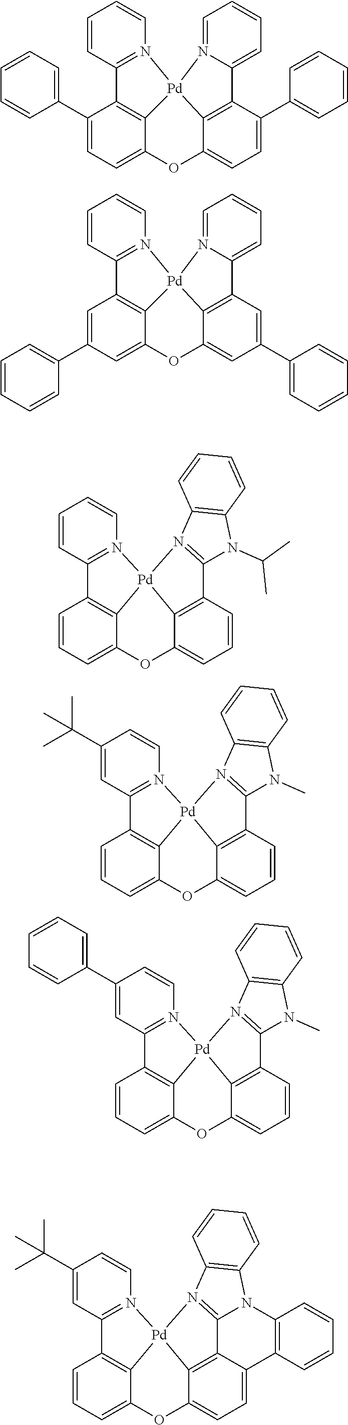

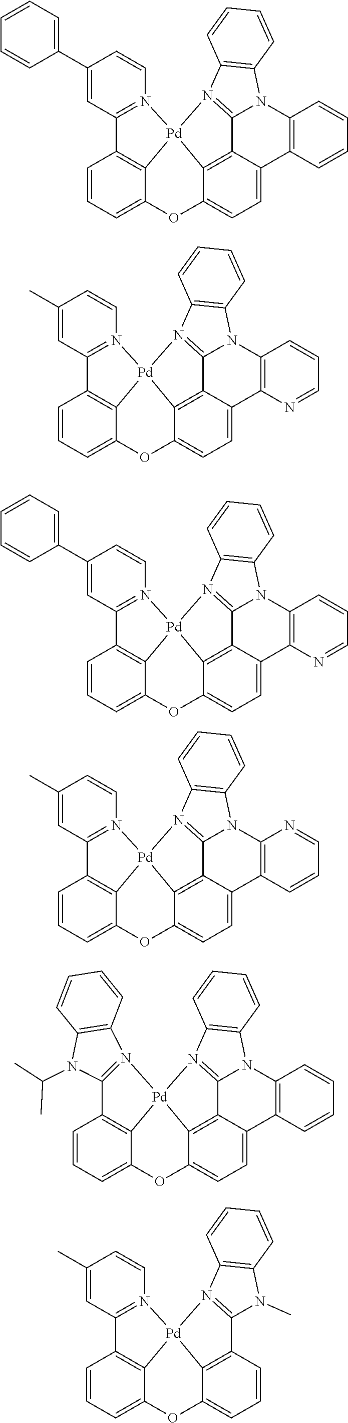

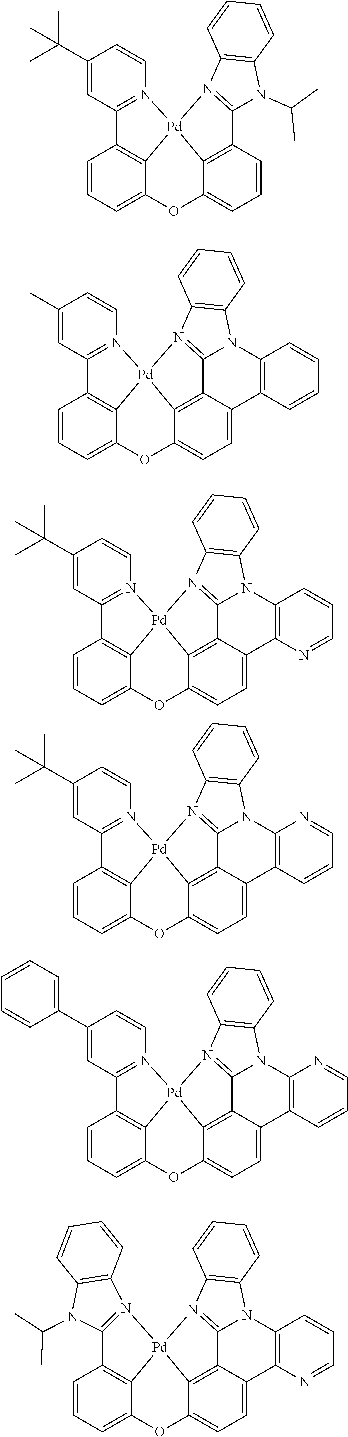

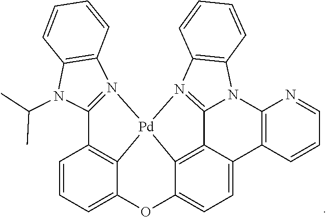

17. The device of claim 1, wherein the fluorescent emitter comprises one of the following structures:
1. Aromatic Hydrocarbons and Their Derivatives 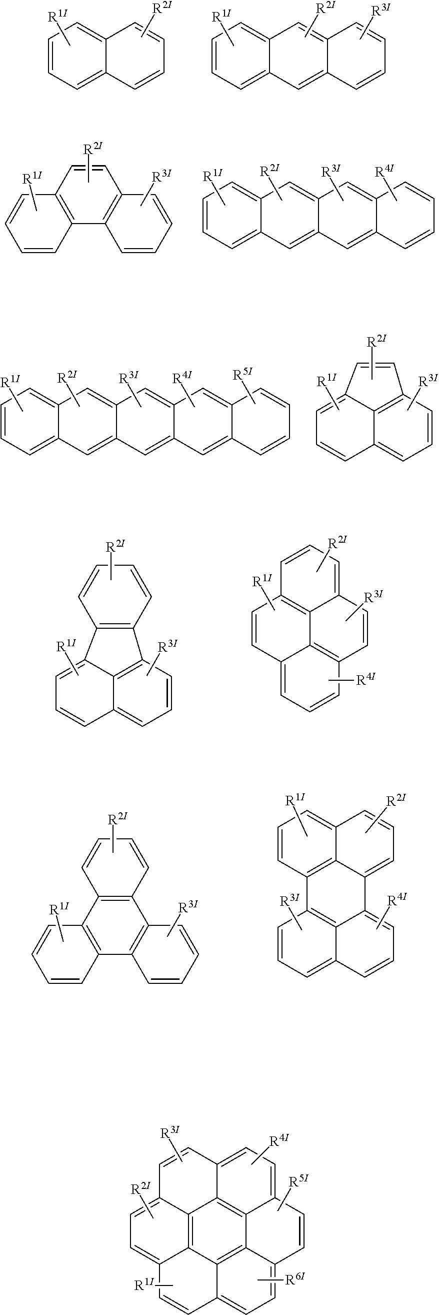 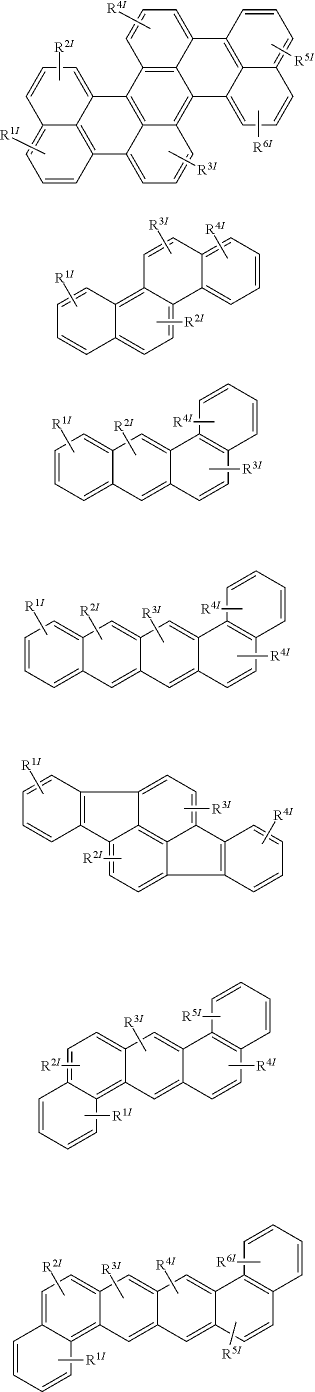 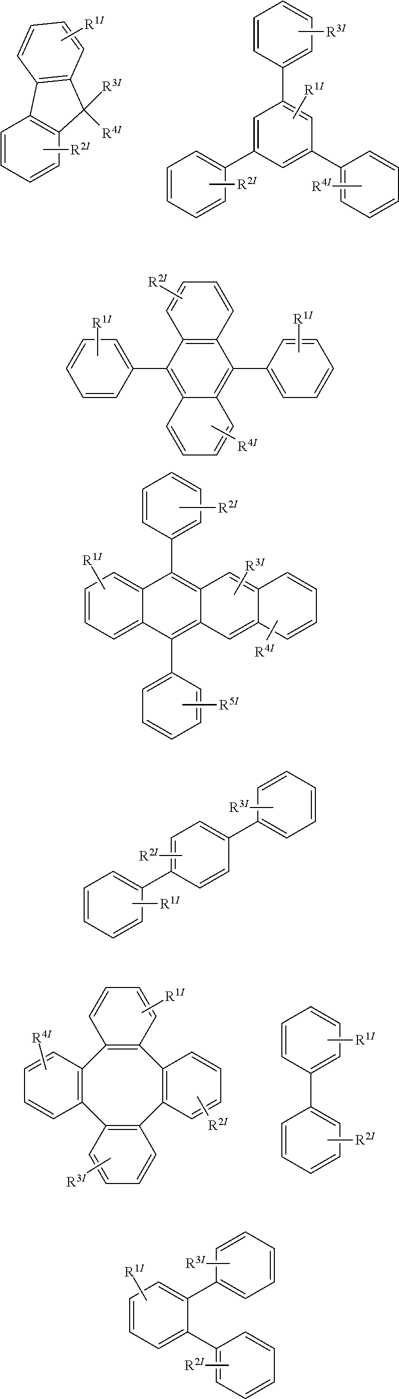 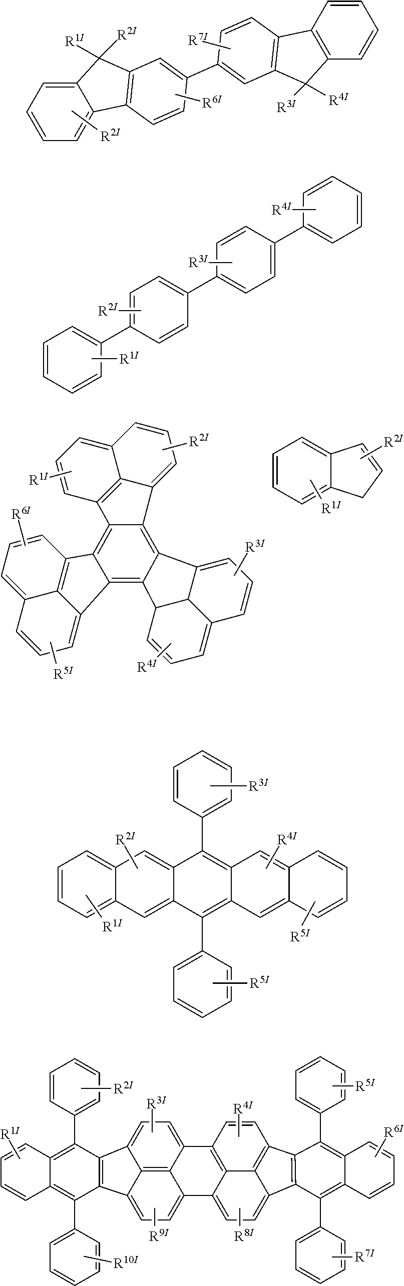 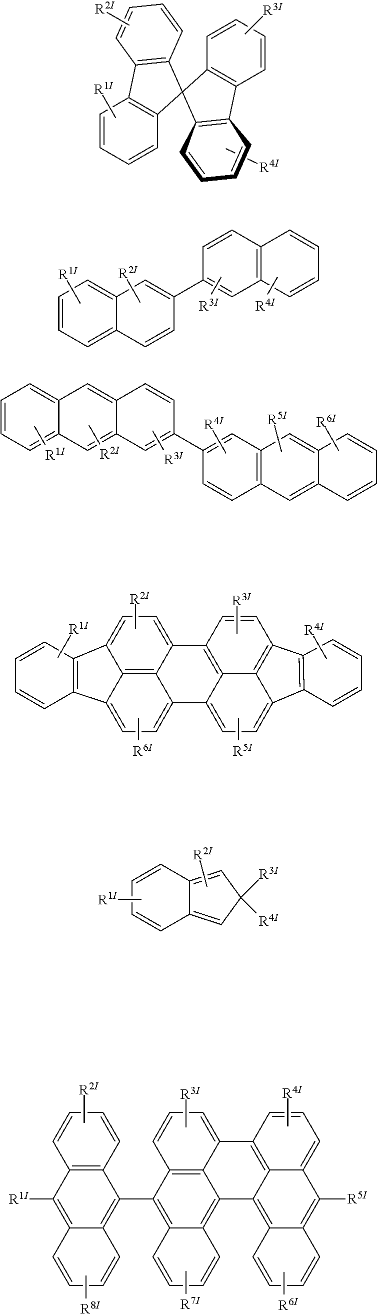
2. Arylethylene, Arylacetylene and Their Derivatives 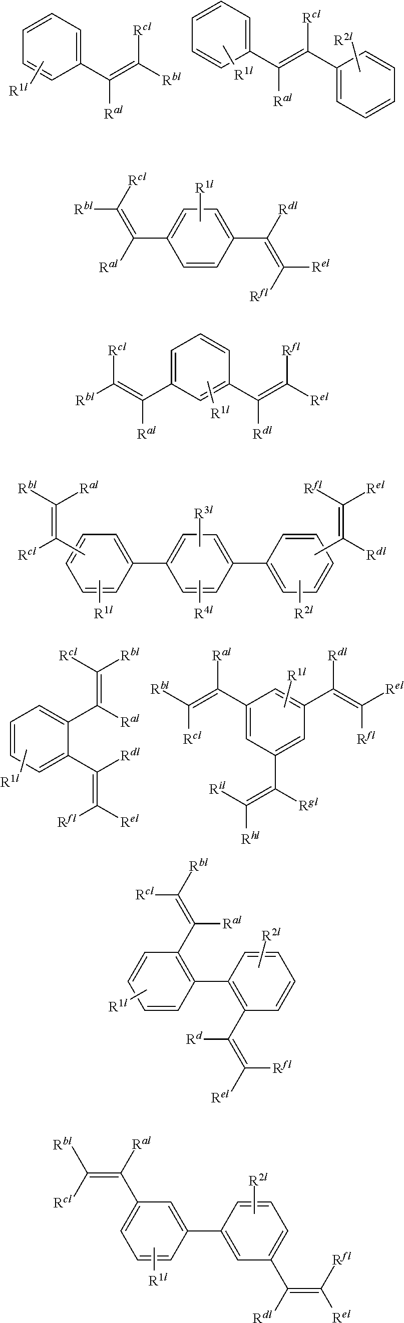 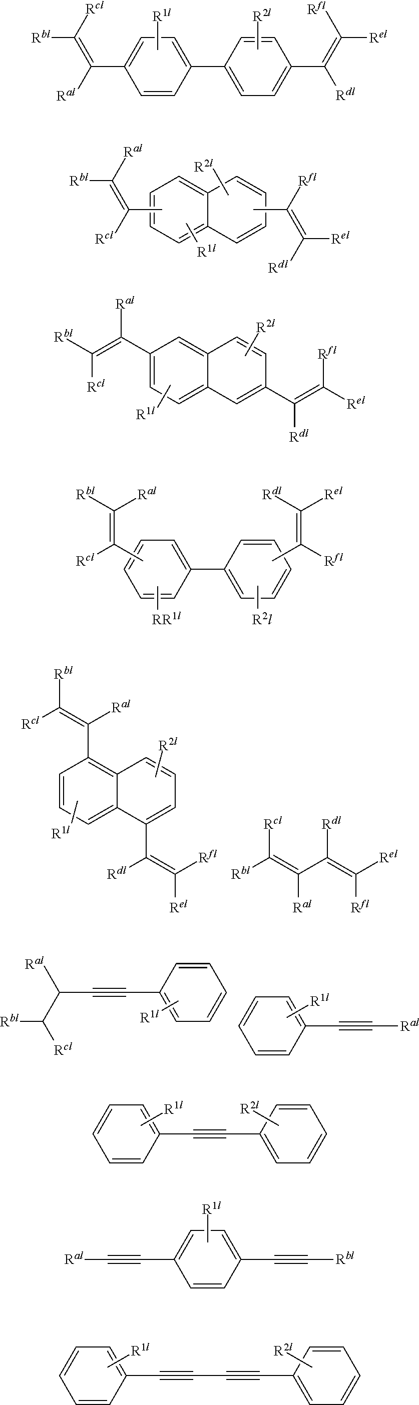 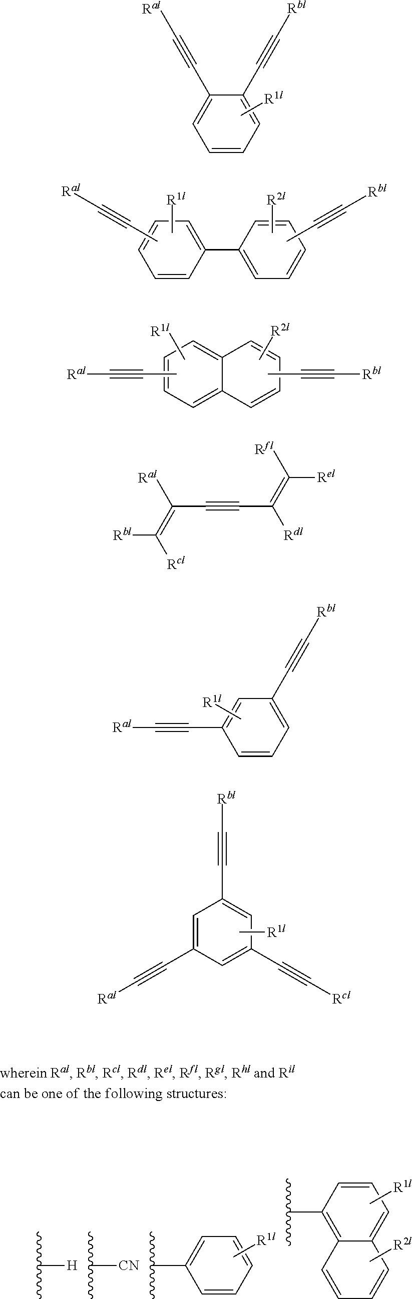 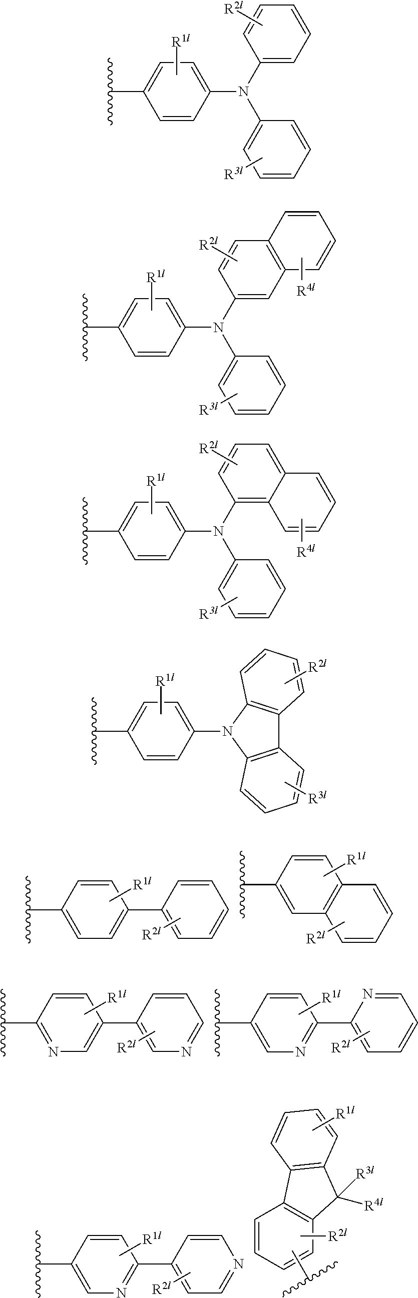 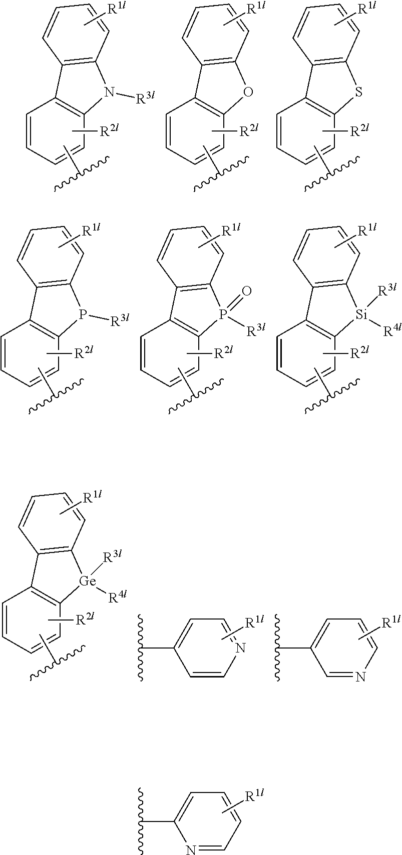
3. Heterocyclic Compounds and Their Derivatives 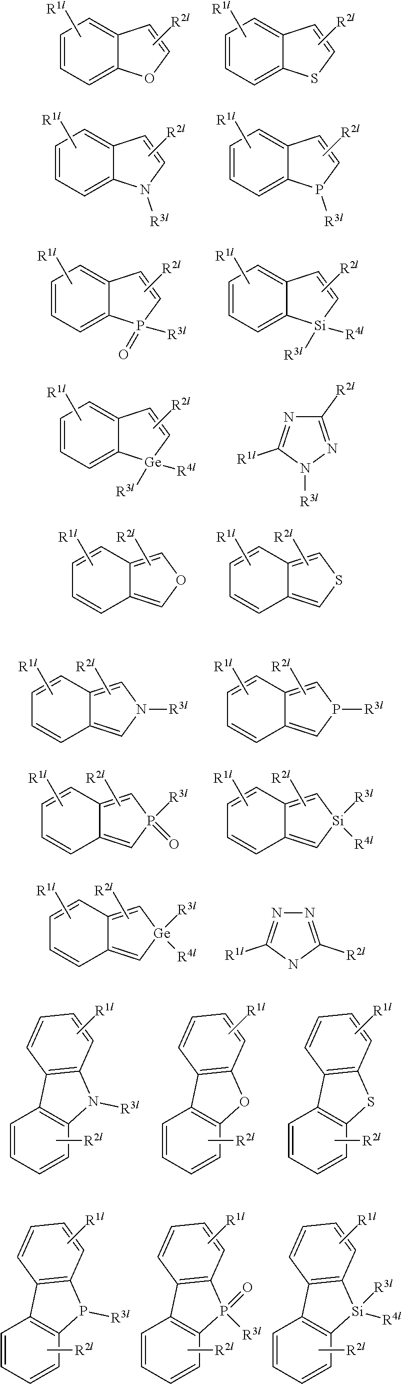 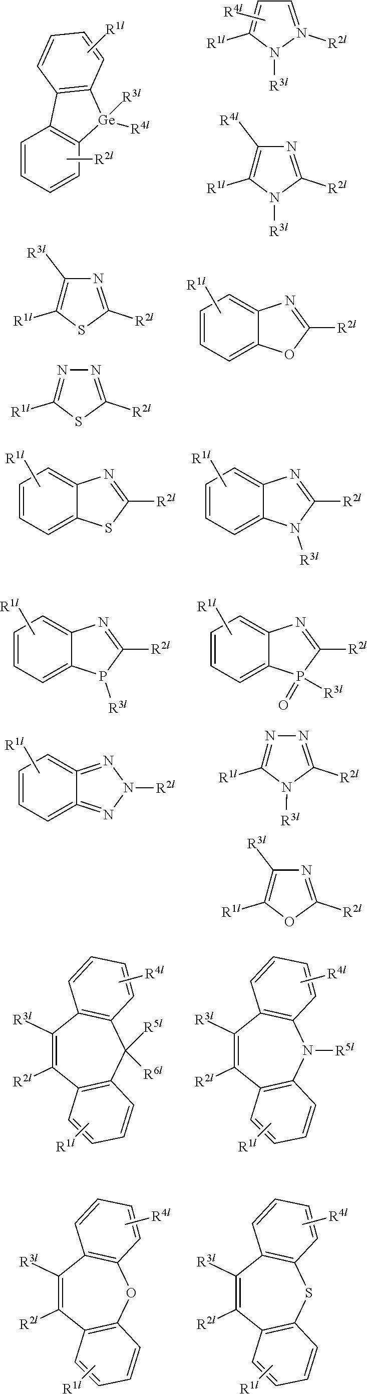 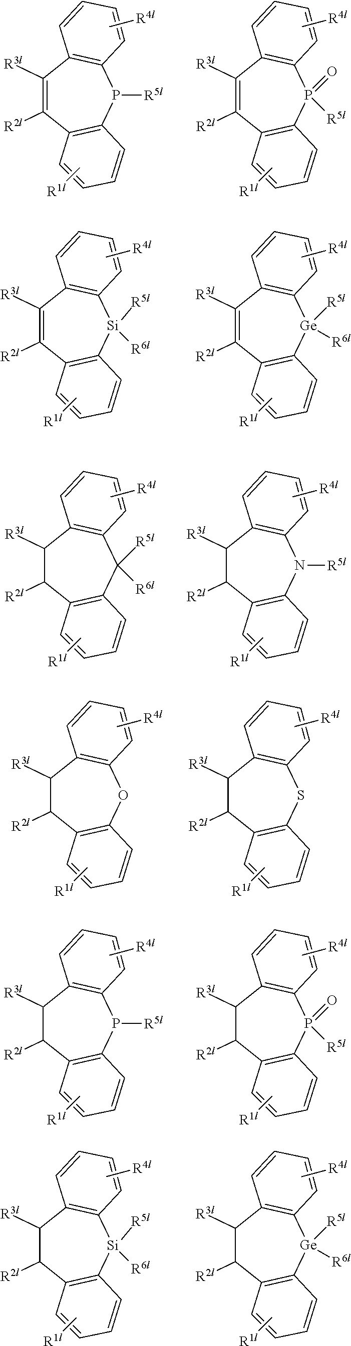 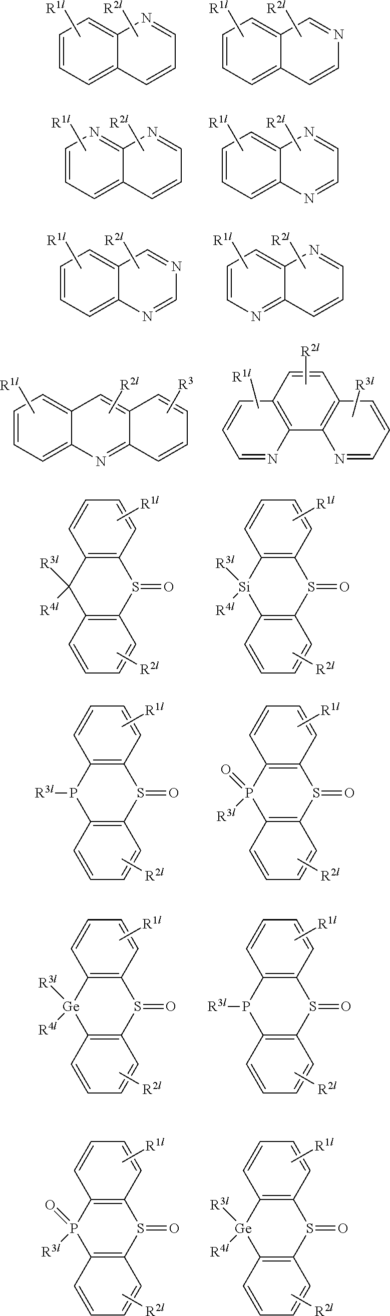 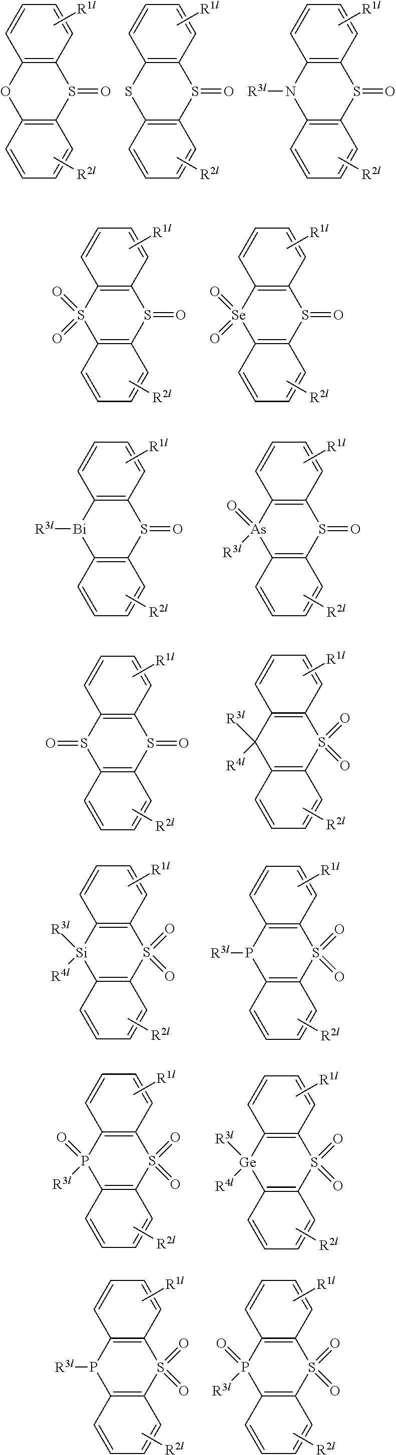 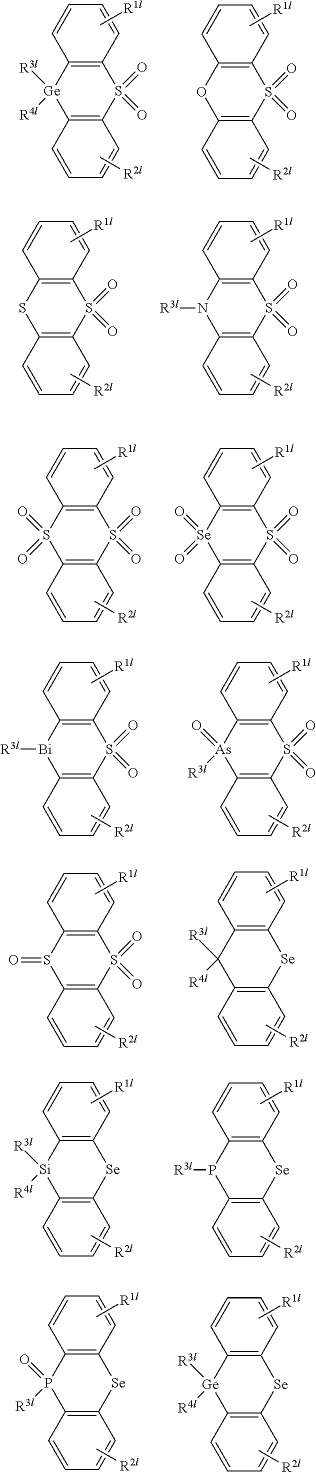 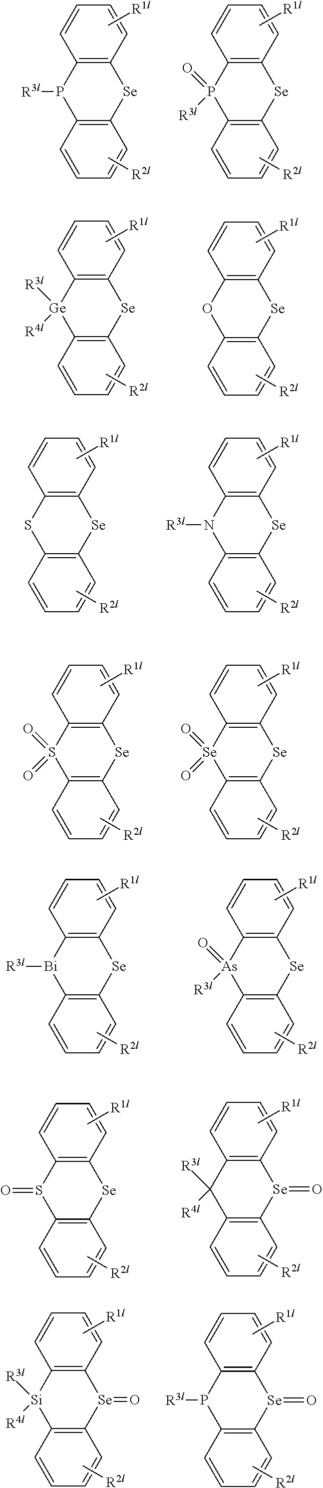 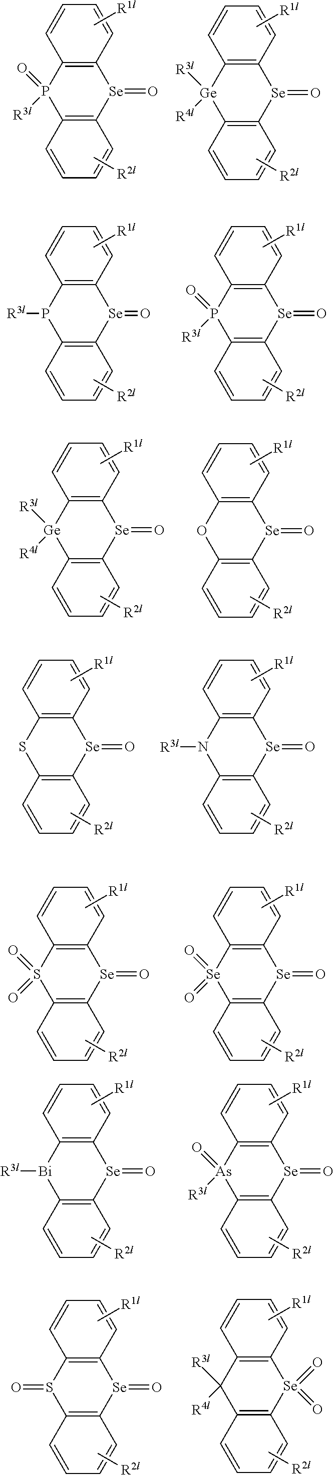 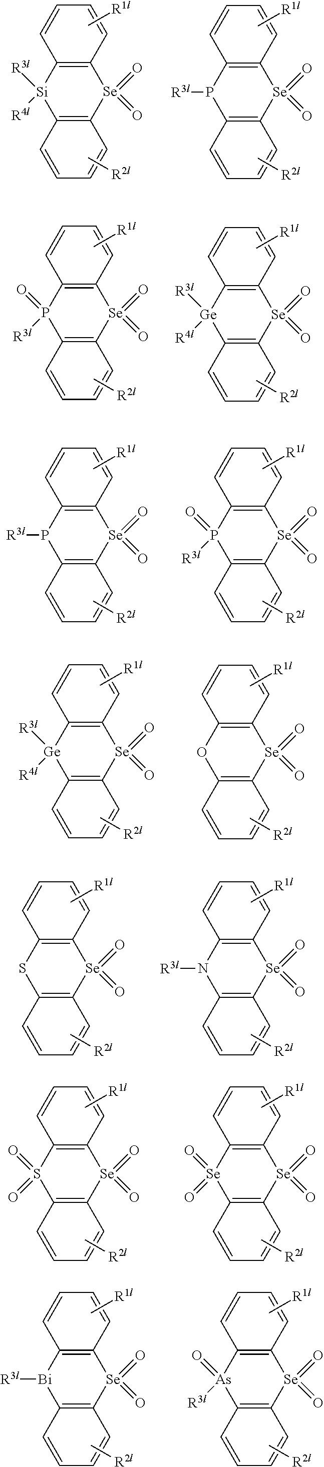 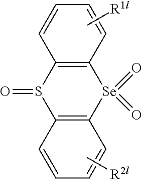 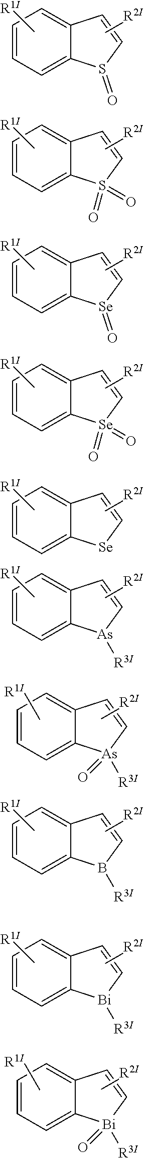 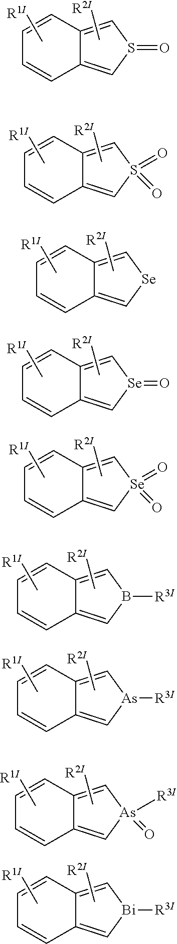 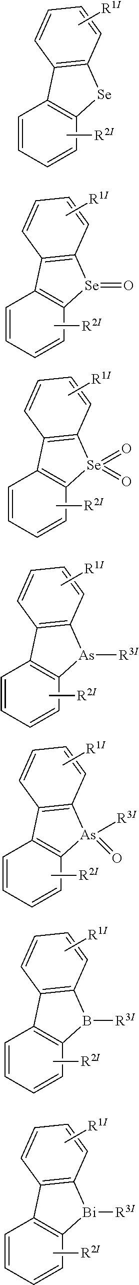 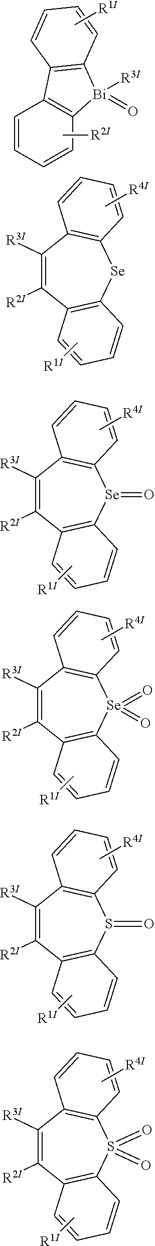 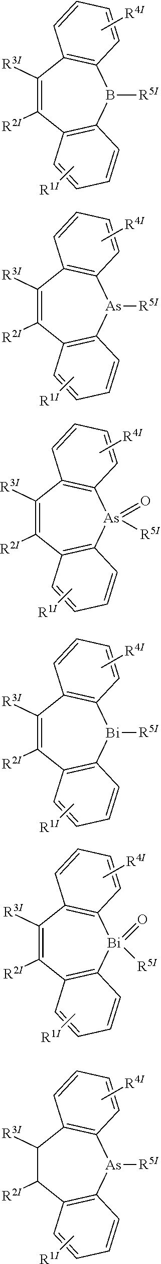 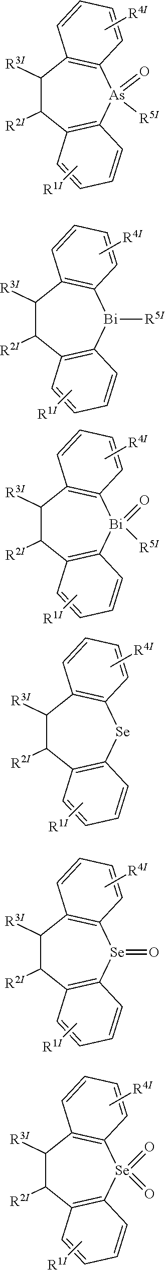 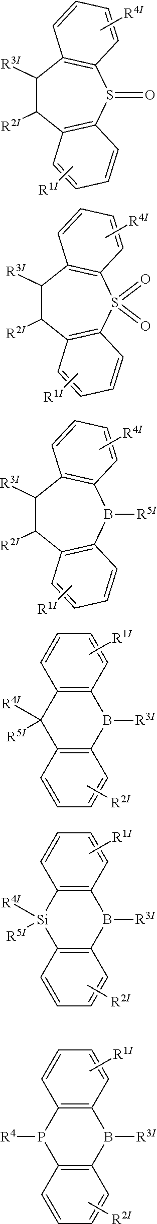 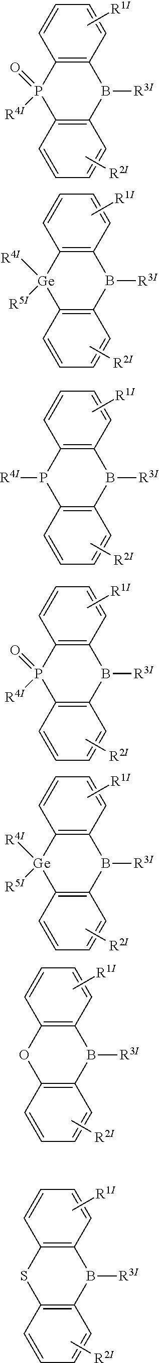 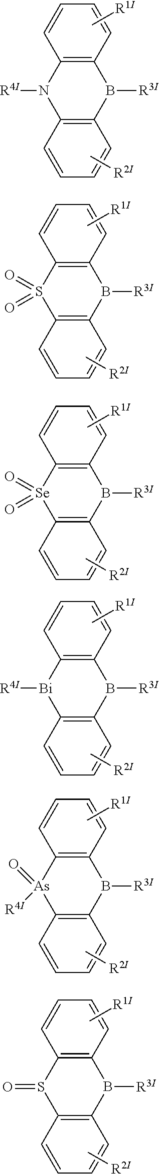 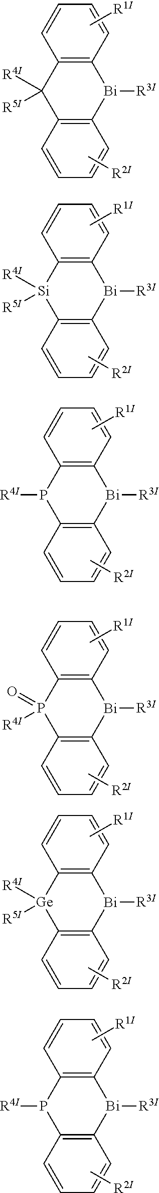 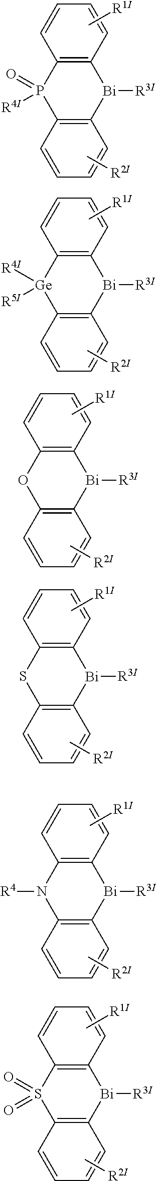 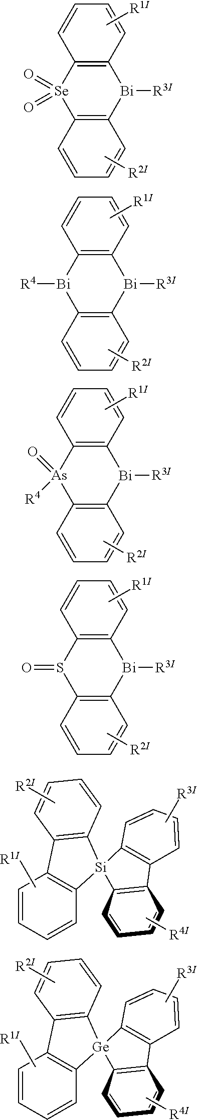 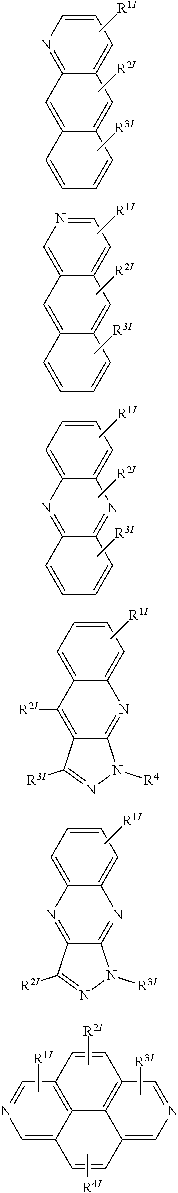 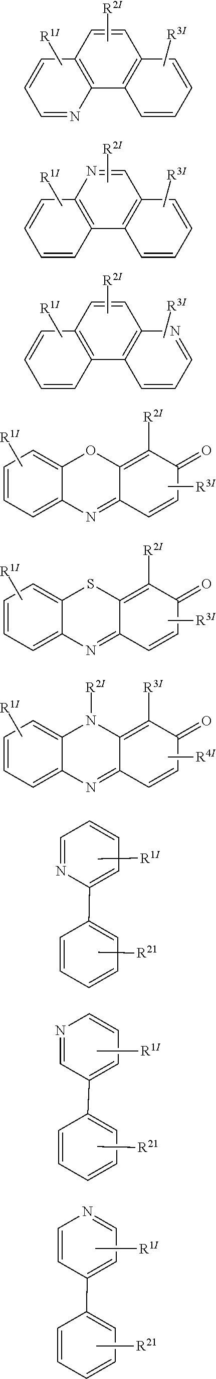 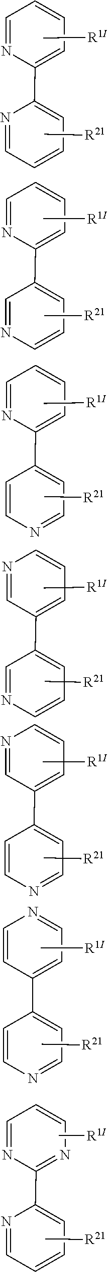 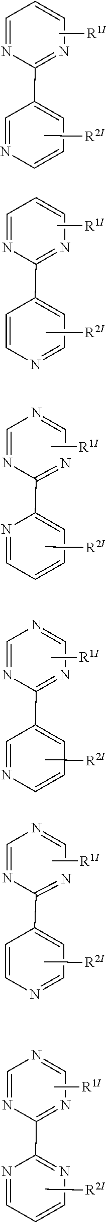 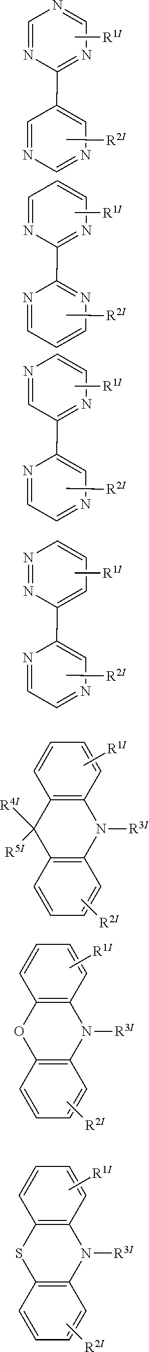 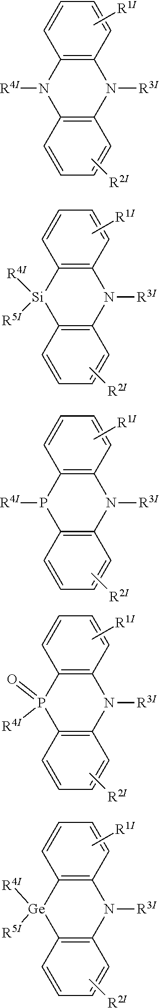 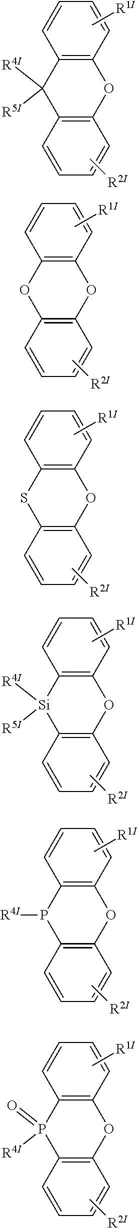 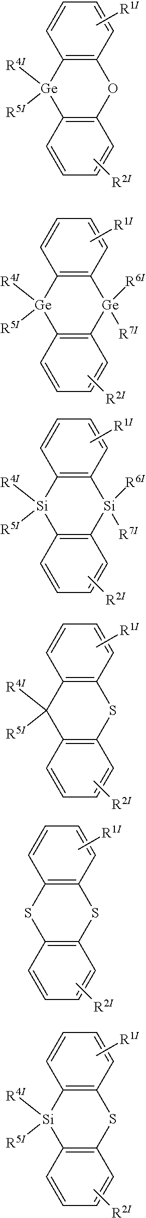 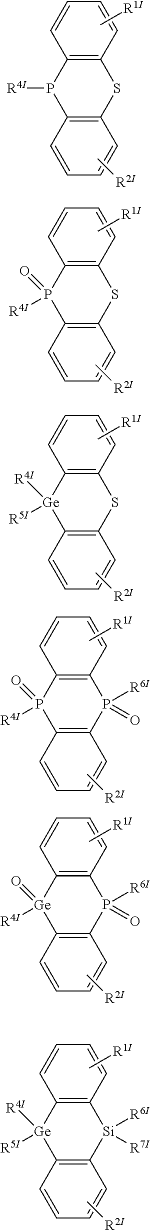 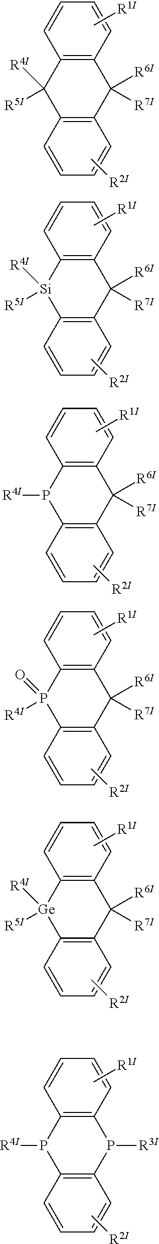 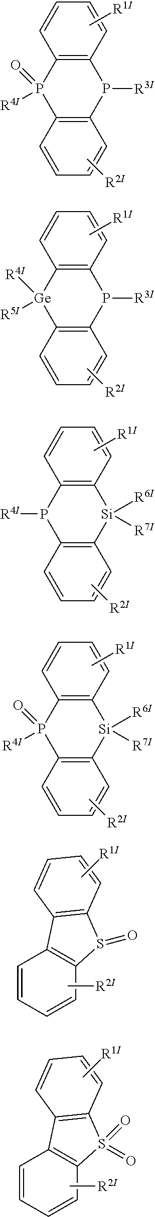 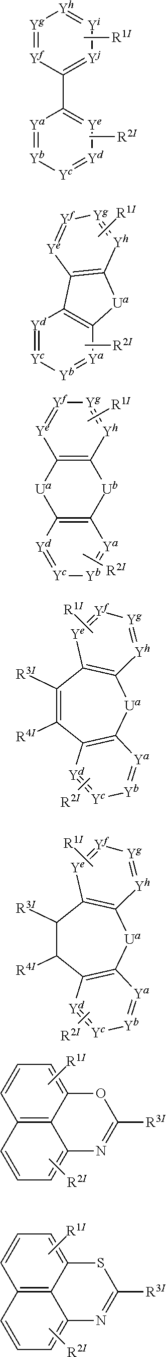 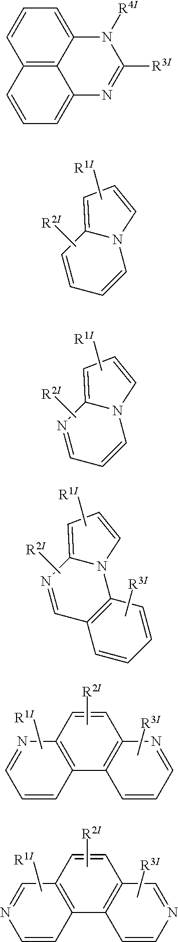
4. Other Fluorescent Luminophors 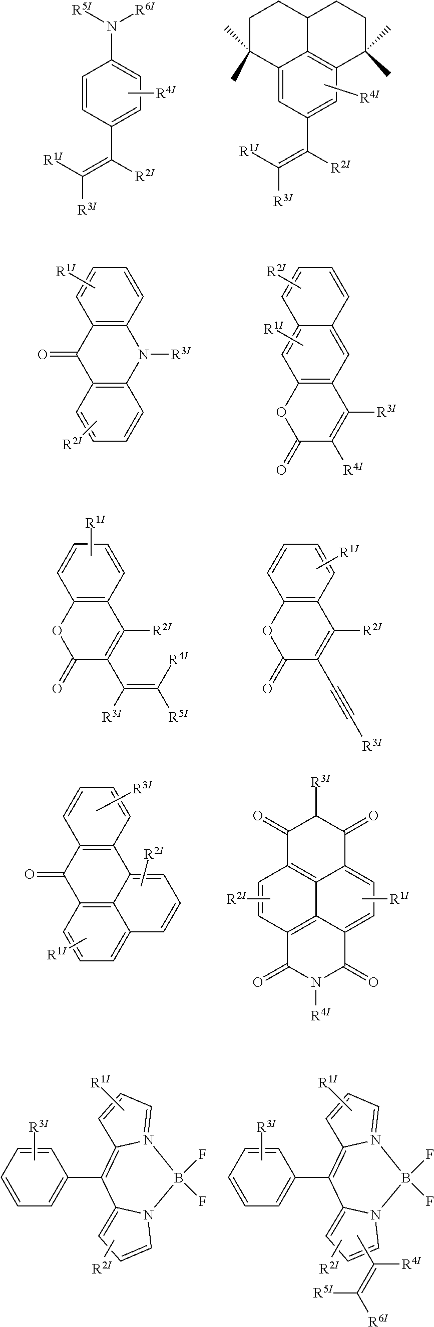 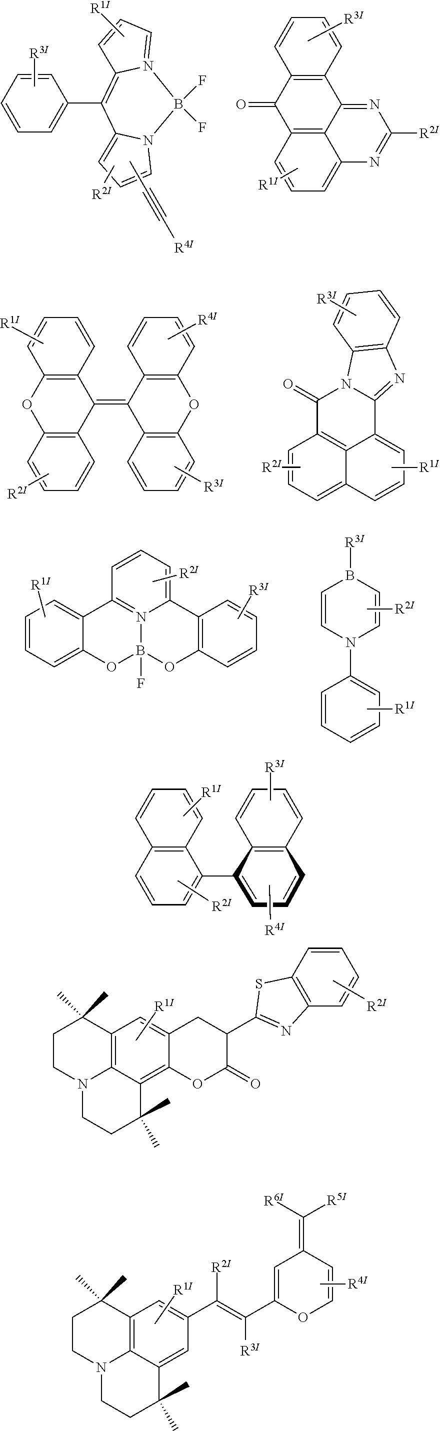 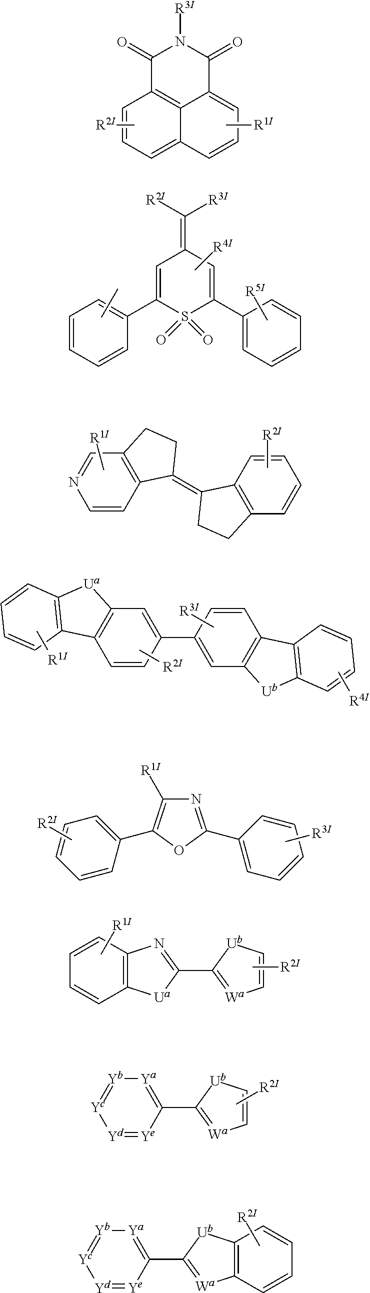 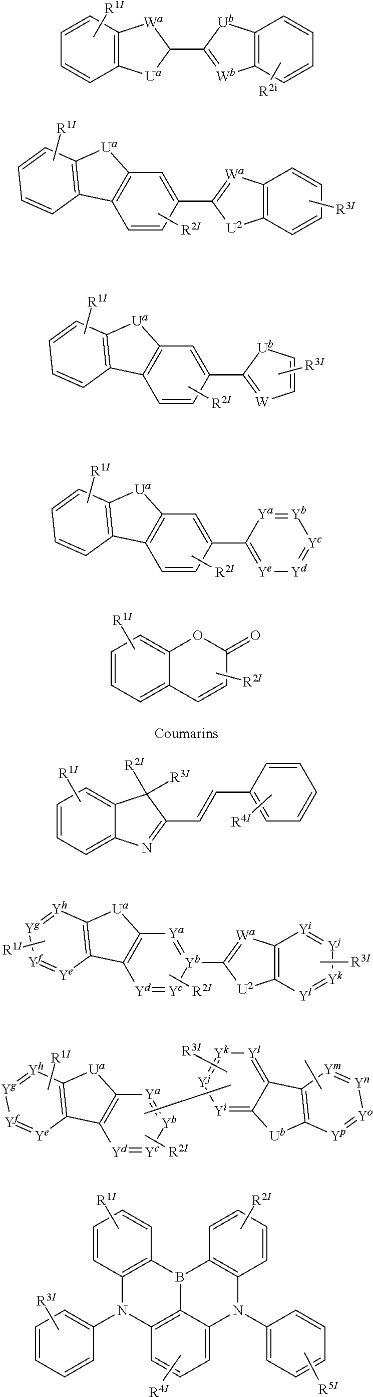
wherein each of R¹¹, R²¹, R³¹, R⁴¹, R⁵¹, R⁶¹, R⁷¹ and R⁸¹ independently are hydrogen, aryl, cycloalkyl, cycloalkenyl, heterocyclyl, heteroaryl, alkyl, alkenyl, alkynyl, deuterium, halogen, hydroxyl , thiol, nitro, cyano, amino, a mono- or di-alkylamino, a mono- or diarylamino, alkoxy, aryloxy, haloalkyl, aralkyl, ester, nitrile, isonitrile, heteroaryl, alkoxycarbonyl, acylamino, alkoxycarbonylamino, aryloxycarbonylamino, sulfonylamino, sulfamoyl, carbamoyl, alkylthio, sulfinyl, ureido, phosphoramide, mercapto, sulfo, carboxyl, hydrzino, substituted silyl, polymeric, or any conjugate or combination thereof;
wherein each of Y^{a}, Y^{b}, Y^{c}, Y^{d}, Y^{e}, Y^{f}, Y^{g}, Y^{h}, Yⁱ, Y^{j}, Y^{k}, Y^{l}, Y^{m}, Yⁿ, Y^{o} and Y^{p} independently are C, N or B;
wherein each of U^{a}, U^{b} and U^{c} independently represent CH₂, CR¹R², C═O, CH₂, SiR¹R², GeH₂, GeR¹R², NH, NR³, PH, PR³, R³P═O, AsR³, R³As═O, O, S, S═O, SO₂, Se, Se═O, SeO₂, BH, BR³, R³Bi═O, BiH, or BiR³;
wherein each R¹, R², and R³ is independently hydrogen, deuterium, halogen, hydroxyl, thiol, nitro, cyano, nitrile, isonitrile, sulfinyl, mercapto, sulfo, carboxyl, hydrazino; substituted or unsubstituted: aryl, cycloalkyl, cycloalkenyl, heterocyclyl, heteroaryl, alkyl, alkenyl, alkynyl, amino, monoalkylamino, dialkylamino, monoarylamino, diarylamino, alkoxy, aryloxy, haloalkyl, aralkyl, ester, alkoxycarbonyl, acylamino, alkoxycarbonylamino, aryloxycarbonylamino, sulfonylamino, sulfamoyl, carbamoyl, alkylthio, ureido, phosphoramide, silyl, polymeric, or any conjugate or combination thereof.

18. The device of claim 1, wherein the fluorescent emitter comprises one of the following compounds:

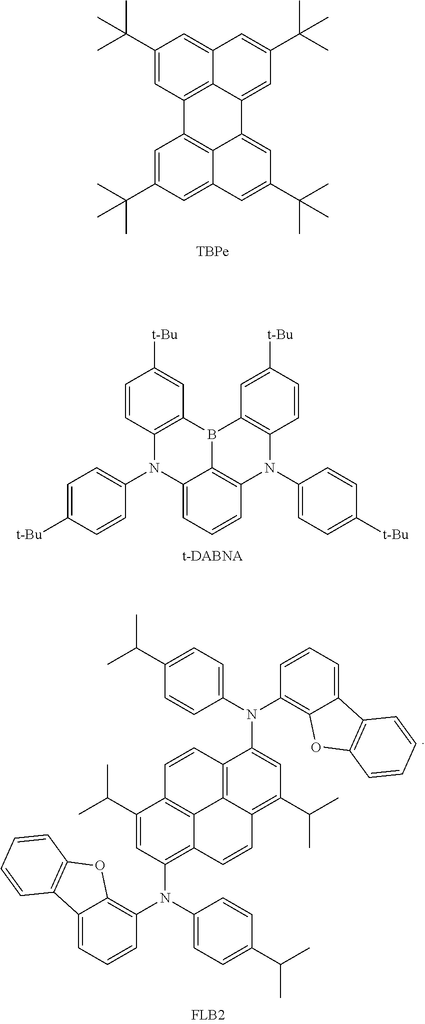

19. A consumer product comprising the device of claim 1.
